(19) United States
(12) Patent Application Publication
(10) Pub. No.: US 2026/0118764 A1
(43) Pub. Date: Apr. 30, 2026

(54) COMPOSITION FOR FORMING SILICON-CONTAINING RESIST UNDERLAYER FILM AND SILICON-CONTAINING RESIST UNDERLAYER FILM

(71) Applicant: NISSAN CHEMICAL CORPORATION, Tokyo (JP)

(72) Inventors: Wataru SHIBAYAMA, Toyama (JP); Satoshi TAKEDA, Toyama (JP); Shuhei SHIGAKI, Toyama (JP); Yuki FURUKAWA, Toyama (JP); Taiki SAIJO, Toyama (JP)

(73) Assignee: NISSAN CHEMICAL CORPORATION, Tokyo (JP)

(21) Appl. No.: 18/728,271

(22) PCT Filed: Jan. 11, 2023
(86) PCT No.: PCT/JP2023/000376

§ 371 Date: Jul. 11, 2024

(30) Foreign Application Priority Data
Jan. 12, 2022 (JP) 2022-003240

(51) Int. Cl. G03F 7/09; C08G 77/26; G03F 7/00; G03F 7/075; G03F 7/16; H01L 21/311

(52) U.S. Cl. CPC G03F 7/094; C08G 77/26; G03F 7/0757; G03F 7/168; G03F 7/70033; H10P 50/73

(57) ABSTRACT

A composition for forming a silicon-containing resist underlayer film, including: component [A]: a carbon-carbon triple bond-containing polysiloxane and component [C]: a solvent.

### TECHNICAL FIELD

The present invention relates to a composition for forming a silicon-containing resist underlayer film and a silicon-containing resist underlayer film.

### BACKGROUND ART

Conventionally, fine processing by lithography using a photoresist has been performed in manufacturing a semiconductor apparatus. The fine processing is a processing method of forming fine irregularities corresponding to a pattern on a substrate surface by forming a photoresist thin film on a semiconductor substrate such as a silicon wafer, irradiating the photoresist thin film with an active ray such as an ultraviolet ray through a mask pattern on which a pattern of a semiconductor device is drawn, developing the photoresist thin film, and etching the substrate using the obtained photoresist pattern as a protective film.

In recent years, the degree of integration of semiconductor devices has been increased, and active rays to be used also tend to have short wavelength from a KrF excimer laser (248 nm) to an ArF excimer laser (193 nm). With the tendency to have short wavelength of active rays, the effect of reflection of the active rays from the semiconductor substrate becomes a major problem, and a method of providing a resist underlayer film called an antireflection film (bottom anti-reflective coating, BARC) between a photoresist and a substrate to be processed has been widely applied.

As an underlayer film between a semiconductor substrate and a photoresist, a film known as a hard mask containing a metal element such as silicon or titanium is used. In this case, since there is a large difference in constituent component between the resist and the hard mask, the rate of removal by dry etching greatly depends on the type of gas used for dry etching. Then, by appropriately selecting the type of gas, the hard mask can be removed by dry etching without a large decrease in film thickness of the photoresist. As described above, in recent manufacturing of a semiconductor apparatus, a resist underlayer film has been configured to be arranged between a semiconductor substrate and a photoresist in order to achieve various effects including an antireflection effect.

A composition for a resist underlayer film has been studied so far, and development of a new material for a resist underlayer film is desired due to diversity of required characteristics and the like. For example, there are disclosed a composition for forming a coating type boron phosphorus glass (BPSG) film including a structure having a specific silicic acid as a skeleton (Patent Literature 1) for the purpose of forming a wet etchable film, and a composition for forming a silicon-containing resist underlayer film containing a carbonyl structure (Patent Literature 2) for the purpose of removing a chemical liquid of a mask residue after lithography.

### CITATION LIST

### Patent Literature

Patent Literature 1: JP 2016-74774 A
Patent Literature 2: WO 2018/181989 A

### SUMMARY OF INVENTION

### Technical Problem

Along with further miniaturization of a resist pattern in a leading-edge semiconductor device in recent years, a resist underlayer film capable of preventing resist pattern collapse is demanded.

The present invention has been made in view of such circumstances, and an object is to provide a silicon-containing resist underlayer film capable of improving resolution of a resist pattern by preventing a fine resist pattern from collapsing, and a composition for forming a silicon-containing resist underlayer film capable of forming the silicon-containing resist underlayer film.

### Solution to Problem

As a result of intensive studies to solve the above problem, the present inventors have found that the above problem can be solved, and have completed the present invention having the gist described below.

That is, the present invention includes the following.
[1]A composition for forming a silicon-containing resist underlayer film, including:
component [A]: a carbon-carbon triple bond-containing polysiloxane; and
component [C]: a solvent.
[2] The composition for forming a silicon-containing resist underlayer film according to [1], wherein the carbon-carbon triple bond-containing polysiloxane contains a structural unit derived from a hydrolyzable silane (A) having a carbon-carbon triple bond.
[3]A composition for forming a silicon-containing resist underlayer film, including:
component [A′]: a polysiloxane;
component [B]: a hydrolyzable silane (A) having a carbon-carbon triple bond; and
component [C]: a solvent.
[4] The composition for forming a silicon-containing resist underlayer film according to [2] or [3], wherein the hydrolyzable silane (A) is a compound represented by Formula (A-1) described below:

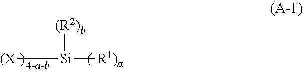

in Formula (A-1), a represents an integer of 1 to 3;
b represents an integer of 0 to 2;
a+b represents an integer of 1 to 3;
R¹ represents an organic group that has a carbon-carbon triple bond and may have an ionic bond;
R² represents an optionally substituted alkyl group, an optionally substituted aryl group, an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group, or a combination of two or more thereof;
X represents an alkoxy group, an aralkyloxy group, an acyloxy group, or a halogen atom;
when there are a plurality of R¹, R², and X, the plurality of R¹, R², and X may be the same or different.
[5] The composition for forming a silicon-containing resist underlayer film according to [4], wherein R¹ in the Formula (A-1) is represented by Formula (A-2a) described below:

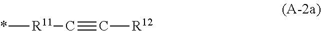

in Formula (A-2a), R¹¹ represents a single bond or a divalent organic group that may have an ionic bond;
R¹² represents a hydrogen atom, an alkyl group having 1 to 6 carbon atoms that may have a substituent group, or an aryl group that may have a substituent group;
* represents a bond.
[6] The composition for forming a silicon-containing resist underlayer film according to [1] or [2], wherein the carbon-carbon triple bond-containing polysiloxane as the component [A] is a polysiloxane modified product in which a part of silanol groups is alcohol-modified or acetal-protected.
[7] The composition for forming a silicon-containing resist underlayer film according to [3], wherein the polysiloxane as the component [A′] is a polysiloxane modified product in which a part of silanol groups is alcohol-modified or acetal-protected.
[8] The composition for forming a silicon-containing resist underlayer film according to any of [1] to [7], wherein the component [C] contains an alcohol-based solvent.
[9] The composition for forming a silicon-containing resist underlayer film according to [8], wherein the component [C] contains a propylene glycol monoalkyl ether.
[10] The composition for forming a silicon-containing resist underlayer film according to any of [1] to [9], further including: component [D]: a curing catalyst.
[11] The composition for forming a silicon-containing resist underlayer film according to any of [1] to [10], further including: component [E]: a nitric acid.
[12] The composition for forming a silicon-containing resist underlayer film according to any of [1] to [11], wherein the component [C] contains water.
[13] The composition for forming a silicon-containing resist underlayer film according to any of [1] to [12], the composition being for forming a resist underlayer film for EUV lithography.
[14]A silicon-containing resist underlayer film, the film being a cured product of the composition for forming a silicon-containing resist underlayer film according to any of [1] to [13].
[15]A semiconductor processing substrate including:
a semiconductor substrate; and
the silicon-containing resist underlayer film according to [14].
[16]A method for manufacturing a semiconductor element, the method including:
a step of forming an organic underlayer film on a substrate;
a step of forming a resist underlayer film on the organic underlayer film using the composition for forming a silicon-containing resist underlayer film according to any of [1] to [13]; and
a step of forming a resist film on the resist underlayer film.
[17] The method for manufacturing a semiconductor element according to [16], wherein
the resist film is formed of a resist for EUV lithography.
[18] The method for manufacturing a semiconductor element according to [16] or [17], wherein
in the step of forming the resist underlayer film, a composition for forming a silicon-containing resist underlayer film filtered through a nylon filter is used.
[19]A pattern forming method, including:
a step of forming an organic underlayer film on a semiconductor substrate;
a step of applying the composition for forming a silicon-containing resist underlayer film according to any of [1] to [13] on the organic underlayer film and baking the composition to form a resist underlayer film;
a step of applying a composition for forming a resist film on the resist underlayer film to form a resist film;
a step of exposing and developing the resist film to obtain a resist pattern;
a step of etching the resist underlayer film using the resist pattern as a mask; and
a step of etching the organic underlayer film using the patterned resist underlayer film as a mask.
[20] The pattern forming method according to [19], further including:
a step of removing the resist underlayer film by a wet method using a chemical liquid after the step of etching the organic underlayer film.
[21] The pattern forming method according to [19] or [20], wherein
the resist film is formed of a resist for EUV lithography.

### Advantageous Effects of Invention

According to the present invention, it is possible to provide a silicon-containing resist underlayer film capable of improving resolution of a resist pattern by preventing a fine resist pattern from collapsing, and a composition for forming a silicon-containing resist underlayer film capable of forming the silicon-containing resist underlayer film.

### DESCRIPTION OF EMBODIMENTS

### (Composition for Forming Silicon-Containing Resist Underlayer Film)

### First Embodiment

The first embodiment of the composition for forming a silicon-containing resist underlayer film of the present invention contains a polysiloxane as component [A] and a solvent as component [C], and further contains other components as necessary.

The polysiloxane as component [A] has a carbon-carbon triple bond.

The carbon-carbon triple bond-containing polysiloxane as component [A](hereinafter, sometimes referred to as “polysiloxane [A]”) preferably contains a structural unit derived from hydrolyzable silane (A) having a carbon-carbon triple bond.

### Second Embodiment

The second embodiment of the composition for forming a silicon-containing resist underlayer film of the present invention contains a polysiloxane as component [A′](hereinafter, sometimes referred to as “polysiloxane [A′]”), hydrolyzable silane (A) having a carbon-carbon triple bond as component [B], and a solvent as component [C], and further contains other components as necessary.

The present inventors consider as described below.

Since the silicon-containing resist underlayer film formed from the composition for forming a silicon-containing resist underlayer film of the present invention has a carbon-carbon triple bond, collapse of the fine resist pattern can be prevented, and as a result, resolution of the resist pattern can be enhanced. The carbon-carbon triple bond reacts with a polar functional group in the resist by light irradiation with EUV or the like, and crosslinking is performed, whereby the crosslink density of the silicon-containing resist underlayer film can be increased. As a result, collapse of the fine resist pattern can be prevented, and as a result, resolution of the resist pattern can be enhanced.

### <Hydrolyzable Silane (A) Having Carbon-Carbon Triple Bond>

The hydrolyzable silane (A) has a carbon-carbon triple bond. In other words, the hydrolyzable silane (A) has a structure represented by Formula (AA) described below.

The hydrolyzable silane (A) having a carbon-carbon triple bond (hereinafter, sometimes referred to as “hydrolyzable silane (A)”) may have two or more carbon-carbon triple bonds. In other words, the hydrolyzable silane (A) may have two or more structures represented by Formula (AA) described below.

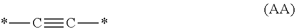 [SMILES: *C#C*]

(In the structure (AA), * represents a bond. Note that one bond may be bonded to a hydrogen atom.)

In that case, the two or more structures represented by Formula (AA) may each be bonded to one linking group bonded to a silicon atom, and the two or more structures represented by Formula (AA) may each be bonded to a silicon atom directly or via different linking groups.

The linking group is, for example, an organic group. The linking group may have an ionic bond. When the linking group has an ionic bond, the linking group may have an ionic bond in a row of atoms connecting the structure represented by Formula (AA) and the silicon atom, or may have an ionic bond in a row of atoms branched from a row of atoms connecting the structure represented by Formula (AA) and the silicon atom.

The number of carbon atoms of the linking group is not particularly limited, but the number of carbon atoms of the linking group is preferably 1 to 30 and more preferably 1 to 20.

The linking group usually has a hydrogen atom. The linking group may have an oxygen atom or a nitrogen atom.

The hydrolyzable silane (A) having a carbon-carbon triple bond is preferably a compound represented by Formula (A-1) described below.

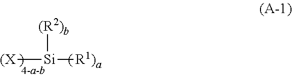

(In Formula (A-1), a represents an integer of 1 to 3.
b represents an integer of 0 to 2.
a+b represents an integer of 1 to 3.
R¹ represents an organic group that has a carbon-carbon triple bond and may have an ionic bond.
R² represents an optionally substituted alkyl group, an optionally substituted aryl group, an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group, or a combination of two or more thereof.
X represents an alkoxy group, an aralkyloxy group, an acyloxy group, or a halogen atom.
when there are a plurality of R¹, R², and X, the plurality of R¹, R², and X may be the same or different.)

### <<R¹ in Formula (A-1)>>

R¹ may have one carbon-carbon triple bond or a plurality of carbon-carbon triple bonds.

The number of carbon atoms of R¹ is not particularly limited, but the number of carbon atoms of R¹ is preferably 2 to 30 and more preferably 2 to 20.

R¹ usually has a hydrogen atom. R¹ may have an oxygen atom or a nitrogen atom in addition to a carbon-carbon triple bond and a hydrogen atom.

R¹ may have an ionic bond. When R¹ has an ionic bond, R¹ may have an ionic bond in a row of atoms connecting the carbon-carbon triple bond and the silicon atom, or may have an ionic bond in a row of atoms branched from a row of atoms connecting the carbon-carbon triple bond and the silicon atom.

R¹ in Formula (A-1) is preferably represented by Formula (A-2a) described below.

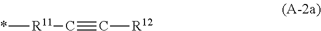

(In Formula (A-2a), R¹¹ represents a single bond or a divalent organic group that may have an ionic bond.

R¹² represents a hydrogen atom, an alkyl group having 1 to 6 carbon atoms that may have a substituent group, or an aryl group that may have a substituent group.

* represents a bond.)

In a case where R¹¹ is a divalent organic group that may have an ionic bond, the number of carbon atoms of R¹¹ is not particularly limited, but the number of carbon atoms of R¹¹ is preferably 1 to 25 and more preferably 1 to 15.

Examples of the alkyl group having 1 to 6 carbon atoms that may have a substituent group in R¹² include an alkyl group having 1 to 6 carbon atoms.

Examples of the alkyl group having 1 to 6 carbon atoms include a methyl group, an ethyl group, an n-propyl group, an i-propyl group, a cyclopropyl group, an n-butyl group, an i-butyl group, an s-butyl group, a t-butyl group, a cyclobutyl group, a 1-methyl-cyclopropyl group, a 2-methyl-cyclopropyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group.

Examples of the alkyl group having 1 to 6 carbon atoms that may have a substituent group include a hydroxyl group, a halogen atom, a carboxyl group, a nitro group, a cyano group, a methylenedioxy group, an acetoxy group, a methylthio group, an amino group, and an alkoxy group having 1 to 6 carbon atoms.

In the present invention, examples of the halogen atom include a fluorine atom, a chlorine atom, a bromine atom, and an iodine atom.

The number of these substituent groups may be one or two or more.

Note that, in the present specification, “i” means “iso”, “s” means “sec”, and “t” means “tert”.

The aryl group in the aryl group that may have a substituent group may be, for example, any of a phenyl group, a monovalent group derived by removing one hydrogen atom of a condensed ring aromatic hydrocarbon compound, and a monovalent group derived by removing one hydrogen atom of a ring-linked aromatic hydrocarbon compound, and the number of carbon atoms thereof is not particularly limited, but is preferably 40 or less, more preferably 30 or less, and still more preferably 20 or less.

Examples of the aryl group include an aryl group having 6 to 20 carbon atoms, and examples thereof include a phenyl group, a 1-naphthyl group, a 2-naphthyl group, a 1-anthryl group, a 2-anthryl group, a 9-anthryl group, a 1-naphthacenyl group, a 2-naphthacenyl group, a 5-naphthacenyl group, a 2-chrysenyl group, a 1-pyrenyl group, a 2-pyrenyl group, a pentacenyl group, a benzopyrenyl group, and a triphenylenyl group; a biphenyl-2-yl group (o-biphenylyl group), a biphenyl-3-yl group (m-biphenylyl group), a biphenyl-4-yl group (p-biphenylyl group), a paraterphenyl-4-yl group, a metaterphenyl-4-yl group, an orthoterphenyl-4-yl group, a 1,1′-binaphthyl-2-yl group, and a 2,2′-binaphthyl-1-yl group, but are not limited thereto.

Examples of the substituent group in the aryl group that may have a substituent group include a hydroxyl group, a halogen atom, a carboxyl group, a nitro group, a cyano group, a methylenedioxy group, an acetoxy group, a methylthio group, an amino group, an alkyl group having 1 to 6 carbon atoms, and an alkoxy group having 1 to 6 carbon atoms.

The number of these substituent groups may be one or two or more.

R¹ may have a hydrogen atom, an oxygen atom, or a nitrogen atom in addition to a carbon-carbon triple bond.

R¹ may have an ionic bond. When R¹ has an ionic bond, R¹ may have an ionic bond in a row of atoms connecting the carbon-carbon triple bond and the silicon atom, or may have a nitro group in a row of atoms branched from a row of atoms connecting the carbon-carbon triple bond and the silicon atom.

### <<<R¹¹>>>

R¹¹ is preferably a single bond or one of divalent organic groups represented by Formulae (A-2-1) to (A-2-6) described below.

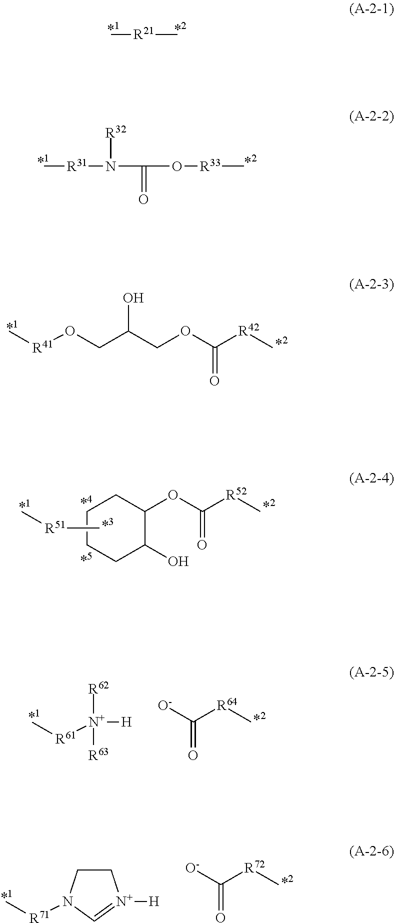

(In Formula (A-2-1), R²¹ represents an alkylene group having 1 to 6 carbon atoms.

In Formula (A-2-2), R³¹ represents an alkylene group having 1 to 6 carbon atoms. R³² represents a hydrogen atom or an alkyl group having 1 to 4 carbon atoms. R³³ represents a single bond or an alkylene group having 1 to 6 carbon atoms.

In Formula (A-2-3), R⁴¹ represents an alkylene group having 1 to 6 carbon atoms. R⁴² represents a single bond or an alkylene group having 1 to 6 carbon atoms.

In Formula (A-2-4), R⁵¹ represents an alkylene group having 1 to 6 carbon atoms. R⁵² represents a single bond or an alkylene group having 1 to 6 carbon atoms.

In Formula (A-2-5), R⁶¹ represents an alkylene group having 1 to 6 carbon atoms. R⁶² and R⁶³ each independently represent a hydrogen atom or an alkyl group having 1 to 4 carbon atoms. R⁶⁴ represents a single bond or an alkylene group having 1 to 6 carbon atoms.

In Formula (A-2-6), R⁷¹ represents an alkylene group having 1 to 6 carbon atoms. R⁷² represents a single bond or an alkylene group having 1 to 6 carbon atoms.

In Formulae (A-2-1) to (A-2-6), *1 represents a bond bonded to Si. *2 represents a bond bonded to a carbon atom constituting a carbon-carbon triple bond. *3 represents a bond bonded to a carbon atom represented by *4 or a carbon atom represented by *5.)

Note that, in the composition for forming a silicon-containing resist underlayer film and the resist underlayer film, the amino group (—N(R³²)—) in Formula (A-2-2) may be cationized. For example, when a nitric acid is added to the composition for forming a silicon-containing resist underlayer film, the amino group (—N(R³²)—) in Formula (A-2-2) may be cationized to form a nitrate.

The alkylene group having 1 to 6 carbon atoms in R²¹, R³¹, R³³, R⁴¹, R⁴², R⁵¹, R⁵², R⁶¹, R⁶⁴, R⁷¹, and R⁷² may be linear or branched. Examples of the alkylene group having 1 to 6 carbon atoms include linear alkylene groups such as a methylene group, an ethylene group, a trimethylene group, a tetramethylene group, a pentamethylene group, and a hexamethylene group. Among them, a methylene group, an ethylene group, a trimethylene group, and a tetramethylene group are preferable.

The alkyl group having 1 to 4 carbon atoms in R³², R⁶², and R⁶³ may be linear or branched. Examples of the alkyl group having 1 to 4 carbon atoms include a methyl group, an ethyl group, an n-propyl group, an i-propyl group, an n-butyl group, an i-butyl group, an s-butyl group, and a t-butyl group.

As R³², R⁶², and R⁶³, a hydrogen atom, a methyl group, and an ethyl group are preferable.

### <<R² in Formula (A-1)>>

The alkyl group may be linear, branched, or cyclic, and the number of carbon atoms thereof is not particularly limited, but is preferably 40 or less, more preferably 30 or less, still more preferably 20 or less, and yet still more preferably 10 or less.

Specific examples of the linear or branched alkyl group as the alkyl group include a methyl group, an ethyl group, an n-propyl group, an i-propyl group, an n-butyl group, an i-butyl group, an s-butyl group, a t-butyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, and a 1-ethyl-2-methyl-n-propyl group.

Specific examples of the cyclic alkyl group include a cycloalkyl group such as a cyclopropyl group, a cyclobutyl group, a 1-methyl-cyclopropyl group, a 2-methyl-cyclopropyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group, a crosslinked cyclic cycloalkyl group such as a bicyclobutyl group, a bicyclopentyl group, a bicyclohexyl group, a bicycloheptyl group, a bicyclooctyl group, a bicyclononyl group, and a bicyclodecyl group, and the like.

The aryl group may be any of a phenyl group, a monovalent group derived by removing one hydrogen atom of a condensed ring aromatic hydrocarbon compound, and a monovalent group derived by removing one hydrogen atom of a ring-linked aromatic hydrocarbon compound, and the number of carbon atoms thereof is not particularly limited, but is preferably 40 or less, more preferably 30 or less, and still more preferably 20 or less.

Examples of the aryl group include an aryl group having 6 to 20 carbon atoms, and examples thereof include a phenyl group, a 1-naphthyl group, a 2-naphthyl group, a 1-anthryl group, a 2-anthryl group, a 9-anthryl group, a 1-naphthacenyl group, a 2-naphthacenyl group, a 5-naphthacenyl group, a 2-chrysenyl group, a 1-pyrenyl group, a 2-pyrenyl group, a pentacenyl group, a benzopyrenyl group, and a triphenylenyl group; a biphenyl-2-yl group (o-biphenylyl group), a biphenyl-3-yl group (m-biphenylyl group), a biphenyl-4-yl group (p-biphenylyl group), a paraterphenyl-4-yl group, a metaterphenyl-4-yl group, an orthoterphenyl-4-yl group, a 1,1′-binaphthyl-2-yl group, and a 2,2′-binaphthyl-1-yl group, but are not limited thereto.

The aralkyl group is an alkyl group substituted with an aryl group, and specific examples of such an aryl group and an alkyl group include the same groups as those described above. The number of carbon atoms of the aralkyl group is not particularly limited, but is preferably 40 or less, more preferably 30 or less, and still more preferably 20 or less.

Specific examples of the aralkyl group include a phenylmethyl group (benzyl group), a 2-phenylethylene group, a 3-phenyl-n-propyl group, a 4-phenyl-n-butyl group, a 5-phenyl-n-pentyl group, a 6-phenyl-n-hexyl group, a 7-phenyl-n-heptyl group, an 8-phenyl-n-octyl group, a 9-phenyl-n-nonyl group, and a 10-phenyl-n-decyl group, but are not limited thereto.

The halogenated alkyl group, the halogenated aryl group, and the halogenated aralkyl group are respectively an alkyl group, an aryl group, and an aralkyl group substituted with one or more halogen atoms, and specific examples of such an alkyl group, an aryl group, and an aralkyl group include the same groups as those described above.

Examples of the halogen atom include a fluorine atom, a chlorine atom, a bromine atom, and an iodine atom.

The number of carbon atoms of the halogenated alkyl group is not particularly limited, but is preferably 40 or less, more preferably 30 or less, still more preferably 20 or less, and yet still more preferably 10 or less.

Specific examples of the halogenated alkyl group include a monofluoromethyl group, a difluoromethyl group, a trifluoromethyl group, a bromodifluoromethyl group, a 2-chloroethyl group, a 2-bromoethyl group, a 1,1-difluoroethyl group, a 2,2,2-trifluoroethyl group, a 1,1,2,2-tetrafluoroethyl group, a 2-chloro-1,1,2-trifluoroethyl group, a pentafluoroethyl group, a 3-bromopropyl group, a 2,2,3,3-tetrafluoropropyl group, a 1,1,2,3,3,3-hexafluoropropyl group, a 1,1,1,3,3,3-hexafluoropropane-2-yl group, a 3-bromo-2-methylpropyl group, a 4-bromobutyl group, and a perfluoropentyl group, but are not limited thereto.

The number of carbon atoms of the halogenated aryl group is not particularly limited, but is preferably 40 or less, more preferably 30 or less, and still more preferably 20 or less.

Specific examples of the halogenated aryl group include a 2-fluorophenyl group, a 3-fluorophenyl group, a 4-fluorophenyl group, a 2,3-difluorophenyl group, a 2,4-difluorophenyl group, a 2,5-difluorophenyl group, a 2,6-difluorophenyl group, a 3,4-difluorophenyl group, a 3,5-difluorophenyl group, a 2,3,4-trifluorophenyl group, a 2,3,5-trifluorophenyl group, a 2,3,6-trifluorophenyl group, a 2,4,5-trifluorophenyl group, a 2,4,6-trifluorophenyl group, a 3,4,5-trifluorophenyl group, a 2,3,4,5-tetrafluorophenyl group, a 2,3,4,6-tetrafluorophenyl group, a 2,3,5,6-tetrafluorophenyl group, a pentafluorophenyl group, a 2-fluoro-1-naphthyl group, a 3-fluoro-1-naphthyl group, a 4-fluoro-1-naphthyl group, a 6-fluoro-1-naphthyl group, a 7-fluoro-1-naphthyl group, an 8-fluoro-1-naphthyl group, a 4,5-difluoro-1-naphthyl group, a 5,7-difluoro-1-naphthyl group, a 5,8-difluoro-1-naphthyl group, a 5,6,7,8-tetrafluoro-1-naphthyl group, a heptafluoro-1-naphthyl group, a 1-fluoro-2-naphthyl group, a 5-fluoro-2-naphthyl group, a 6-fluoro-2-naphthyl group, a 7-fluoro-2-naphthyl group, a 5,7-difluoro-2-naphthyl group, and a heptafluoro-2-naphthyl group, and groups obtained as fluorine atoms (fluoro groups) of the groups are optionally substituted with chlorine atoms (chloro groups), bromine atoms (bromo groups), and iodine atoms (iodine groups), but are not limited thereto.

The number of carbon atoms of the halogenated aralkyl group is not particularly limited, but is preferably 40 or less, more preferably 30 or less, and still more preferably 20 or less.

Specific examples of the halogenated aralkyl group include a 2-fluorobenzyl group, a 3-fluorobenzyl group, a 4-fluorobenzyl group, a 2,3-difluorobenzyl group, a 2,4-difluorobenzyl group, a 2,5-difluorobenzyl group, a 2,6-difluorobenzyl group, a 3,4-difluorobenzyl group, a 3,5-difluorobenzyl group, a 2,3,4-trifluorobenzyl group, a 2,3,5-trifluorobenzyl group, a 2,3,6-trifluorobenzyl group, a 2,4,5-trifluorobenzyl group, a 2,4,6-trifluorobenzyl group, a 2,3,4,5-tetrafluorobenzyl group, a 2,3,4,6-tetrafluorobenzyl group, a 2,3,5,6-tetrafluorobenzyl group, a 2,3,4,5,6-pentafluorobenzyl group, and groups obtained as fluorine atoms (fluoro groups) of the groups are optionally substituted with chlorine atoms (chloro groups), bromine atoms (bromo groups), and iodine atoms (iodine groups), but are not limited thereto.

The alkoxyalkyl group, the alkoxyaryl group, and the alkoxyaralkyl group are respectively an alkyl group, an aryl group, and an aralkyl group substituted with one or more alkoxy groups, and specific examples of such an alkyl group, an aryl group, and an aralkyl group include the same groups as those described above.

Examples of the alkoxy group as a substituent group include alkoxy groups having at least any of linear, branched, and cyclic alkyl moieties having 1 to 20 carbon atoms.

Examples of the linear or branched alkoxy group include a methoxy group, an ethoxy group, an n-propoxy group, an i-propoxy group, an n-butoxy group, an i-butoxy group, an s-butoxy group, a t-butoxy group, an n-pentyloxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, and a 1-ethyl-2-methyl-n-propoxy group.

In addition, examples of the cyclic alkoxy group include a cyclopropoxy group, a cyclobutoxy group, a 1-methyl-cyclopropoxy group, a 2-methyl-cyclopropoxy group, a cyclopentyloxy group, a 1-methyl-cyclobutoxy group, a 2-methyl-cyclobutoxy group, a 3-methyl-cyclobutoxy group, a 1,2-dimethyl-cyclopropoxy group, a 2,3-dimethyl-cyclopropoxy group, a 1-ethyl-cyclopropoxy group, a 2-ethyl-cyclopropoxy group, a cyclohexyloxy group, a 1-methyl-cyclopentyloxy group, a 2-methyl-cyclopentyloxy group, a 3-methyl-cyclopentyloxy group, a 1-ethyl-cyclobutoxy group, a 2-ethyl-cyclobutoxy group, a 3-ethyl-cyclobutoxy group, a 1,2-dimethyl-cyclobutoxy group, a 1,3-dimethyl-cyclobutoxy group, a 2,2-dimethyl-cyclobutoxy group, a 2,3-dimethyl-cyclobutoxy group, a 2,4-dimethyl-cyclobutoxy group, a 3,3-dimethyl-cyclobutoxy group, a 1-n-propyl-cyclopropoxy group, a 2-n-propyl-cyclopropoxy group, a 1-i-propyl-cyclopropoxy group, a 2-i-propyl-cyclopropoxy group, a 1,2,2-trimethyl-cyclopropoxy group, a 1,2,3-trimethyl-cyclopropoxy group, a 2,2,3-trimethyl-cyclopropoxy group, a 1-ethyl-2-methyl-cyclopropoxy group, a 2-ethyl-1-methyl-cyclopropoxy group, a 2-ethyl-2-methyl-cyclopropoxy group, a 2-ethyl-3-methyl-cyclopropoxy group, and the like.

Specific examples of the alkoxyalkyl group include a lower (about 5 or less carbon atoms) alkyloxy-lower (about 5 or less carbon atoms) alkyl group such as a methoxymethyl group, an ethoxymethyl group, a 1-ethoxyethyl group, a 2-ethoxyethyl group, and an ethoxymethyl group, but are not limited thereto.

Specific examples of the alkoxyaryl group include a 2-methoxyphenyl group, a 3-methoxyphenyl group, a 4-methoxyphenyl group, a 2-(1-ethoxy) phenyl group, a 3-(1-ethoxy) phenyl group, a 4-(1-ethoxy) phenyl group, a 2-(2-ethoxy) phenyl group, a 3-(2-ethoxy) phenyl group, a 4-(2-ethoxy) phenyl group, a 2-methoxynaphthalene-1-yl group, a 3-methoxynaphthalene-1-yl group, a 4-methoxynaphthalene-1-yl group, a 5-methoxynaphthalene-1-yl group, a 6-methoxynaphthalene-1-yl group, and a 7-methoxynaphthalene-1-yl group, but are not limited thereto.

Specific examples of the alkoxyaralkyl group include a 3-(methoxyphenyl) benzyl group and a 4-(methoxyphenyl) benzyl group, but are not limited thereto.

The alkenyl group may be linear or branched, and the number of carbon atoms thereof is not particularly limited, but is preferably 40 or less, more preferably 30 or less, still more preferably 20 or less, and yet still more preferably 10 or less.

Specific examples of the alkenyl group include an ethenyl group (vinyl group), a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, a 1-ethylethenyl group, a 1-methyl-1-propenyl group, a 1-methyl-2-propenyl group, a 1-pentenyl group, a 2-pentenyl group, a 3-pentenyl group, a 4-pentenyl group, a 1-n-propylethenyl group, a 1-methyl-1-butenyl group, a 1-methyl-2-butenyl group, a 1-methyl-3-butenyl group, a 2-ethyl-2-propenyl group, a 2-methyl-1-butenyl group, a 2-methyl-2-butenyl group, a 2-methyl-3-butenyl group, a 3-methyl-1-butenyl group, a 3-methyl-2-butenyl group, a 3-methyl-3-butenyl group, a 1,1-dimethyl-2-propenyl group, a 1-i-propylethenyl group, a 1,2-dimethyl-1-propenyl group, a 1,2-dimethyl-2-propenyl group, a 1-cyclopentenyl group, a 2-cyclopentenyl group, a 3-cyclopentenyl group, a 1-hexenyl group, a 2-hexenyl group, a 3-hexenyl group, a 4-hexenyl group, a 5-hexenyl group, a 1-methyl-1-pentenyl group, a 1-methyl-2-pentenyl group, a 1-methyl-3-pentenyl group, a 1-methyl-4-pentenyl group, a 1-n-butylethenyl group, a 2-methyl-1-pentenyl group, a 2-methyl-2-pentenyl group, a 2-methyl-3-pentenyl group, a 2-methyl-4-pentenyl group, a 2-n-propyl-2-propenyl group, a 3-methyl-1-pentenyl group, a 3-methyl-2-pentenyl group, a 3-methyl-3-pentenyl group, a 3-methyl-4-pentenyl group, a 3-ethyl-3-butenyl group, a 4-methyl-1-pentenyl group, a 4-methyl-2-pentenyl group, a 4-methyl-3-pentenyl group, a 4-methyl-4-pentenyl group, a 1,1-dimethyl-2-butenyl group, a 1,1-dimethyl-3-butenyl group, a 1,2-dimethyl-1-butenyl group, a 1,2-dimethyl-2-butenyl group, a 1,2-dimethyl-3-butenyl group, a 1-methyl-2-ethyl-2-propenyl group, a 1-s-butylethenyl group, a 1,3-dimethyl-1-butenyl group, a 1,3-dimethyl-2-butenyl group, a 1,3-dimethyl-3-butenyl group, a 1-i-butylethenyl group, a 2,2-dimethyl-3-butenyl group, a 2,3-dimethyl-1-butenyl group, a 2,3-dimethyl-2-butenyl group, a 2,3-dimethyl-3-butenyl group, a 2-i-propyl-2-propenyl group, a 3,3-dimethyl-1-butenyl group, a 1-ethyl-1-butenyl group, a 1-ethyl-2-butenyl group, a 1-ethyl-3-butenyl group, a 1-n-propyl-1-propenyl group, a 1-n-propyl-2-propenyl group, a 2-ethyl-1-butenyl group, a 2-ethyl-2-butenyl group, a 2-ethyl-3-butenyl group, a 1,1,2-trimethyl-2-propenyl group, a 1-t-butylethenyl group, a 1-methyl-1-ethyl-2-propenyl group, a 1-ethyl-2-methyl-1-propenyl group, a 1-ethyl-2-methyl-2-propenyl group, a 1-i-propyl-1-propenyl group, a 1-i-propyl-2-propenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, a 1-cyclohexenyl group, a 2-cyclohexenyl group, and a 3-cyclohexenyl group, and examples thereof also include a crosslinked cyclic alkenyl group such as a bicycloheptenyl group (norbornyl group).

In addition, examples of the substituent group in the alkyl group, aryl group, aralkyl group, halogenated alkyl group, halogenated aryl group, halogenated aralkyl group, alkoxyalkyl group, alkoxyaryl group, alkoxyaralkyl group, and alkenyl group described above include an alkyl group, an aryl group, an aralkyl group, a halogenated alkyl group, a halogenated aryl group, a halogenated aralkyl group, an alkoxyalkyl group, an aryloxy group, an alkoxyaryl group, an alkoxyaralkyl group, an alkenyl group, an alkoxy group, and an aralkyloxy group, and specific examples thereof and suitable numbers of carbon atoms thereof include the same as those described above or below.

In addition, the aryloxy group described as the substituent group is a group in which an aryl group is bonded via an oxygen atom (—O—), and specific examples of such an aryl group include the same as those described above. The number of carbon atoms of the aryloxy group is not particularly limited, but is preferably 40 or less, more preferably 30 or less, and still more preferably 20 or less, and specific examples thereof include a phenoxy group and a naphthalene-2-yloxy group, but are not limited thereto.

In addition, when there are two or more substituent groups, the substituent groups may be bonded to each other to form a ring.

Examples of the organic group having an epoxy group include a glycidoxymethyl group, a glycidoxyethyl group, a glycidoxypropyl group, a glycidoxybutyl group, and an epoxycyclohexyl group.

Examples of the organic group having an acryloyl group include an acryloylmethyl group, an acryloylethyl group, and an acryloylpropyl group.

Examples of the organic group having a methacryloyl group include a methacryloylmethyl group, a methacryloylethyl group, and a methacryloylpropyl group.

Examples of the organic group having a mercapto group include a mercaptoethyl group, a mercaptobutyl group, a mercaptohexyl group, a mercaptooctyl group, and a mercaptophenyl group.

Examples of the organic group having an amino group include an amino group, an aminomethyl group, an aminoethyl group, an aminophenyl group, a dimethylaminoethyl group, and a dimethylaminopropyl group, but are not limited thereto. The organic group having an amino group will be described below in more detail.

Examples of the organic group having an alkoxy group include a methoxymethyl group and a methoxyethyl group, but are not limited thereto. However, a group in which an alkoxy group is directly bonded to a silicon atom is excluded.

Examples of the organic group having a sulfonyl group include a sulfonylalkyl group and a sulfonylaryl group, but are not limited thereto.

Examples of the organic group having a cyano group include a cyanoethyl group, a cyanopropyl group, a cyanophenyl group, and a thiocyanate group.

Examples of the organic group having an amino group include an organic group having at least one of a primary amino group, a secondary amino group, and a tertiary amino group. A hydrolysis condensate in which a hydrolyzable silane having a tertiary amino group is hydrolyzed with a strong acid to form a counter cation having a tertiary ammonium group can be preferably used. In addition, the organic group may contain a hetero atom such as an oxygen atom or a sulfur atom in addition to the nitrogen atom constituting the amino group.

Preferable examples of the organic group having an amino group include a group represented by Formula (A1) described below.

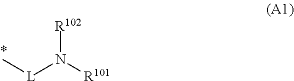

In Formula (A1), R¹⁰¹ and R¹⁰² independently represent a hydrogen atom or a hydrocarbon group, and L independently represents an optionally substituted alkylene group. * represents a bond.

Examples of the hydrocarbon group include an alkyl group, an alkenyl group, and an aryl group, but are not limited thereto. Specific examples of the alkyl group, alkenyl group, and aryl group include the same groups as those described above for R².

In addition, the alkylene group may be either linear or branched, and the number of carbon atoms thereof is usually 1 to 10 and preferably 1 to 5. Examples include linear alkylene groups such as a methylene group, an ethylene group, a trimethylene group, a tetramethylene group, a pentamethylene group, a hexamethylene group, a heptamethylene group, an octamethylene group, a nonamethylene group, and a decamethylene group.

Examples of the organic group having an amino group include an amino group, an aminomethyl group, an aminoethyl group, an aminophenyl group, a dimethylaminoethyl group, and a dimethylaminopropyl group, but are not limited thereto.

### <<X in Formula (A-1)>>

Examples of the alkoxy group in X include the alkoxy group exemplified in the description of R².

Examples of the halogen atom in X include the halogen atom exemplified in the description of R².

The aralkyloxy group is a monovalent group derived by removing a hydrogen atom from a hydroxy group of an aralkyl alcohol, and specific examples of the aralkyl group in the aralkyloxy group include the same groups as those described above.

The number of carbon atoms of the aralkyloxy group is not particularly limited, but can be, for example, 40 or less, preferably 30 or less, and more preferably 20 or less.

Specific examples of the aralkyloxy group include a phenylmethyloxy group (benzyloxy group), a 2-phenylethyleneoxy group, a 3-phenyl-n-propyloxy group, a 4-phenyl-n-butyloxy group, a 5-phenyl-n-pentyloxy group, a 6-phenyl-n-hexyloxy group, a 7-phenyl-n-heptyloxy group, an 8-phenyl-n-octyloxy group, a 9-phenyl-n-nonyloxy group, and a 10-phenyl-n-decyloxy group, but are not limited thereto.

The acyloxy group is a monovalent group derived by removing a hydrogen atom from a carboxyl group (—COOH) of a carboxylic acid compound, and typically includes, but is not limited to, an alkylcarbonyloxy group, an arylcarbonyloxy group, or an aralkylcarbonyloxy group derived by removing a hydrogen atom from a carboxyl group of an alkyl carboxylic acid, an aryl carboxylic acid, or an aralkyl carboxylic acid. Specific examples of the alkyl group, the aryl group, and the aralkyl group in the alkyl carboxylic acid, the aryl carboxylic acid, and the aralkyl carboxylic acid include the same groups as those described above.

Specific examples of the acyloxy group include an acyloxy group having 2 to 20 carbon atoms, and examples thereof include a methylcarbonyloxy group, an ethylcarbonyloxy group, an n-propylcarbonyloxy group, an i-propylcarbonyloxy group, an n-butylcarbonyloxy group, an i-butylcarbonyloxy group, an s-butylcarbonyloxy group, a t-butylcarbonyloxy group, an n-pentylcarbonyloxy group, a 1-methyl-n-butylcarbonyloxy group, a 2-methyl-n-butylcarbonyloxy group, a 3-methyl-n-butylcarbonyloxy group, a 1,1-dimethyl-n-propylcarbonyloxy group, a 1,2-dimethyl-n-propylcarbonyloxy group, a 2,2-dimethyl-n-propylcarbonyloxy group, a 1-ethyl-n-propylcarbonyloxy group, an n-hexylcarbonyloxy group, a 1-methyl-n-pentylcarbonyloxy group, a 2-methyl-n-pentylcarbonyloxy group, a 3-methyl-n-pentylcarbonyloxy group, a 4-methyl-n-pentylcarbonyloxy group, a 1,1-dimethyl-n-butylcarbonyloxy group, a 1,2-dimethyl-n-butylcarbonyloxy group, a 1,3-dimethyl-n-butylcarbonyloxy group, a 2,2-dimethyl-n-butylcarbonyloxy group, a 2,3-dimethyl-n-butylcarbonyloxy group, a 3,3-dimethyl-n-butylcarbonyloxy group, a 1-ethyl-n-butylcarbonyloxy group, a 2-ethyl-n-butylcarbonyloxy group, a 1,1,2-trimethyl-n-propylcarbonyloxy group, a 1,2,2-trimethyl-n-propylcarbonyloxy group, a 1-ethyl-1-methyl-n-propylcarbonyloxy group, a 1-ethyl-2-methyl-n-propylcarbonyloxy group, a phenylcarbonyloxy group, and a tosylcarbonyloxy group.

Specific examples of the hydrolyzable silane (A) having a carbon-carbon triple bond include, for example, the compounds described below, but the hydrolyzable silane (A) having a carbon-carbon triple bond is not limited to the compounds described below.

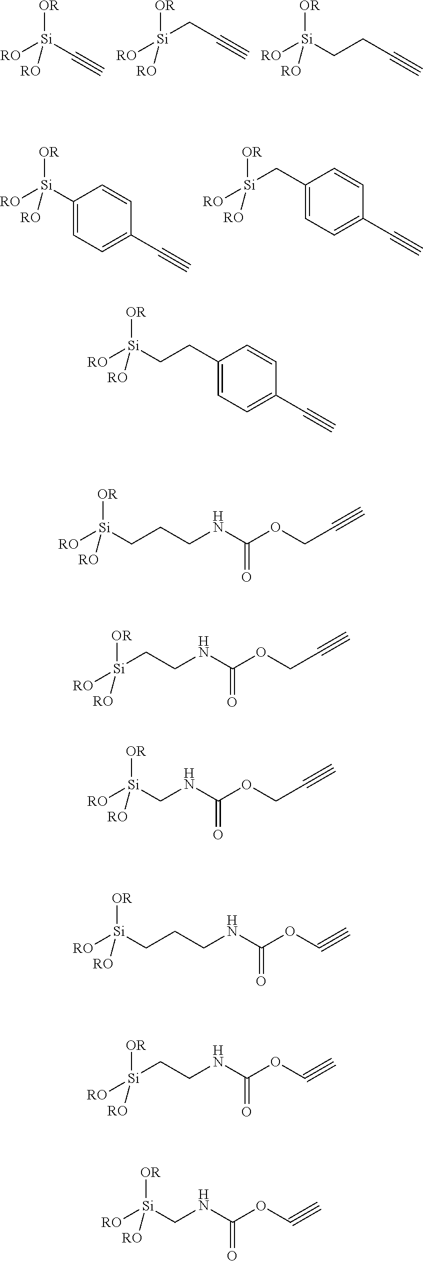

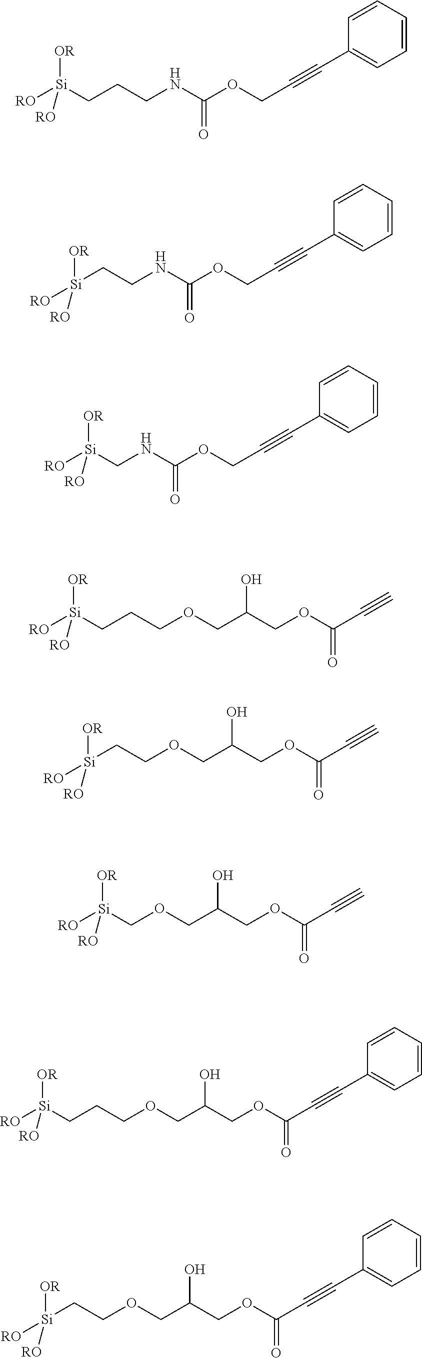

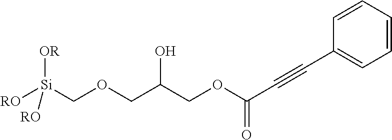

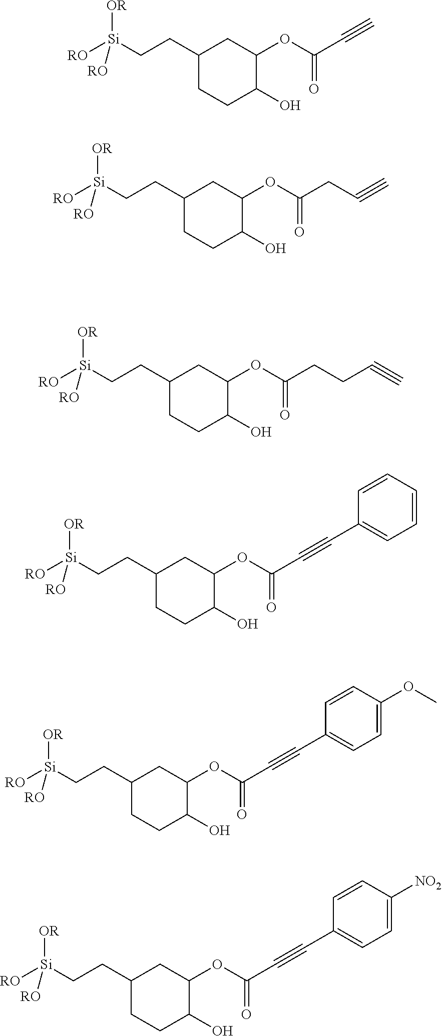

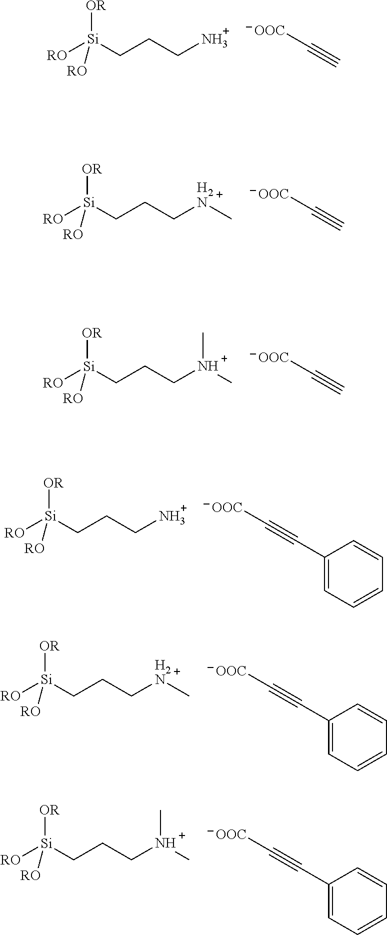

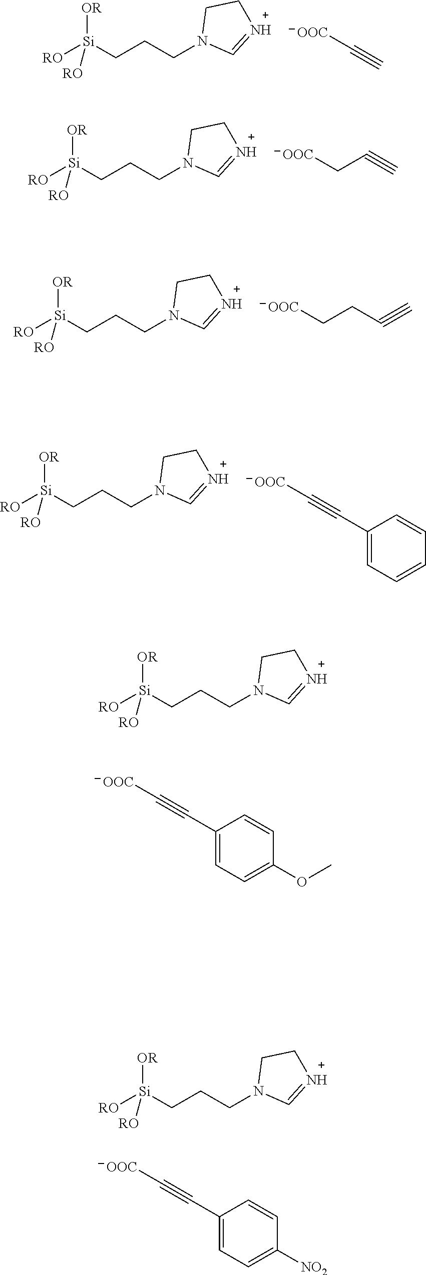

In the formulae, R represents a methyl group or an ethyl group.

In the first embodiment, the amount of the hydrolyzable silane (A) in synthesizing polysiloxane [A] containing a constituent unit derived from the hydrolyzable silane (A) having a carbon-carbon triple bond is preferably 0.01 to 100 parts by mass, more preferably 0.05 to 50 parts by mass, still more preferably 0.1 to 30 parts by mass, and particularly preferably 1 to 20 parts by mass, with respect to 100 parts by mass of the total amount of the hydrolyzable silane used for synthesizing the polysiloxane, from the viewpoint of more sufficiently obtaining the effect of the present invention.

In the second embodiment, the content of the hydrolyzable silane (A) having a carbon-carbon triple bond as component [B] in the composition for forming a silicon-containing resist underlayer film is preferably 0.01 to 100 parts by mass, more preferably 0.05 to 50 parts by mass, still more preferably 0.1 to 30 parts by mass, and particularly preferably 1 to 20 parts by mass, with respect to 100 parts by mass of polysiloxane [A′], from the viewpoint of more sufficiently obtaining the effect of the present invention.

### <Component [A] and Component [A′]: Polysiloxane>

The polysiloxane as component [A] is not particularly limited as long as it is a polymer having a carbon-carbon triple bond and having a siloxane bond.

The polysiloxane as component [A′] is not particularly limited as long as it is a polymer having a siloxane bond. The polysiloxane as component [A′] may be a polysiloxane as component [A].

The polysiloxane may be a modified polysiloxane in which a part of silanol groups is modified, for example, a polysiloxane modified product in which a part of silanol groups is alcohol-modified or acetal-protected.

In addition, the polysiloxane may be, as an example, a hydrolysis condensate of a hydrolyzable silane, or may be a modified product in which at least a part of silanol groups of the hydrolysis condensate is alcohol-modified or acetal-protected (hereinafter, sometimes referred to as a “modified product of a hydrolysis condensate”). The hydrolyzable silane related to the hydrolysis condensate may contain one or two or more hydrolyzable silanes.

In addition, the polysiloxane as component [A] or component [A′] can have a structure having any of a cage type, a ladder type, a linear type, and a branched type main chain. Further, as the polysiloxane as component [A′], a commercially available polysiloxane can be used.

Note that, in the present invention, the “hydrolysis condensate” of the hydrolyzable silane, that is, the product of the hydrolysis condensation includes not only a polyorganosiloxane polymer that is a condensate in which the condensation is completely completed but also a polyorganosiloxane polymer that is a partial hydrolysis condensate in which the condensation is not completely completed. Such a partial hydrolysis condensate is also a polymer obtained by hydrolysis and condensation of a hydrolyzable silane similarly to a condensate in which the condensation is completely completed, but the hydrolysis is partially stopped and the hydrolyzable silane is not condensed, and therefore a Si—OH group remains. In addition, in addition to the hydrolysis condensate, an uncondensed hydrolysate (complete hydrolysate, partial hydrolysate) or a monomer (hydrolyzable silane) may remain in the composition for forming a silicon-containing resist underlayer film.

Note that, in the present specification, the “hydrolyzable silane” may also be simply referred to as a “silane compound”.

Examples of the polysiloxane as component [A] include a hydrolysis condensate of a hydrolyzable silane including the hydrolyzable silane (A) having a carbon-carbon triple bond or a modified product thereof.

Examples of the polysiloxane as component [A] include a hydrolysis condensate of a hydrolyzable silane including the hydrolyzable silane (A) having a carbon-carbon triple bond and at least one hydrolyzable silane represented by Formula (1) described below, or a modified product thereof.

Examples of the polysiloxane as component [A′] include a hydrolysis condensate of a hydrolyzable silane containing at least one hydrolyzable silane represented by Formula (1) described below, or a modified product thereof.

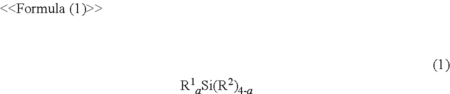

In Formula (1), R¹ is a group bonded to a silicon atom and independently represents an optionally substituted alkyl group, an optionally substituted aryl group, an optionally substituted aralkyl group, an optionally substituted halogenated alkyl, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group, or a combination of two or more thereof.

In addition, R² is a group or atom bonded to a silicon atom, and independently represents an alkoxy group, an aralkyloxy group, an acyloxy group, or a halogen atom.
a represents an integer of 0 to 3.

Specific examples of each group and atom in R¹ in Formula (1) and the suitable number of carbon atoms thereof may include the groups and the number of carbon atoms described above for R² in Formula (A-1).

Specific examples of each group and atom in R² in Formula (1) and the suitable number of carbon atoms thereof may include the groups, atoms, and the number of carbon atoms described above for X in Formula (A-1).

### <<<Specific Example of Hydrolyzable Silane Represented by Formula (1)>>>

Specific examples of the hydrolyzable silane represented by Formula (1) include tetramethoxysilane, tetrachlorosilane, tetraacetoxysilane, tetraethoxysilane, tetra-n-propoxysilane, tetra-i-propoxysilane, tetra-n-butoxysilane, methyltrimethoxysilane, methyltrichlorosilane, methyltriacetoxysilane, methyltriethoxysilane, methyltripropoxysilane, methyltributoxysilane, methyltriamyloxysilane, methyltriphenoxysilane, methyltribenzyloxysilane, methyltriphenethyloxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl)propyltrimethoxysilane, γ-(3,4-epoxycyclohexyl)propyltriethoxysilane, δ-(3,4-epoxycyclohexyl)butyltrimethoxysilane, δ-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, ethyltrimethoxysilane, ethyltriethoxysilane, vinyltrimethoxysilane, vinyltriethoxysilane, vinyltrichlorosilane, vinyltriacetoxysilane, methylvinyldimethoxysilane, methylvinyldiethoxysilane, methylvinyldichlorosilane, methylvinyldiacetoxysilane, dimethylvinylmethoxysilane, dimethylvinylethoxysilane, dimethylvinylchlorosilane, dimethylvinylacetoxysilane, divinyldimethoxysilane, divinyldiethoxysilane, divinyldichlorosilane, divinyldiacetoxysilane, γ-glycidoxypropylvinyldimethoxysilane, γ-glycidoxypropylvinyldiethoxysilane, allyltrimethoxysilane, allyltriethoxysilane, allyltrichlorosilane, allyltriacetoxysilane, allylmethyldimethoxysilane, allylmethyldiethoxysilane, allylmethyldichlorosilane, allylmethyldiacetoxysilane, allyldimethylmethoxysilane, allyldimethylethoxysilane, allyldimethylchlorosilane, allyldimethylacetoxysilane, diallyldimethoxysilane, diallyldiethoxysilane, diallyldichlorosilane, diallyldiacetoxysilane, 3-allylaminopropyltrimethoxysilane, 3-allylaminopropyltriethoxysilane, p-styryltrimethoxysilane, phenyltrimethoxysilane, phenyltriethoxysilane, phenyltrichlorosilane, phenyltriacetoxysilane, phenylmethyldimethoxysilane, phenylmethyldiethoxysilane, phenylmethyldichlorosilane, phenylmethyldiacetoxysilane, phenyldimethylmethoxysilane, phenyldimethylethoxysilane, phenyldimethylchlorosilane, phenyldimethylacetoxysilane, diphenylmethylmethoxysilane, diphenylmethylethoxysilane, diphenylmethylchlorosilane, diphenylmethylacetoxysilane, diphenyldimethoxysilane, diphenyldiethoxysilane, diphenyldichlorosilane, diphenyldiacetoxysilane, triphenylmethoxysilane, triphenylethoxysilane, triphenylacetoxysilane, triphenylchlorosilane, 3-phenylaminopropyltrimethoxysilane, 3-phenylaminopropyltriethoxysilane, dimethoxymethyl-3-(3-phenoxypropylthiopropyl)silane, triethoxy((2-methoxy-4-(methoxymethyl)phenoxy)methyl)silane, benzyltrimethoxysilane, benzyltriethoxysilane, benzylmethyldimethoxysilane, benzylmethyldiethoxysilane, benzyldimethylmethoxysilane, benzyldimethylethoxysilane, benzyldimethylchlorosilane, phenethyltrimethoxysilane, phenethyltriethoxysilane, phenethyltrichlorosilane, phenethyltriacetoxysilane, phenethylmethyldimethoxysilane, phenethylmethyldiethoxysilane, phenethylmethyldichlorosilane, phenethylmethyldiacetoxysilane, methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenethyltriethoxysilane, methoxyphenethyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, i-propoxyphenyltrimethoxysilane, i-propoxyphenyltriethoxysilane, i-propoxyphenyltriacetoxysilane, i-propoxyphenyltrichlorosilane, i-propoxybenzyltrimethoxysilane, i-propoxybenzyltriethoxysilane, i-propoxybenzyltriacetoxysilane, i-propoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxybenzyltrichlorosilane, methoxynaphthyltrimethoxysilane, methoxynaphthyltriethoxysilane, methoxynaphthyltriacetoxysilane, methoxynaphthyltrichlorosilane, ethoxynaphthyltrimethoxysilane, ethoxynaphthyltriethoxysilane, ethoxynaphthyltriacetoxysilane, ethoxynaphthyltrichlorosilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, β-cyanoethyltriethoxysilane, thiocyanate propyltriethoxysilane, chloromethyltrimethoxysilane, chloromethyltriethoxysilane, triethoxysilylpropyldiallyl isocyanurate, bicyclo[2,2,1]heptenyltriethoxysilane, benzenesulfonylpropyltriethoxysilane, benzenesulfonamidopropyltriethoxysilane, dimethylaminopropyltrimethoxysilane, dimethyldimethoxysilane, phenylmethyldimethoxysilane, dimethyldiethoxysilane, phenylmethyldiethoxysilane, γ-chloropropylmethyldimethoxysilane, γ-chloropropylmethyldiethoxysilane, dimethyldiacetoxysilane, γ-methacryloxypropylmethyldimethoxysilane, γ-methacryloxypropylmethyldiethoxysilane, γ-mercaptopropylmethyldimethoxysilane, γ-mercaptomethyldiethoxysilane, methylvinyldimethoxysilane, methylvinyldiethoxysilane, silanes represented by Formulae (A-1) to (A-41) described below, silanes represented by Formulae (1-1) to (1-225) and (1-246) to (1-290) described below, and the like, but are not limited thereto.

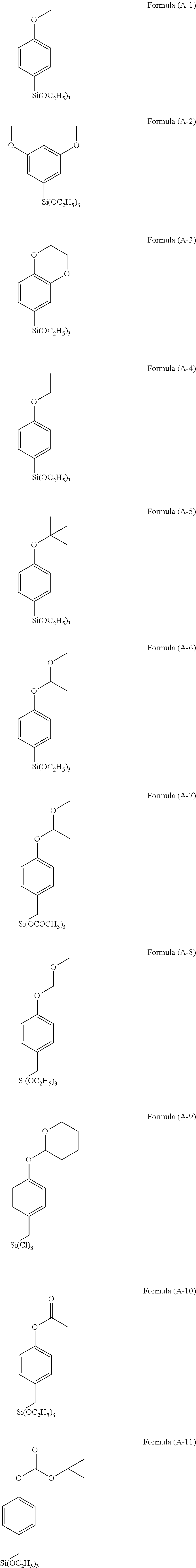

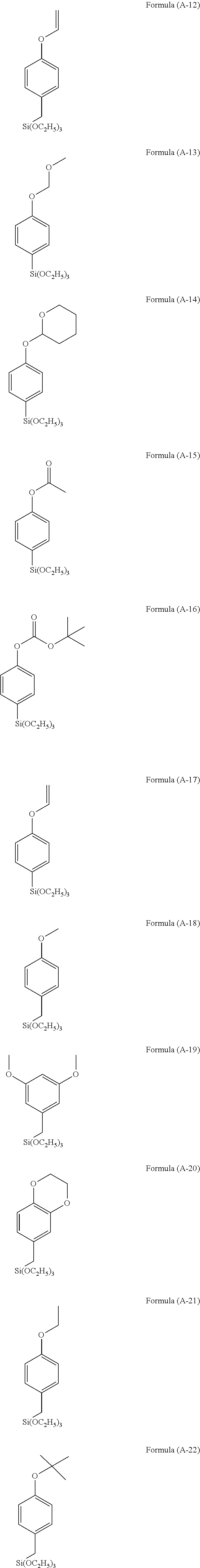

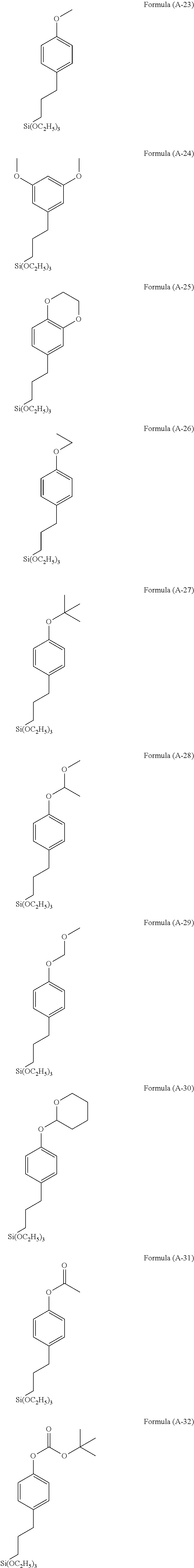

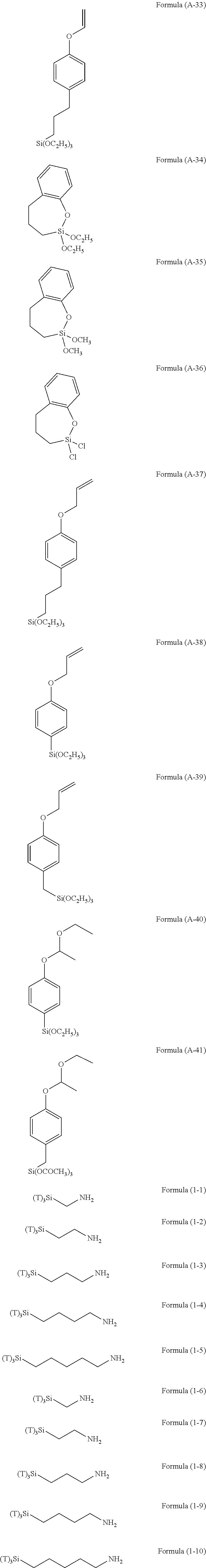

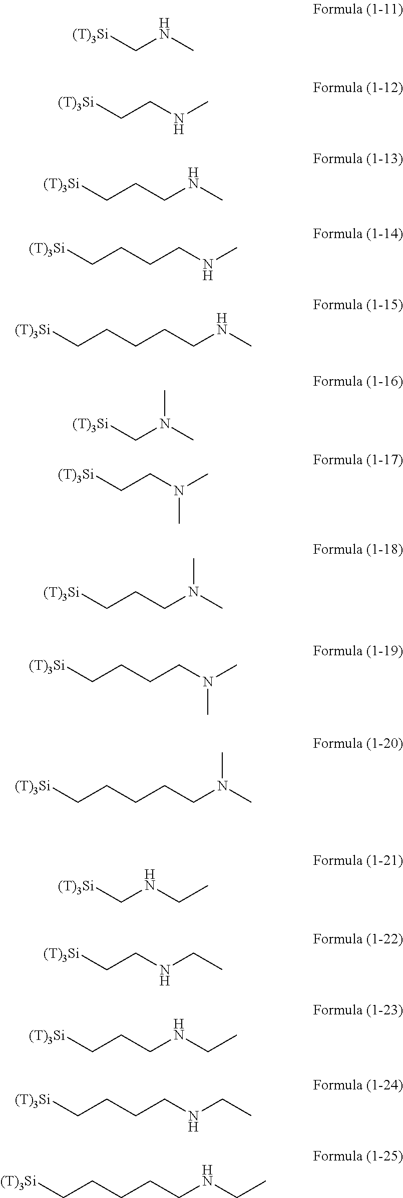

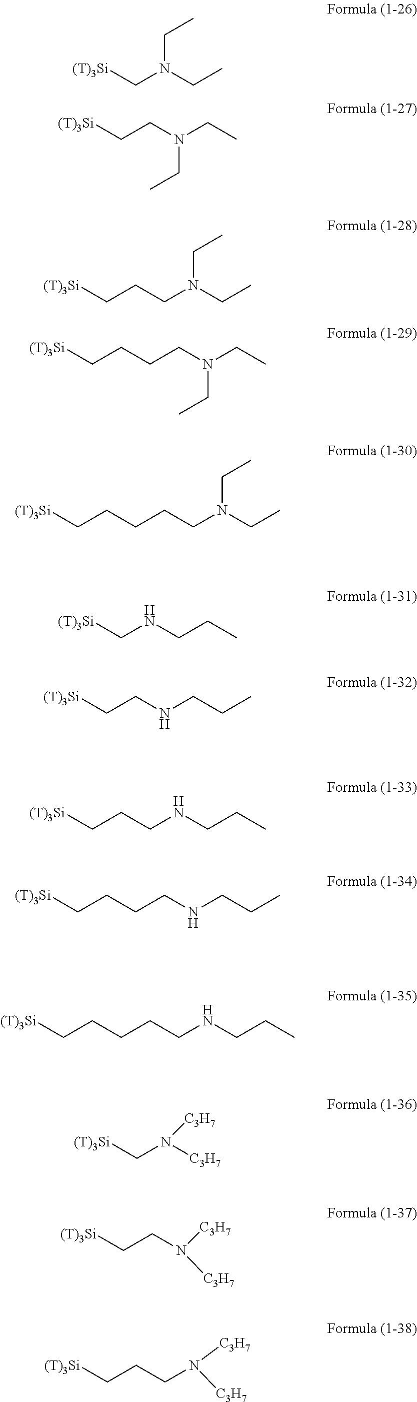

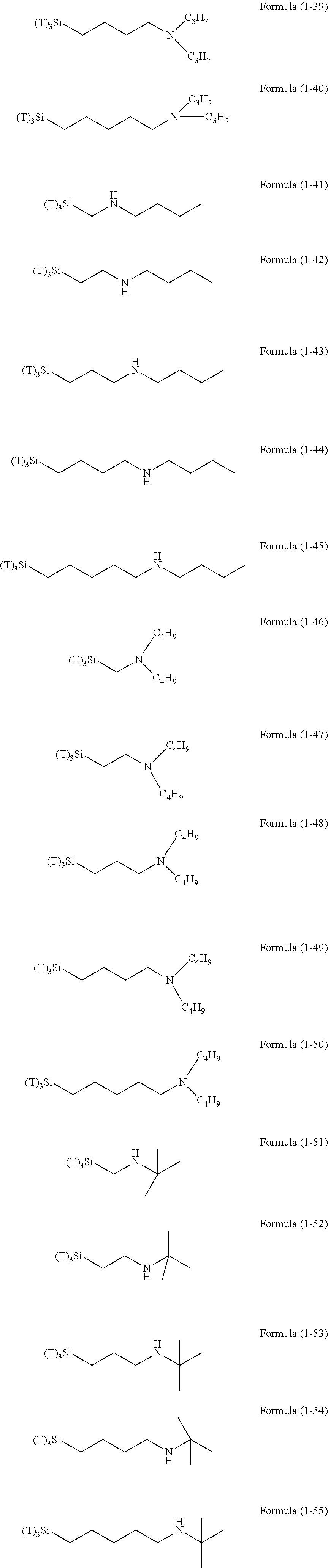

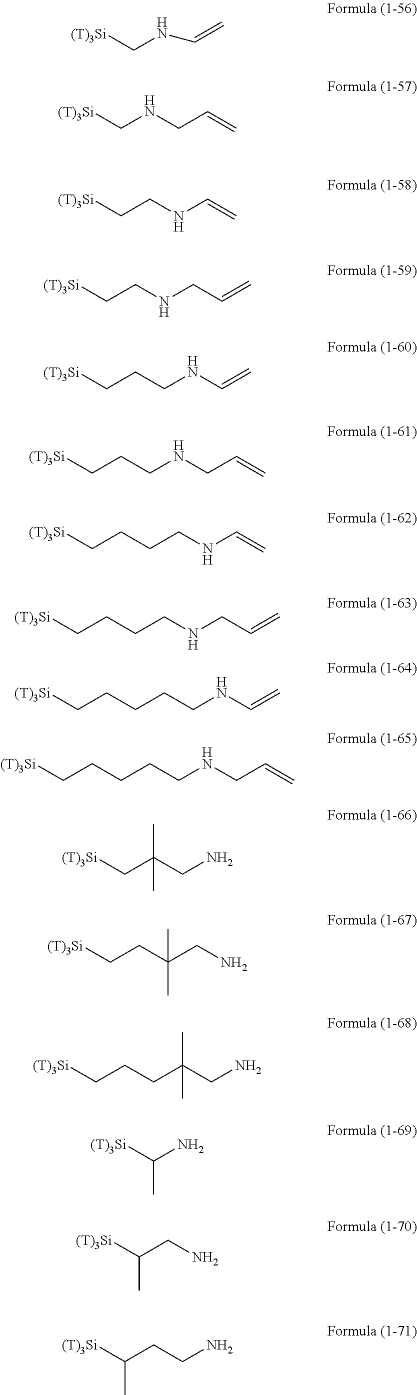

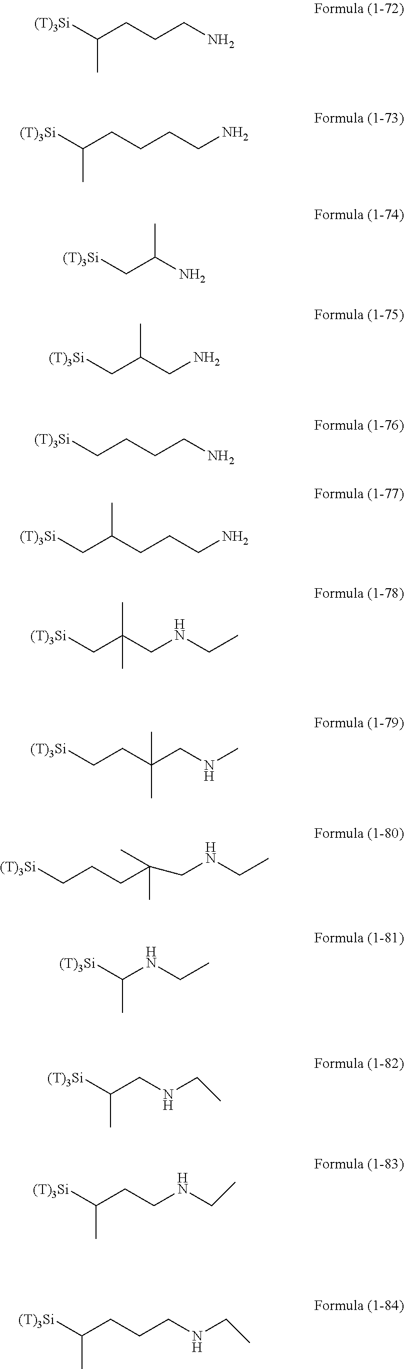

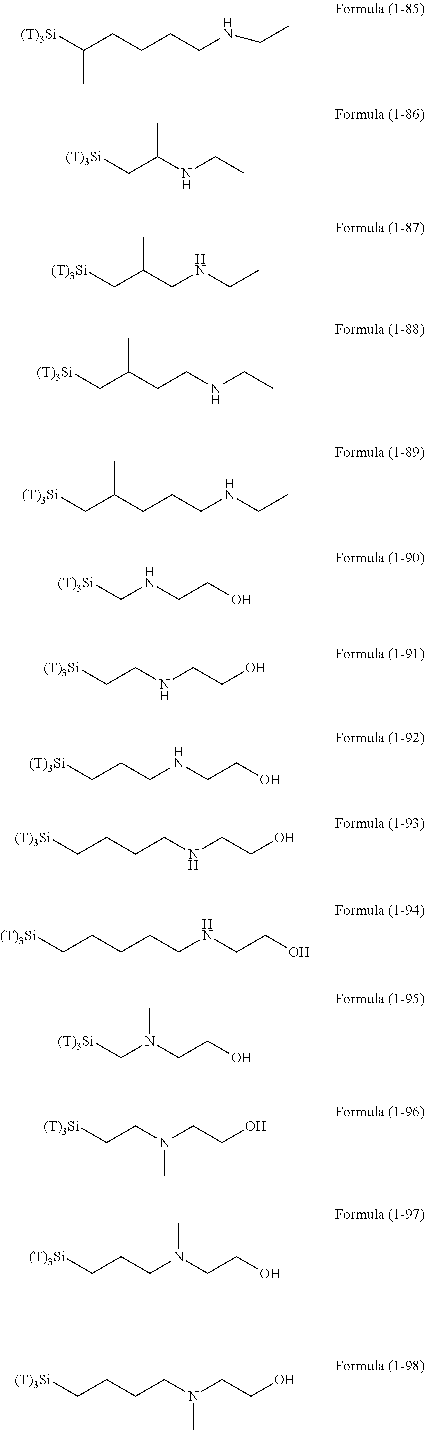

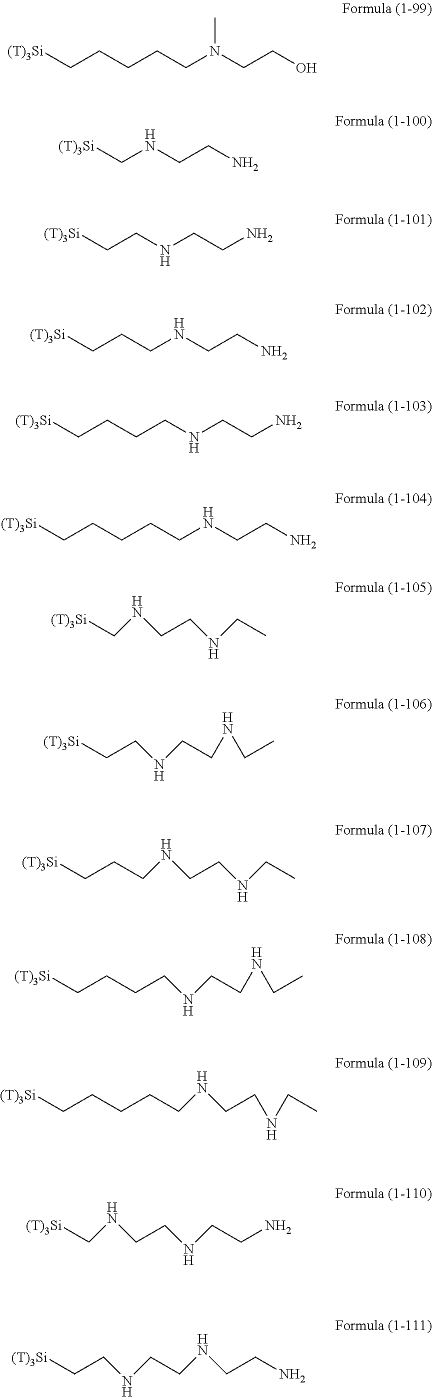

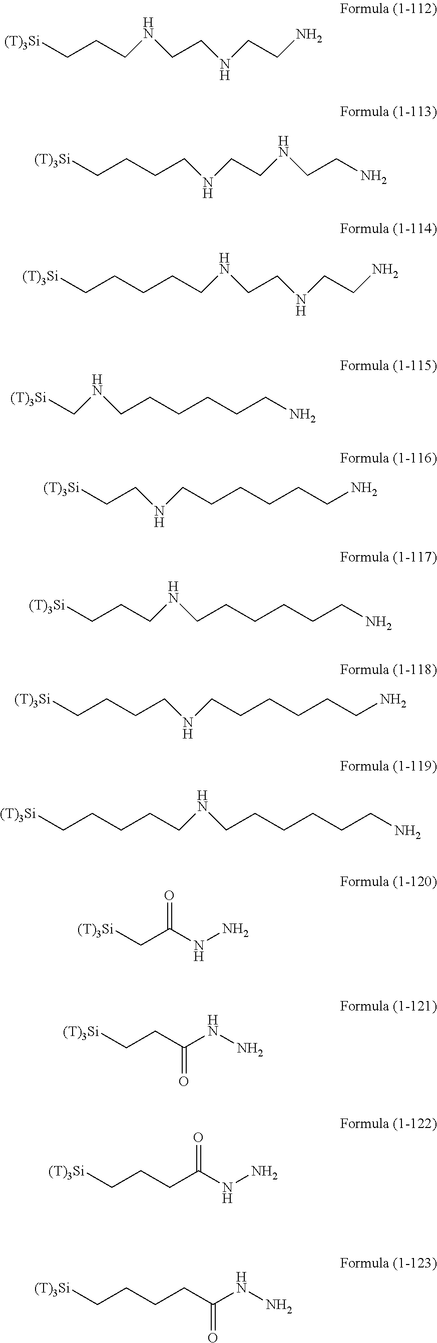

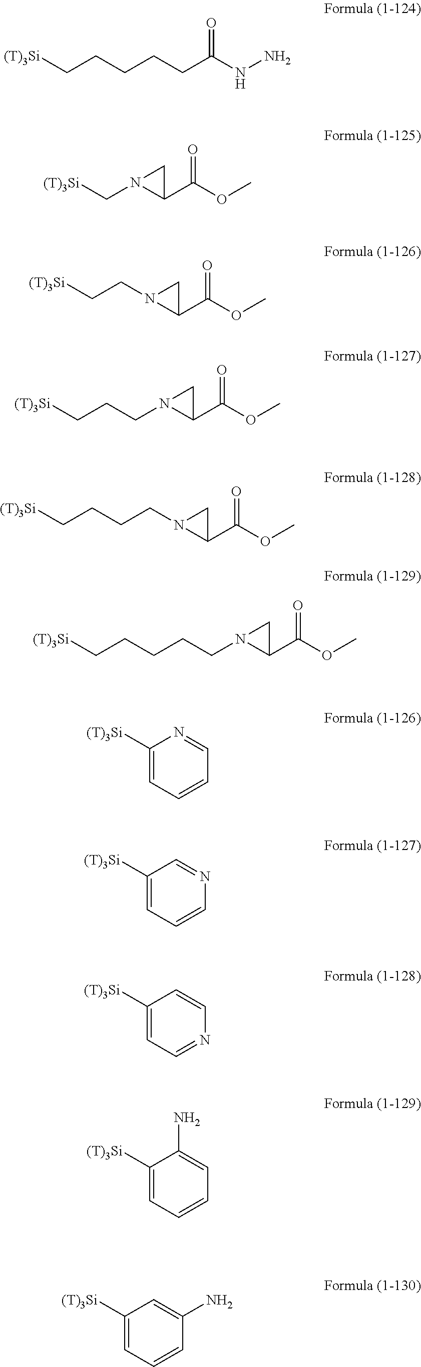

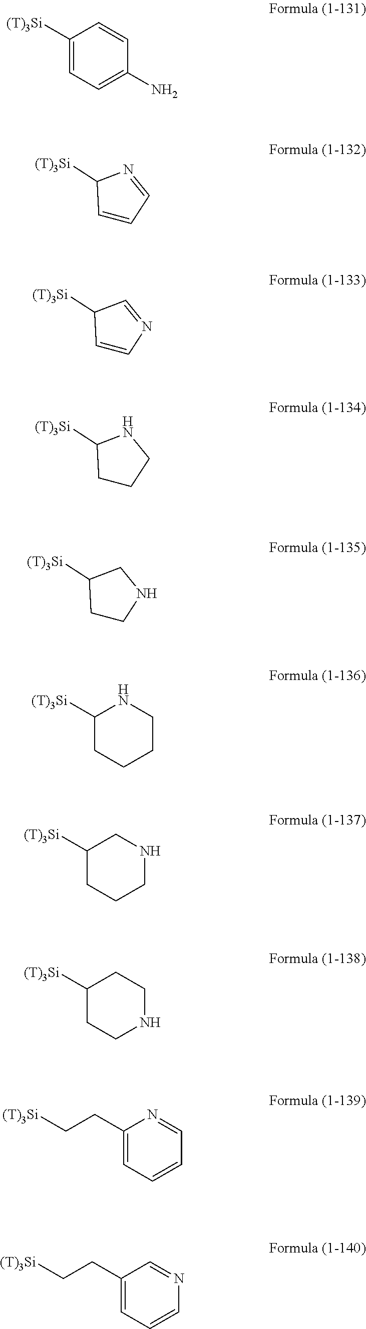

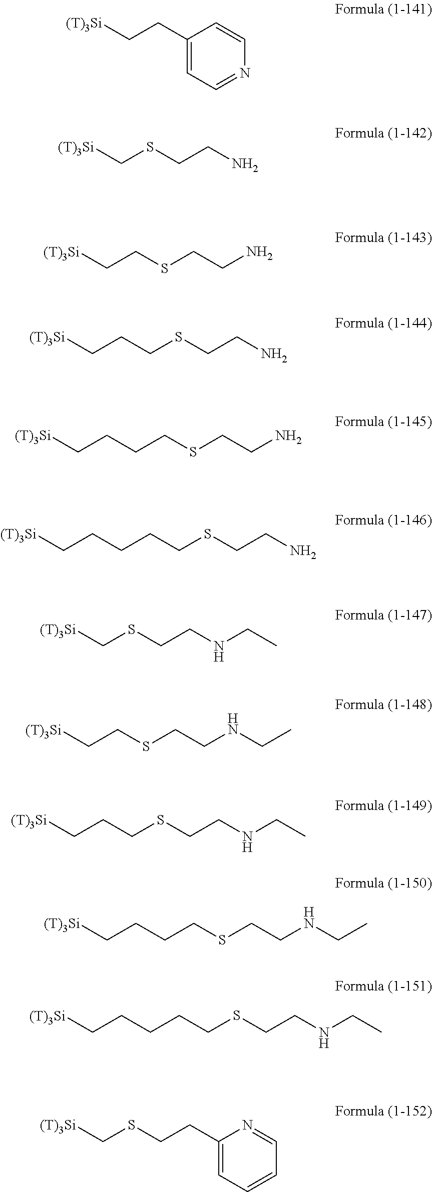

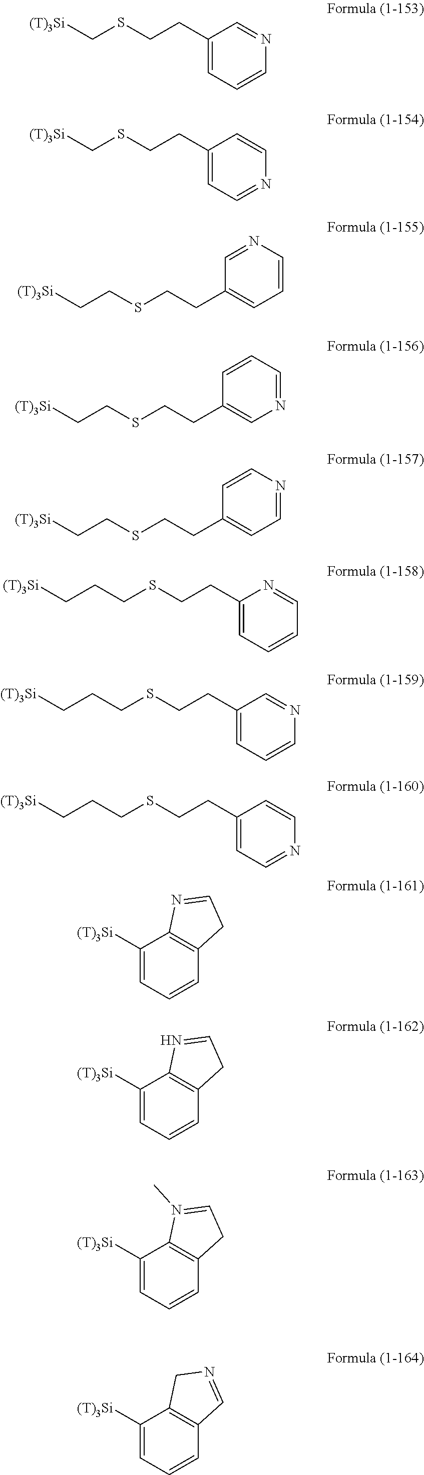

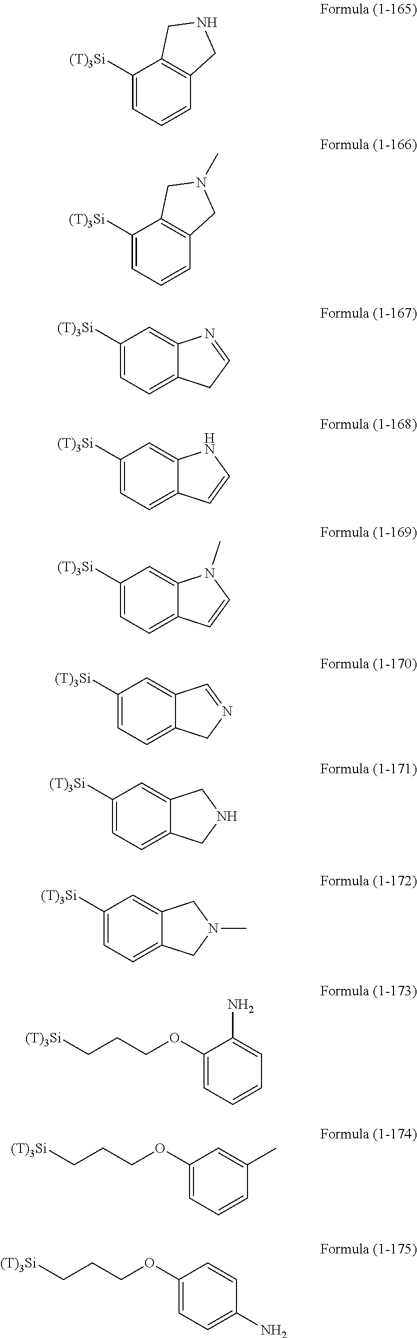

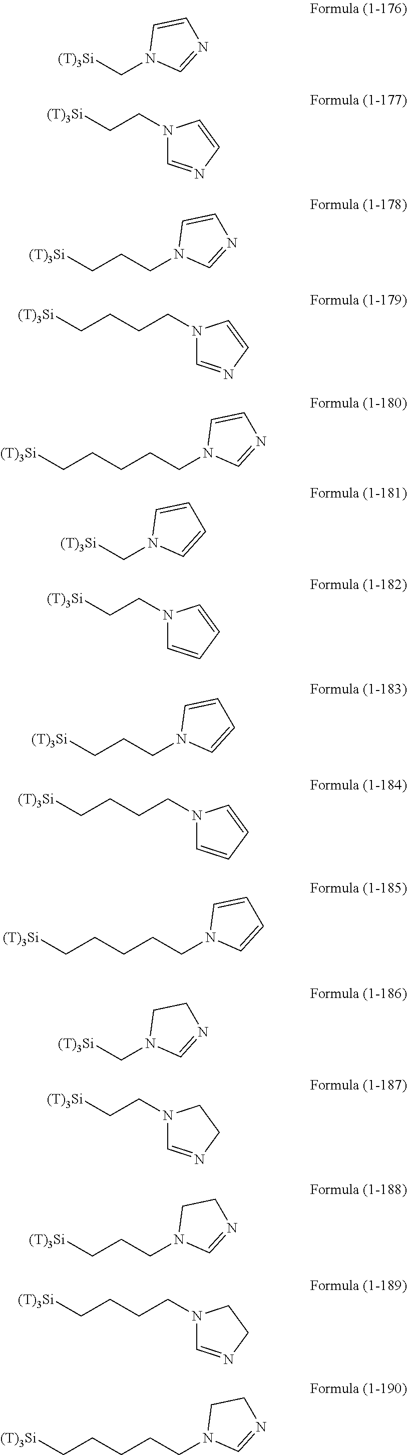

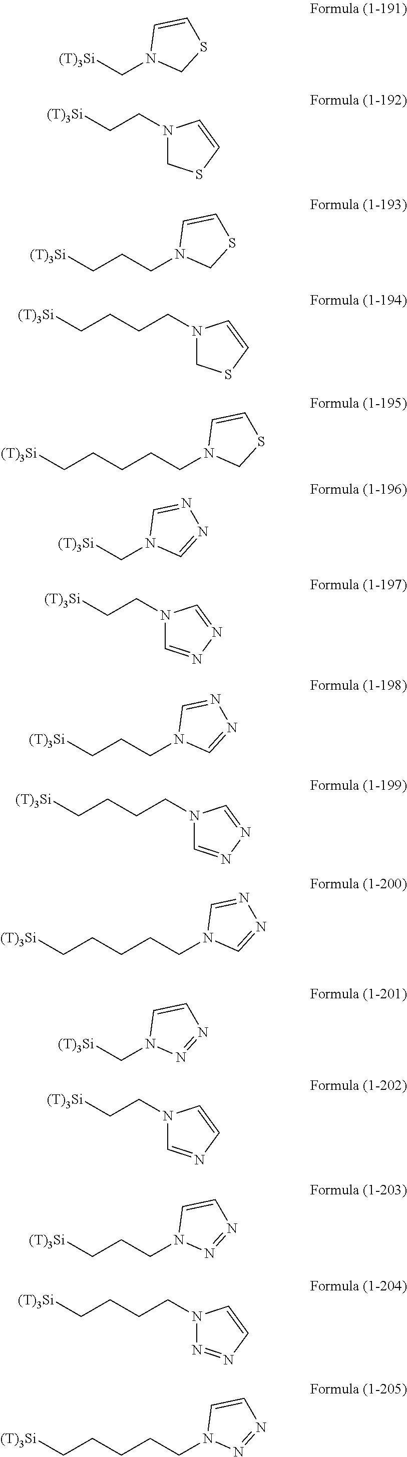

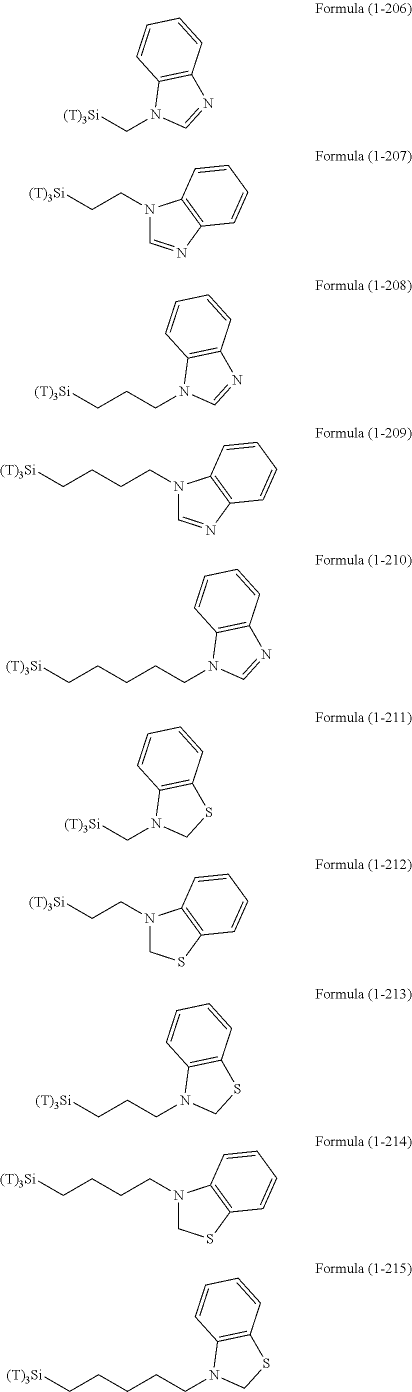

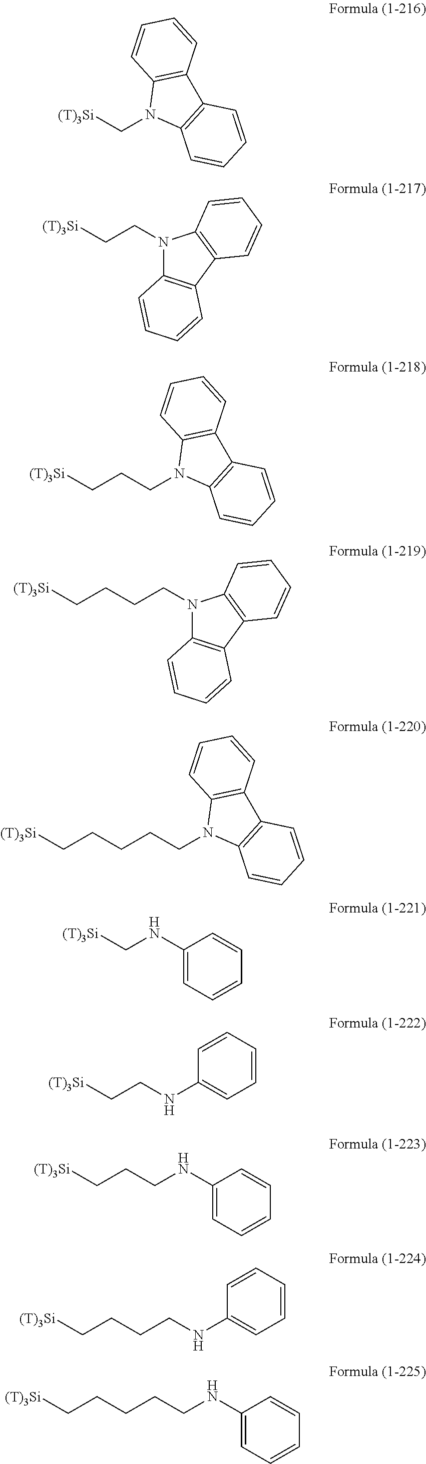

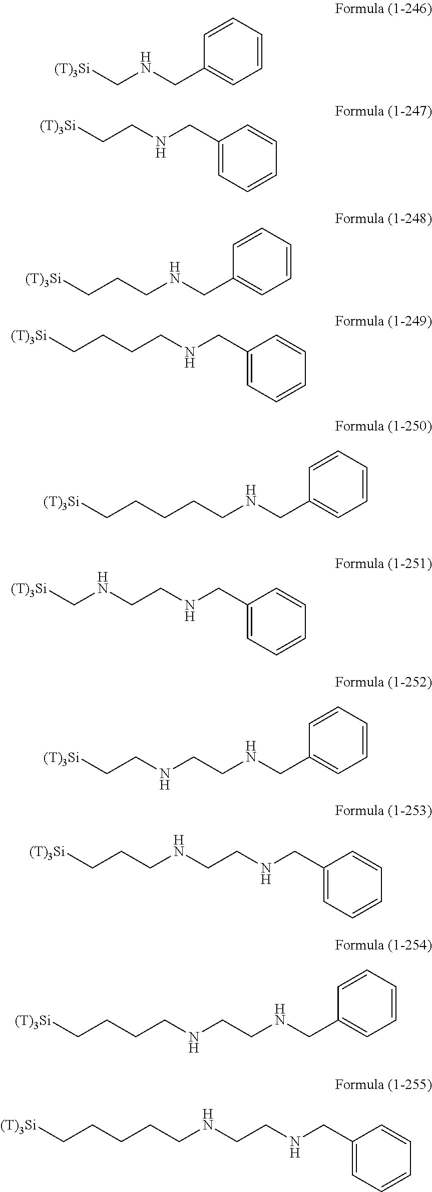

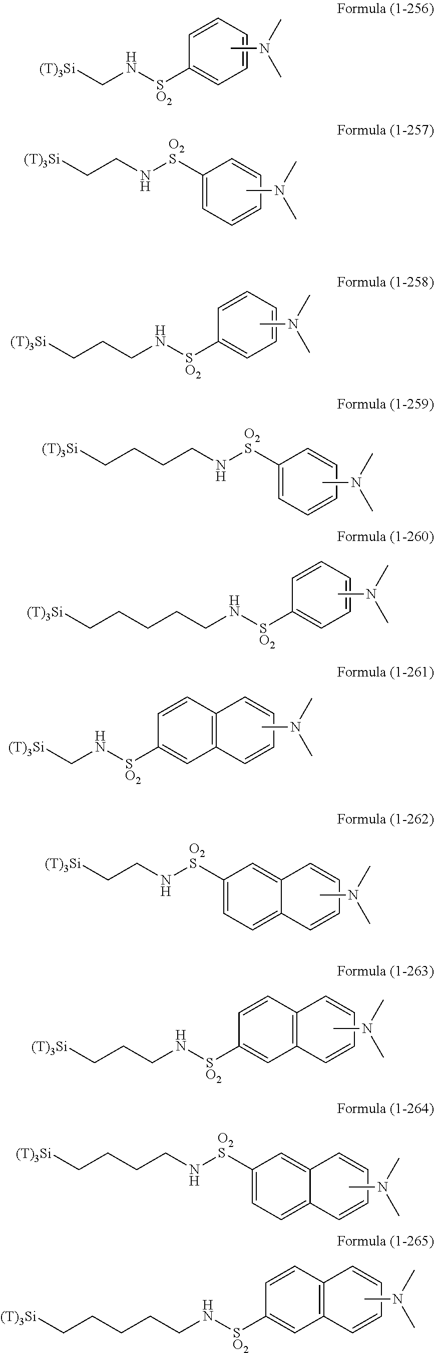

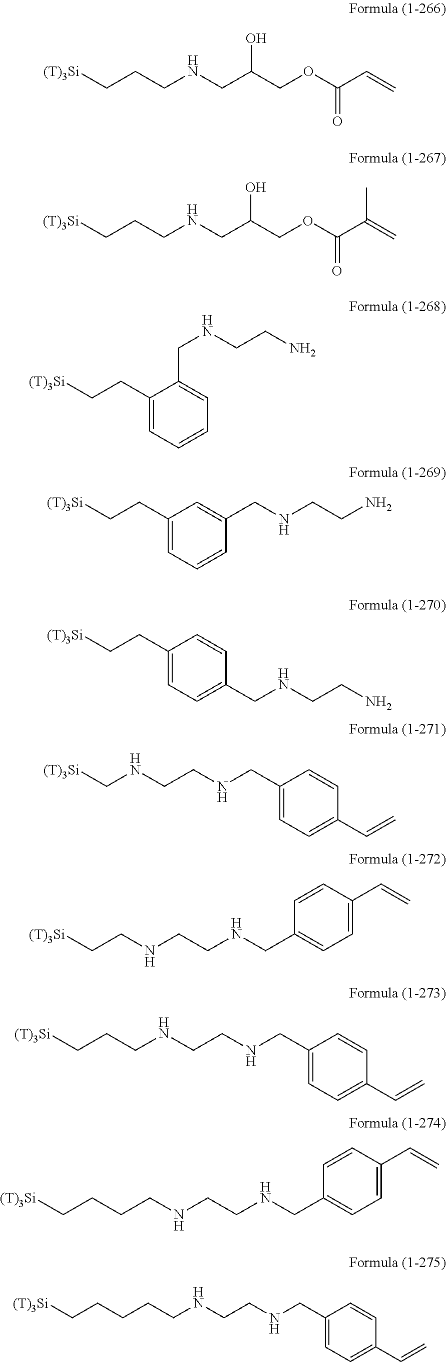

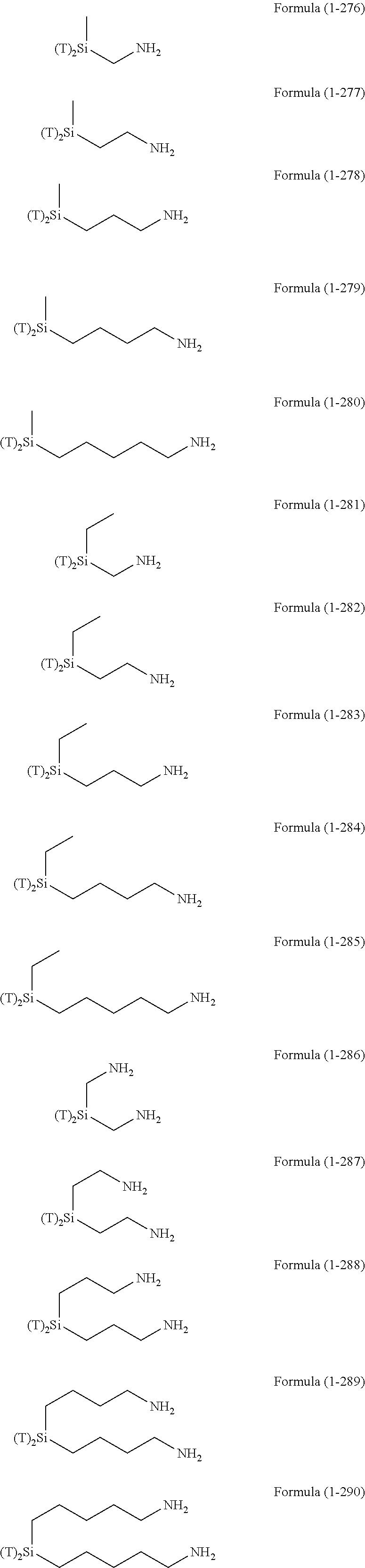

In Formulae (1-1) to (1-225) and (1-246) to (1-290), T independently represents an alkoxy group, an acyloxy group, or a halogen group, and for example, preferably represents a methoxy group or an ethoxy group.

In addition, examples of polysiloxane [A] include a hydrolysis condensate of a hydrolyzable silane including the hydrolyzable silane (A) having a carbon-carbon triple bond and a hydrolyzable silane represented by Formula (2) described below, or a modified product thereof.

In addition, examples of polysiloxane [A] include a hydrolysis condensate of a hydrolyzable silane including the hydrolyzable silane (A) having a carbon-carbon triple bond, a hydrolyzable silane represented by Formula (1), and a hydrolyzable silane represented by Formula (2) described below, or a modified product thereof.

Examples of polysiloxane [A′] include a hydrolysis condensate of a hydrolyzable silane including the hydrolyzable silane represented by Formula (2) described below together with the hydrolyzable silane represented by Formula (1) or in place of the hydrolyzable silane represented by Formula (1), or a modified product thereof.

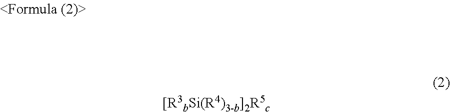

In Formula (2), R³ is a group bonded to a silicon atom and independently represents an optionally substituted alkyl group, an optionally substituted aryl group, an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group, or a combination of two or more thereof.

In addition, R⁴ is a group or atom bonded to a silicon atom, and independently represents an alkoxy group, an aralkyloxy group, an acyloxy group, or a halogen atom.

R⁵ is a group bonded to a silicon atom, and independently represents an alkylene group or an arylene group.

b represents 0 or 1, and c represents 0 or 1.

Specific examples of each group and atom in R³ and the suitable number of carbon atoms thereof may include the groups and the number of carbon atoms described above for R² in Formula (A-1).

Specific examples of each group and atom in R⁴ and the suitable number of carbon atoms thereof may include the groups, atoms, and the number of carbon atoms described above for X in Formula (A-1).

Specific examples of the alkylene group in R⁵ include alkylene groups such as linear alkylene groups such as a methylene group, an ethylene group, a trimethylene group, a tetramethylene group, a pentamethylene group, a hexamethylene group, a heptamethylene group, an octamethylene group, a nonamethylene group, and a decamethylene group, and branched alkylene groups such as a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, and a 1-ethyltrimethylene group, alkanetriyl groups such as a methanetriyl group, an ethane-1,1,2-triyl group, an ethane-1,2,2-triyl group, an ethane-2,2,2-triyl group, a propane-1,1,1-triyl group, a propane-1,1,2-triyl group, a propane-1,2,3-triyl group, a propane-1,2,2-triyl group, a propane-1,1,3-triyl group, a butane-1,1,1-triyl group, a butane-1,1,2-triyl group, a butane-1,1,3-triyl group, a butane-1,2,3-triyl group, a butane-1,2,4-triyl group, a butane-1,2,2-triyl group, a butane-2,2,3-triyl group, a 2-methylpropane-1,1,1-triyl group, a 2-methylpropan-1,1,2-triyl group, and a 2-methylpropane-1,1,3-triyl group, and the like, but are not limited thereto.

Specific examples of the arylene group in R⁵ include a 1,2-phenylene group, a 1,3-phenylene group, and a 1,4-phenylene group; groups derived by removing two hydrogen atoms on the aromatic ring of a condensed ring aromatic hydrocarbon compound such as a 1,5-naphthalenediyl group, a 1,8-naphthalenediyl group, a 2,6-naphthalenediyl group, a 2,7-naphthalenediyl group, a 1,2-anthracenediyl group, a 1,3-anthracenediyl group, a 1,4-anthracenediyl group, a 1,5-anthracenediyl group, a 1,6-anthracenediyl group, a 1,7-anthracenediyl group, a 1,8-anthracenediyl group, a 2,3-anthracenediyl group, a 2,6-anthracenediyl group, a 2,7-anthracenediyl group, a 2,9-anthracenediyl group, a 2,10-anthracenediyl group, and a 9,10-anthracenediyl group; groups derived by removing two hydrogen atoms on the aromatic ring of a ring-linked aromatic hydrocarbon compound of a 4,4′-biphenyldiyl group and a 4,4″-paraterphenyldiyl group, and the like, but are not limited thereto.

b is preferably 0.

c is preferably 1.

Specific examples of the hydrolyzable silane represented by Formula (2) include methylenebistrimethoxysilane, methylenebistrichlorosilane, methylenebistriacetoxysilane, ethylenebistriethoxysilane, ethylenebistrichlorosilane, ethylenebistriacetoxysilane, propylenebistriethoxysilane, butylenebistrimethoxysilane, phenylenebistrimethoxysilane, phenylenebistriethoxysilane, phenylenebismethyldiethoxysilane, phenylenebismethyldimethoxysilane, naphthylenebistrimethoxysilane, bistrimethoxydisilane, bistriethoxydisilane, bisethyldiethoxydisilane, and bismethyldimethoxydisilane, but are not limited thereto.

Examples of polysiloxane [A] include a hydrolysis condensate of a hydrolyzable silane including the hydrolyzable silane (A) having a carbon-carbon triple bond, a hydrolyzable silane represented by Formula (1), and/or a hydrolyzable silane represented by Formula (2) and other hydrolyzable silanes described below, or a modified product thereof.

Examples of polysiloxane [A′] include a hydrolysis condensate of a hydrolyzable silane including the hydrolyzable silane represented by Formula (1) and/or the hydrolyzable silane represented by Formula (2) and other hydrolyzable silanes described below, or a modified product thereof.

Examples of the other hydrolyzable silanes include a silane compound having an onium group in the molecule, a silane compound having a cyclic urea skeleton in the molecule, and the like, but are not limited thereto.

### <<Silane Compound (Hydrolyzable Organosilane) Having Onium Group in Molecule>>

The silane compound having an onium group in the molecule is expected to effectively and efficiently promote a crosslinking reaction of the hydrolyzable silane.

A suitable example of the silane compound having an onium group in the molecule is represented by Formula (3).

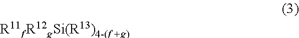

R¹¹ is a group bonded to a silicon atom, and represents an onium group or an organic group having the onium group.

R¹² is a group bonded to a silicon atom and independently represents an optionally substituted alkyl group, an optionally substituted aryl group, an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or an organic group having an epoxy group, an organic group having an acryloyl group, an organic group having a methacryloyl group, an organic group having a mercapto group, an organic group having an amino group, or an organic group having a cyano group, or a combination of two or more thereof.

R¹³ is a group or atom bonded to a silicon atom, and independently represents an alkoxy group, an aralkyloxy group, an acyloxy group, or a halogen atom.

f represents 1 or 2, g represents 0 or 1, and 1≤f+g≤2 is satisfied.

Specific examples of an alkyl group, an aryl group, an aralkyl group, a halogenated alkyl group, a halogenated aryl group, a halogenated aralkyl group, an alkoxyalkyl group, an alkoxyaryl group, an alkoxyaralkyl group, an alkenyl group, and an organic group having an epoxy group, an organic group having an acryloyl group, an organic group having a methacryloyl group, an organic group having a mercapto group, an organic group having an amino group, an organic group having a cyano group, an alkoxy group, an aralkyloxy group, an acyloxy group, and a halogen atom, and specific examples of substituent groups of an alkyl group, an aryl group, an aralkyl group, a halogenated alkyl group, a halogenated aryl group, a halogenated aralkyl group, an alkoxyalkyl group, an alkoxyaryl group, an alkoxyaralkyl group, and an alkenyl group, and suitable numbers of carbon atoms thereof include, for R¹², those described above for R² in Formula (A-1) and, for R¹³, those described above for X in Formula (A-1).

More specifically, specific examples of the onium group include a cyclic ammonium group or a chain ammonium group, and a tertiary ammonium group or a quaternary ammonium group is preferable.

That is, suitable specific examples of the onium group or the organic group having the onium group include a cyclic ammonium group, a chain ammonium group, or an organic group having at least one of the cyclic ammonium group and the chain ammonium group, and a tertiary ammonium group, a quaternary ammonium group, or an organic group having at least one of the tertiary ammonium group and the quaternary ammonium group is preferable.

Note that when the onium group is a cyclic ammonium group, a nitrogen atom constituting an ammonium group also serves as an atom constituting a ring. At this time, a nitrogen atom and a silicon atom constituting the ring may be bonded directly or via a divalent linking group, or a carbon atom and a silicon atom constituting the ring may be bonded directly or via a divalent linking group.

In an example of a preferred embodiment, R¹¹, which is a group bonded to a silicon atom, is a heteroaromatic cyclic ammonium group represented by Formula (S1) described below.

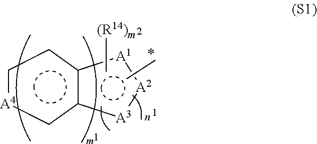

In Formula (S1), A¹, A², A³, and A⁴ independently represent a group represented by any one of Formulae (J1) to (J3) described below, and at least one of A¹ to A⁴ is a group represented by Formula (J2) described below, and it is determined whether a bond between each of A¹ to A⁴ and an atom adjacent to each of A¹ to A⁴ and constituting the ring together is a single bond or a double bond such that the ring to be constituted exhibits aromaticity according to which of A¹ to A⁴ the silicon atom in Formula (3) is bonded to. * represents a bond.

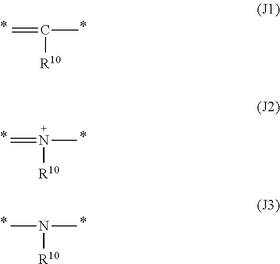

In Formulae (J1) to (J3), R¹⁰ independently represents a single bond, a hydrogen atom, an alkyl group, an aryl group, an aralkyl group, a halogenated alkyl group, a halogenated aryl group, a halogenated aralkyl group, or an alkenyl group, and specific examples of the alkyl group, the aryl group, the aralkyl group, the halogenated alkyl group, the halogenated aryl group, the halogenated aralkyl group, and the alkenyl group, and suitable numbers of carbon atoms thereof include those described above. * represents a bond.

In Formula (S1), R¹⁴ independently represents an alkyl group, an aryl group, an aralkyl group, a halogenated alkyl group, a halogenated aryl group, a halogenated aralkyl group, an alkenyl group, or a hydroxy group, and when there are two or more pieces of R¹⁴, the two pieces of R¹⁴ may be bonded to each other to form a ring, and the ring formed by the two pieces of R¹⁴ may have a crosslinked ring structure, and in such a case, the cyclic ammonium group has an adamantane ring, a norbornene ring, a spiro ring, or the like.

Specific examples of the alkyl group, the aryl group, the aralkyl group, the halogenated alkyl group, the halogenated aryl group, the halogenated aralkyl group, and the alkenyl group, and suitable numbers of carbon atoms thereof include those described above.

In Formula (S1), n¹ is an integer of 1 to 8, m¹ is 0 or 1, and m² is 0 or a positive integer ranging from 1 to the maximum number that can be substituted on a monocyclic ring or a polycyclic ring.

When m¹ is 0, a (4+n¹)-membered ring containing A¹ to A⁴ is formed. That is, a 5-membered ring is formed when n¹ is 1, a 6-membered ring is formed when n¹ is 2, a 7-membered ring is formed when n¹ is 3, an 8-membered ring is formed when n¹ is 4, a 9-membered ring is formed when n¹ is 5, a 10-membered ring is formed when n¹ is 6, a 11-membered ring is formed when n¹ is 7, and a 12-membered ring is formed when n¹ is 8.

When m¹ is 1, a (4+n¹)-membered ring containing A¹ to A³ and a 6-membered ring containing A⁴ are condensed to form a condensed ring.

A¹ to A⁴ may or may not have a hydrogen atom on the atom constituting the ring depending on whether they are of Formulae (J1) to (J3), but when A¹ to A⁴ have a hydrogen atom on the atom constituting the ring, the hydrogen atom may be replaced by R¹⁴. In addition, R¹⁴ may be substituted for a ring-constituting atom other than the ring-constituting atom in A¹ to A⁴. Under such circumstances, as described above, m² is selected from 0 or an integer ranging from 1 to the maximum number that can be substituted on a monocyclic ring or a polycyclic ring.

The bond of the heteroaromatic cyclic ammonium group represented by Formula (S1) is present at any carbon atom or nitrogen atom present in such a monocyclic ring or a condensed ring, and is directly bonded to a silicon atom, or a linking group is bonded to form an organic group having cyclic ammonium, which is bonded to a silicon atom.

Examples of such a linking group include an alkylene group, an arylene group, and an alkenylene group, but are not limited thereto.

Specific examples of the alkylene group and the arylene group and the suitable numbers of carbon atoms thereof include those described above.

In addition, the alkenylene group is a divalent group derived by further removing one hydrogen atom from the alkenyl group, and specific examples of such an alkenyl group include the same groups as those described above. The number of carbon atoms of the alkenylene group is not particularly limited, but is preferably 40 or less, more preferably 30 or less, and still more preferably 20 or less.

Specific examples thereof include vinylene, 1-methylvinylene, propenylene, 1-butenylene, 2-butenylene, 1-pentenylene, and 2-pentenylene groups, but are not limited thereto.

Specific examples of the silane compound (hydrolyzable organosilane) represented by Formula (3) having a heteroaromatic cyclic ammonium group represented by Formula (S1) include silanes represented by Formulae (I-1) to (I-50) described below, but are not limited thereto.

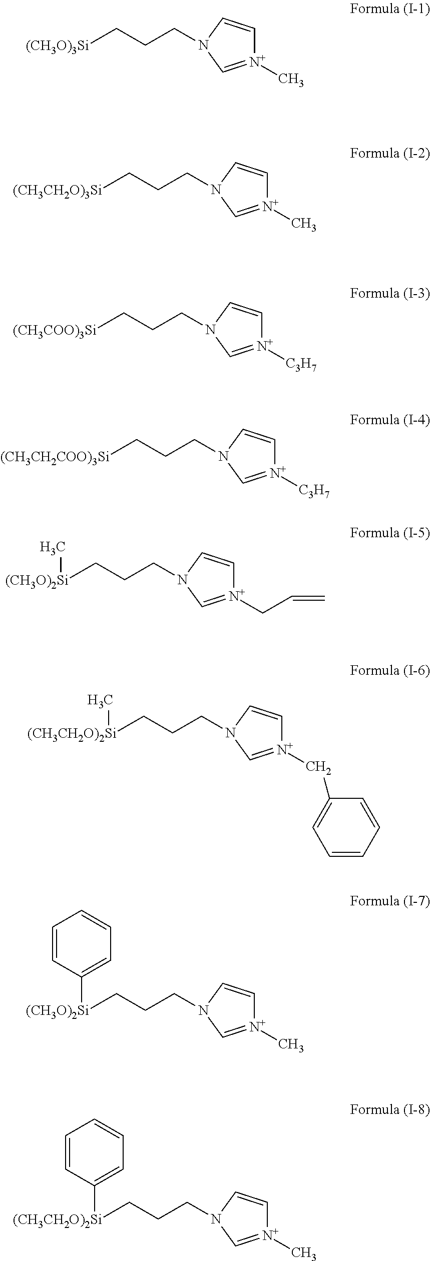

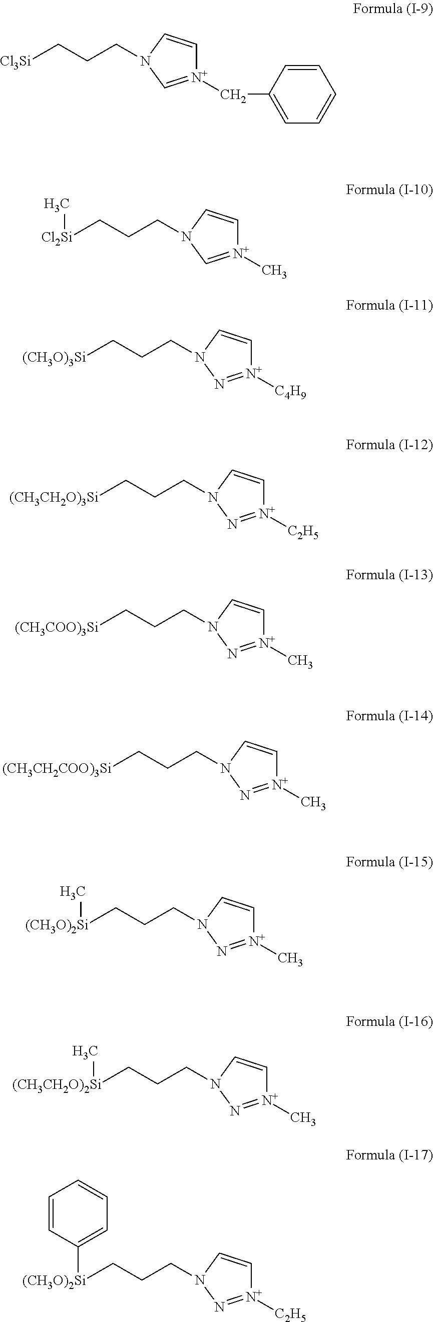

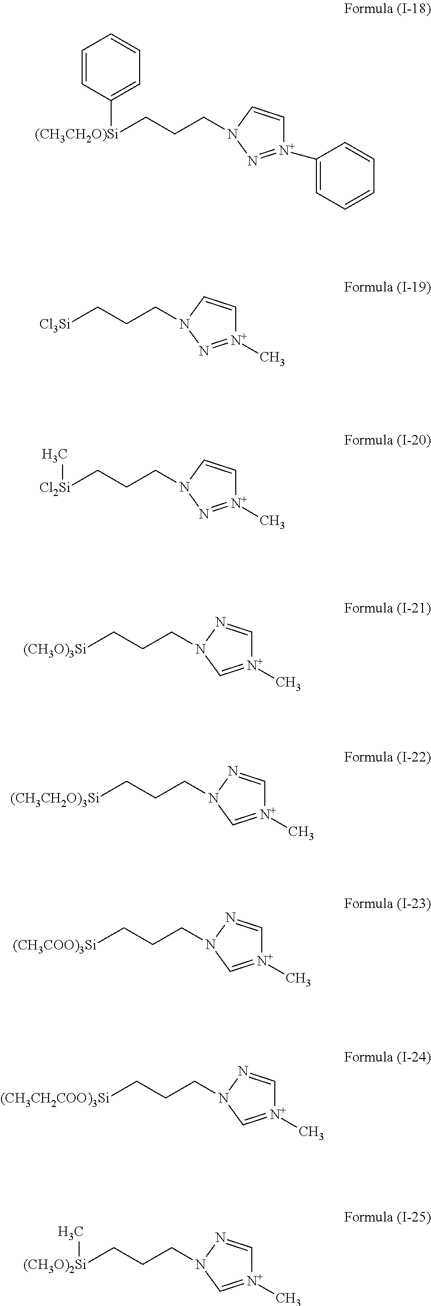

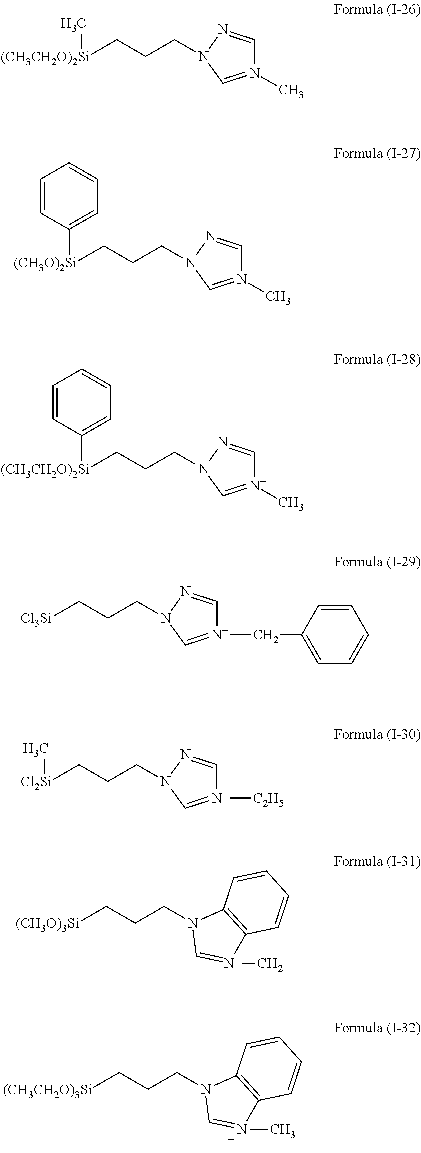

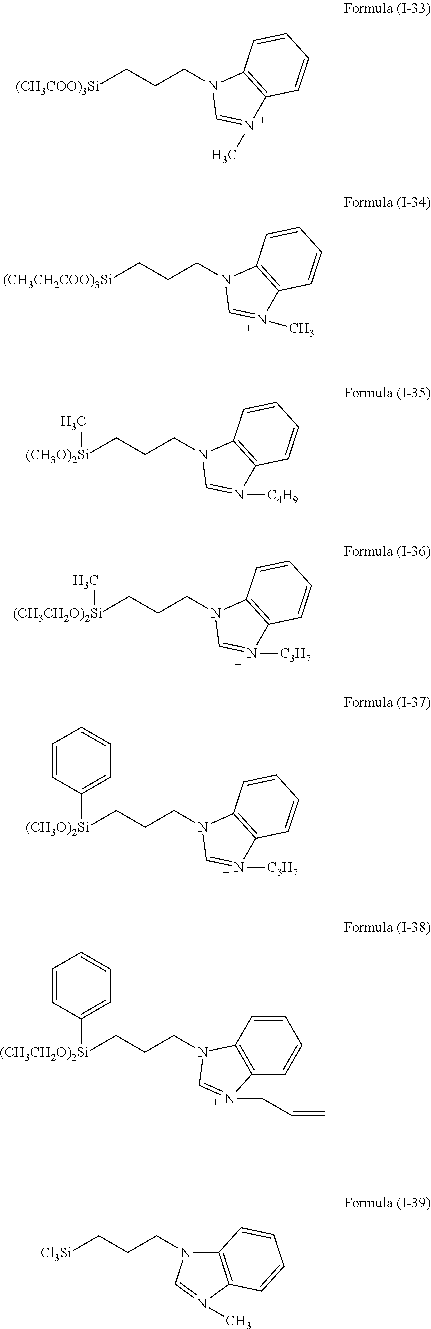

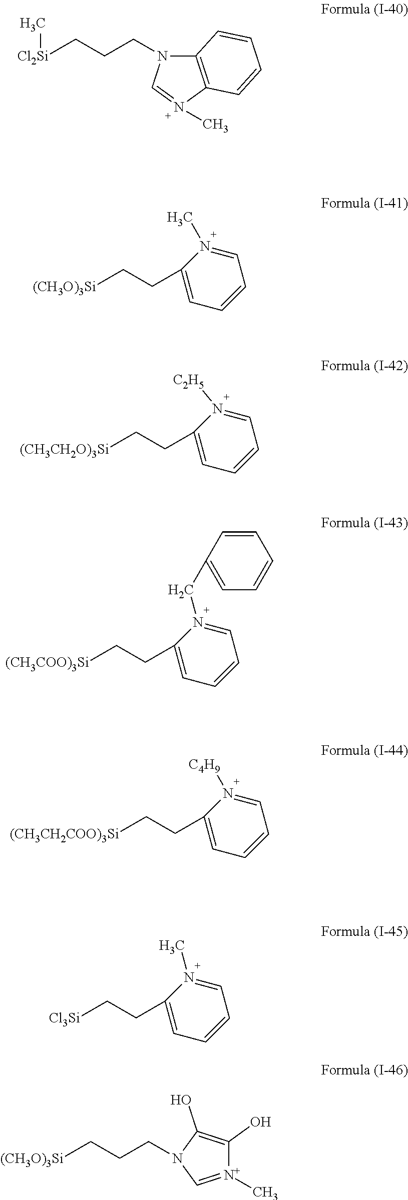

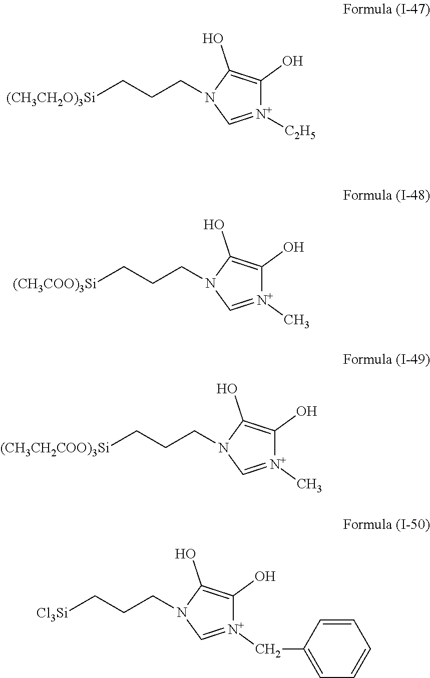

In addition, in another example, R¹¹, which is a group bonded to a silicon atom in Formula (3), can be a heteroaliphatic cyclic ammonium group represented by Formula (S2) described below.

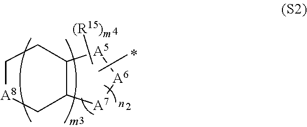

In Formula (S2), A⁵, A⁶, A⁷, and A⁸ independently represent a group represented by any one of Formulae (J4) to (J6) described below, and at least one of A⁵ to A⁸ is a group represented by Formula (J5) described below. It is determined whether a bond between each of A⁵ to A⁸ and an atom adjacent to each of A⁵ to A⁸ and constituting the ring together is a single bond or a double bond such that the ring to be constituted exhibits antiaromaticity according to which of A⁵ to A⁸ the silicon atom in Formula (3) is bonded to. * represents a bond.

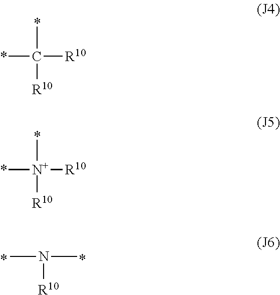

In Formulae (J4) to (J6), R¹⁰ independently represents a single bond, a hydrogen atom, an alkyl group, an aryl group, an aralkyl group, a halogenated alkyl group, a halogenated aryl group, a halogenated aralkyl group, or an alkenyl group, and specific examples of the alkyl group, the aryl group, the aralkyl group, the halogenated alkyl group, the halogenated aryl group, the halogenated aralkyl group, and the alkenyl group, and suitable numbers of carbon atoms thereof include those described above. * represents a bond.

In Formula (S2), R¹⁵ independently represents an alkyl group, an aryl group, an aralkyl group, a halogenated alkyl group, a halogenated aryl group, a halogenated aralkyl group, an alkenyl group, or a hydroxy group, and when there are two or more pieces of R¹⁵, the two pieces of R¹⁵ may be bonded to each other to form a ring, and the ring formed by the two pieces of R¹⁵ may have a crosslinked ring structure, and in such a case, the cyclic ammonium group has an adamantane ring, a norbornene ring, a spiro ring, or the like.

Specific examples of the alkyl group, the aryl group, the aralkyl group, the halogenated alkyl group, the halogenated aryl group, the halogenated aralkyl group, and the alkenyl group, and suitable numbers of carbon atoms thereof include those described above.

In Formula (S2), n² is an integer of 1 to 8, m³ is 0 or 1, and m⁴ is 0 or a positive integer ranging from 1 to the maximum number that can be substituted on a monocyclic ring or a polycyclic ring.

When m³ is 0, a (4+n²)-membered ring containing A⁵ to A⁸ is formed. That is, a 5-membered ring is formed when n² is 1, a 6-membered ring is formed when n² is 2, a 7-membered ring is formed when n² is 3, an 8-membered ring is formed when n² is 4, a 9-membered ring is formed when n² is 5, a 10-membered ring is formed when n² is 6, a 11-membered ring is formed when n² is 7, and a 12-membered ring is formed when n² is 8.

When m³ is 1, a (4+n²)-membered ring containing A⁵ to A⁷ and a 6-membered ring containing A⁸ are condensed to form a condensed ring.

A⁵ to A⁸ may or may not have a hydrogen atom on the atom constituting the ring depending on whether they are of Formulae (J4) to (J6), but when A⁵ to A⁸ have a hydrogen atom on the atom constituting the ring, the hydrogen atom may be replaced by R¹⁵. In addition, R¹⁵ may be substituted for a ring-constituting atom other than the ring-constituting atom in A⁵ to A⁸.

Under such circumstances, as described above, m⁴ is selected from 0 or an integer ranging from 1 to the maximum number that can be substituted on a monocyclic ring or a polycyclic ring.

The bond of the heteroaliphatic cyclic ammonium group represented by Formula (S2) is present at any carbon atom or nitrogen atom present in such a monocyclic ring or a condensed ring, and is directly bonded to a silicon atom, or a linking group is bonded to form an organic group having cyclic ammonium, which is bonded to a silicon atom.

Examples of such a linking group include an alkylene group, an arylene group, and an alkenylene group, and specific examples of the alkylene group, the arylene group, and the alkenylene group and the suitable numbers of carbon atoms thereof include the same as described above.

Specific examples of the silane compound (hydrolyzable organosilane) represented by Formula (3) having a heteroaliphatic cyclic ammonium group represented by Formula (S2) include silanes represented by Formulae (II-1) to (II-30) described below, but are not limited thereto.

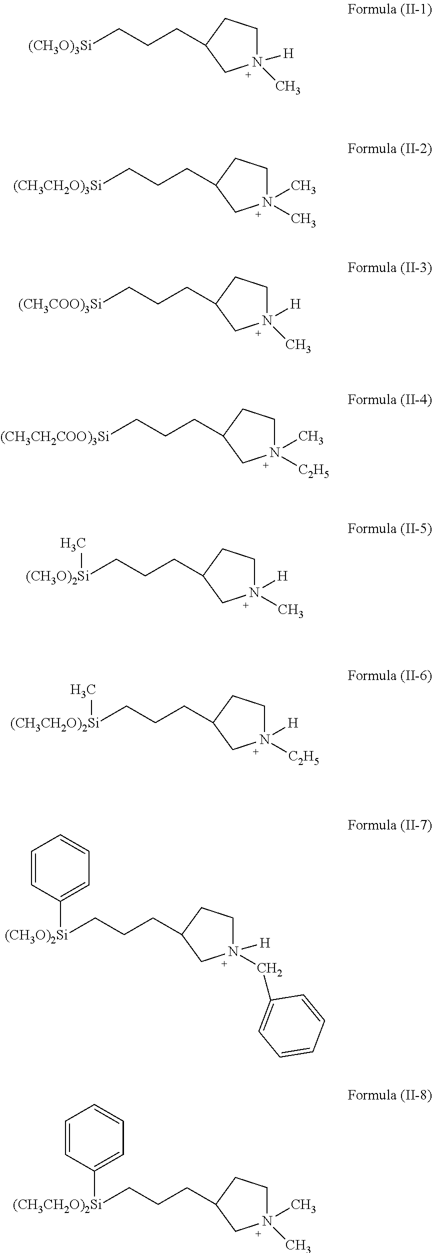

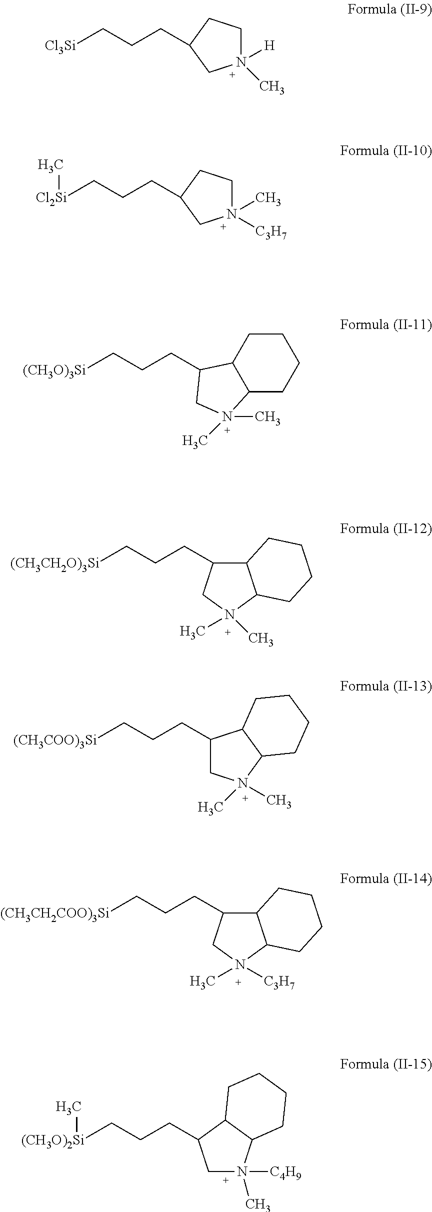

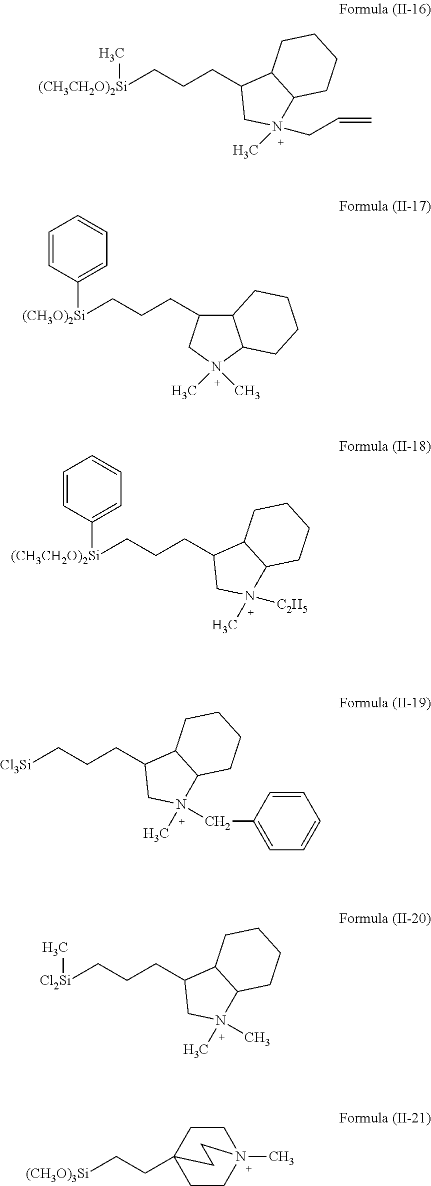

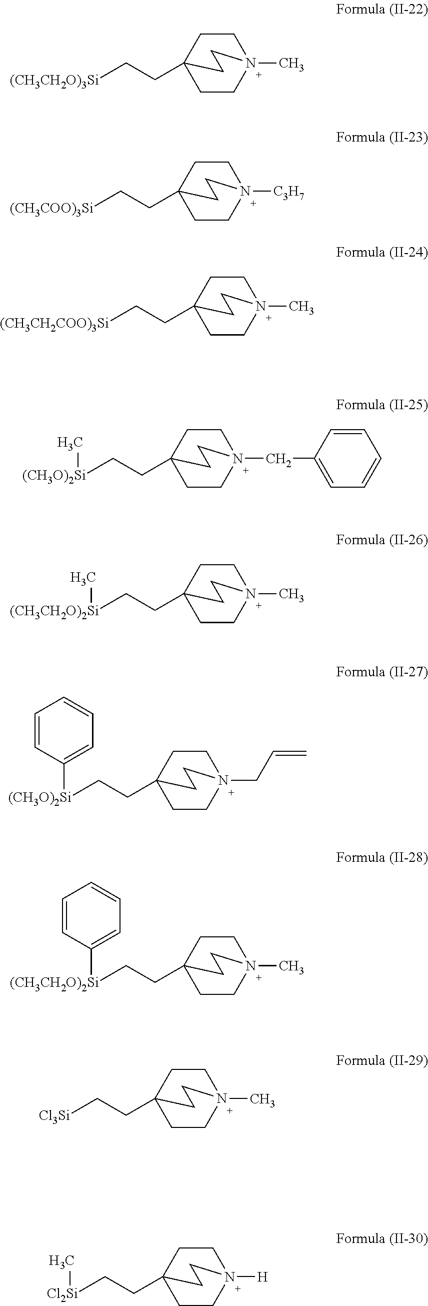

Further, in another example, R¹¹, which is a group bonded to a silicon atom in Formula (3), can be a chain ammonium group represented by Formula (S3) described below.

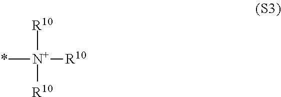

In Formula (S3), R¹⁰ independently represents a hydrogen atom, an alkyl group, an aryl group, an aralkyl group, a halogenated alkyl group, a halogenated aryl group, a halogenated aralkyl group, or an alkenyl group, and specific examples of the alkyl group, the aryl group, the aralkyl group, the halogenated alkyl group, the halogenated aryl group, the halogenated aralkyl group, and the alkenyl group, and suitable numbers of carbon atoms thereof include those described above. * represents a bond.

The chain ammonium group represented by Formula (S3) is directly bonded to a silicon atom, or a linking group is bonded to form an organic group having a chain ammonium group, which is bonded to a silicon atom.

Examples of such a linking group include an alkylene group, an arylene group, and an alkenylene group, and specific examples of the alkylene group, the arylene group, and the alkenylene group include the same as described above.

Specific examples of the silane compound (hydrolyzable organosilane) represented by Formula (3) having a chain ammonium group represented by Formula (S3) include silanes represented by Formulae (III-1) to (III-28) described below, but are not limited thereto.

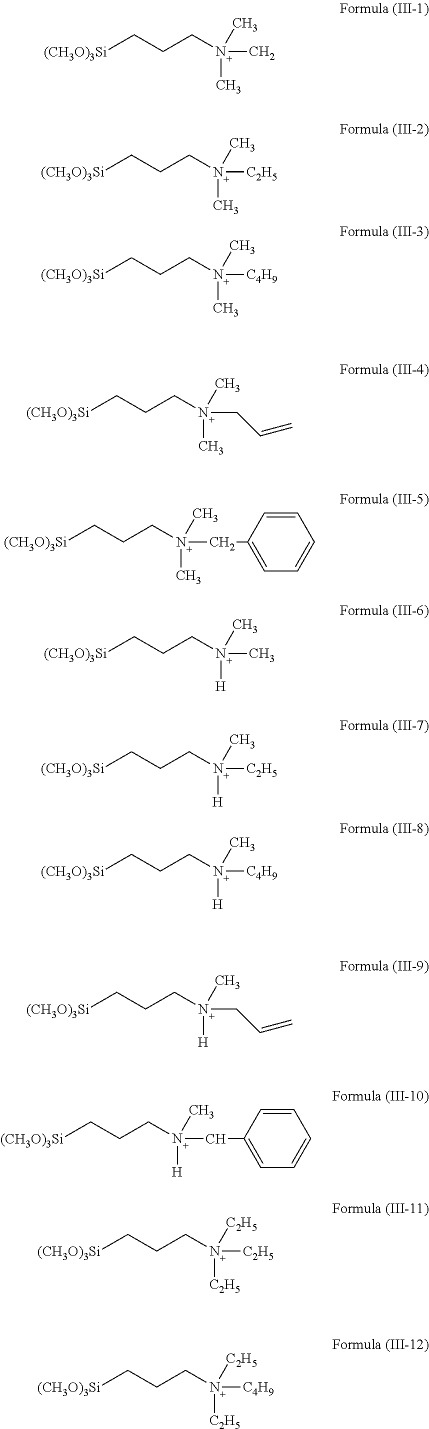

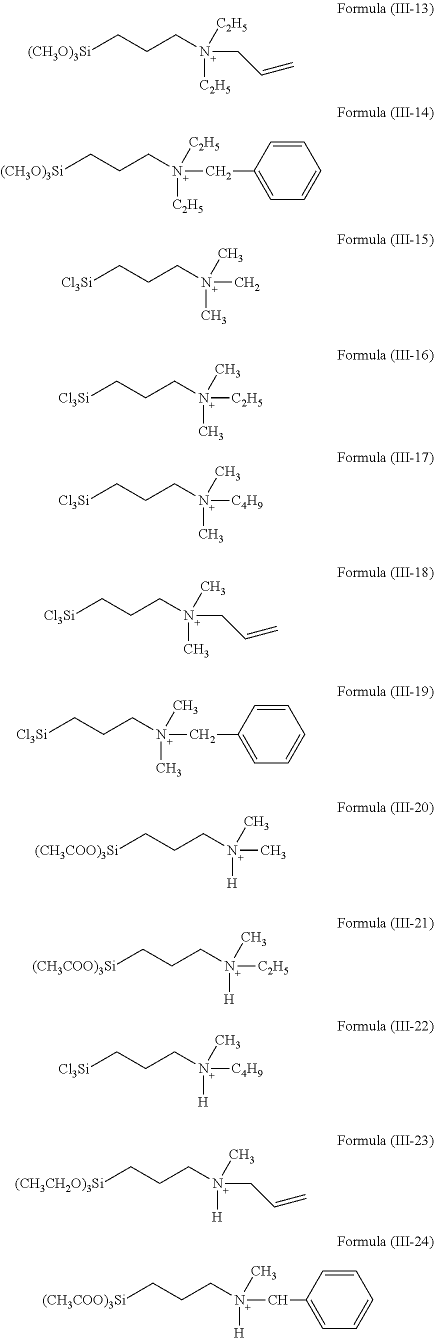

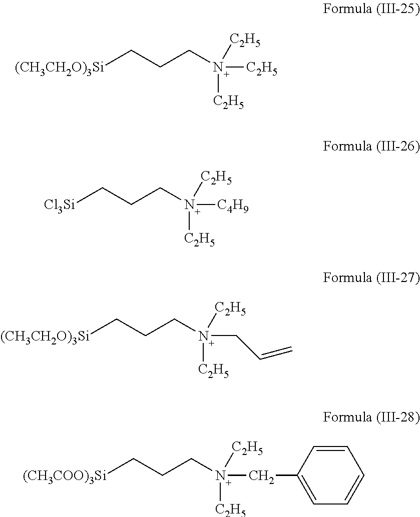

### <<Silane Compound (Hydrolyzable Organosilane) Having Cyclic Urea Skeleton in Molecule>>

Examples of the hydrolyzable organosilane having a cyclic urea skeleton in the molecule include a hydrolyzable organosilane represented by Formula (4-1) described below.

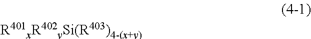

In Formula (4-1), R⁴⁰¹ is a group bonded to a silicon atom, and independently represents a group represented by Formula (4-2) described below.

R⁴⁰² is a group bonded to a silicon atom and represents an optionally substituted alkyl group, an optionally substituted aryl group, an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, or an organic group having an epoxy group, an organic group having an acryloyl group, an organic group having a methacryloyl group, an organic group having a mercapto group, or an organic group having a cyano group, or a combination of two or more thereof.

R⁴⁰³ is a group or atom bonded to a silicon atom, and independently represents an alkoxy group, an aralkyloxy group, an acyloxy group, or a halogen atom.

x is 1 or 2, y is 0 or 1, and x+y≤2 is satisfied.

Specific examples of the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, the alkenyl group, the organic group having an epoxy group, the organic group having an acryloyl group, the organic group having a methacryloyl group, the organic group having a mercapto group, and the organic group having a cyano group of R⁴⁰², and the alkoxy group, the aralkyloxy group, the acyloxy group, and the halogen atom of R⁴⁰³, and substituent groups thereof, suitable numbers of carbon atoms, and the like include those described above for R² and X in Formula (A-1).

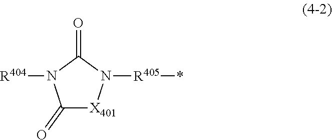

In Formula (4-2), R⁴⁰⁴ independently represents a hydrogen atom, an optionally substituted alkyl group, an optionally substituted alkenyl group, or an organic group having an epoxy group, or an organic group having a sulfonyl group, and R⁴⁰⁵ independently represents an alkylene group, a hydroxyalkylene group, a sulfide bond (—S—), an ether bond (—O—), or an ester bond (—CO—O— or —O—CO—). * represents a bond.

Note that specific examples and suitable numbers of carbon atoms of the optionally substituted alkyl group, the optionally substituted alkenyl group, and the organic group having an epoxy group of R⁴⁰⁴ are the same as those described above for R² in Formula (A-1), but besides these, as the optionally substituted alkyl group of R⁴⁰⁴, an alkyl group in which a terminal hydrogen atom is substituted with a vinyl group is preferable, and specific examples thereof include an allyl group, a 2-vinylethyl group, a 3-vinylpropyl group, and a 4-vinylbutyl group.

The organic group having a sulfonyl group is not particularly limited as long as it contains a sulfonyl group, and examples thereof include an optionally substituted alkylsulfonyl group, an optionally substituted arylsulfonyl group, an optionally substituted aralkylsulfonyl group, an optionally substituted halogenated alkylsulfonyl group, an optionally substituted halogenated arylsulfonyl group, an optionally substituted halogenated aralkylsulfonyl group, an optionally substituted alkoxyalkylsulfonyl group, an optionally substituted alkoxyarylsulfonyl group, an optionally substituted alkoxyaralkylsulfonyl group, and an optionally substituted alkenylsulfonyl group.

Specific examples and suitable numbers of carbon atoms of the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, and the alkenyl group of these groups, and the substituent groups thereof may be the same as those described above for R² in Formula (A-1).

The alkylene group is a divalent group derived by further removing one hydrogen atom from the alkyl group, and may linear, branched, and cyclic, and specific examples of such an alkylene group include the same as those described above. The number of carbon atoms of the alkylene group is not particularly limited, but is preferably 40 or less, more preferably 30 or less, still more preferably 20 or less, and yet still more preferably 10 or less.

In addition, the alkylene group of R⁴⁰⁵ may have one or two or more selected from a sulfide bond, an ether bond, and an ester bond at the terminal or in the middle, preferably in the middle.

Specific examples of the alkylene group include linear alkylene groups such as a methylene group, an ethylene group, a trimethylene group, a tetramethylene group, a pentamethylene group, a hexamethylene group, a heptamethylene group, an octamethylene group, a nonamethylene group, and a decamethylene group, branched alkylene groups such as a methylethylene group, a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, and a 1-ethyltrimethylene group, cyclic alkylene groups such as a 1,2-cyclopropanediyl group, a 1,2-cyclobutanediyl group, a 1,3-cyclobutytanediyl group, a 1,2-cyclohexanediyl, and a 1,3-cyclohexanediyl group, the alkylene group including ether groups such as —CH₂OCH₂—, —CH₂CH₂OCH₂—, —CH₂CH₂OCH₂CH₂—, —CH₂CH₂CH₂OCH₂CH₂—, —CH₂CH₂OCH₂CH₂CH₂—, —CH₂CH₂CH₂OCH₂CH₂CH₂—, —CH₂SCH₂—, —CH₂CH₂SCH₂—, —CH₂CH₂SCH₂CH₂—, —CH₂CH₂CH₂SCH₂CH₂—, —CH₂CH₂SCH₂CH₂CH₂—, —CH₂CH₂CH₂SCH₂CH₂CH₂—, and —CH₂OCH₂CH₂SCH₂—, but are not limited thereto.

The hydroxyalkylene group is one in which at least one of the hydrogen atoms of the above-mentioned alkylene group is substituted with a hydroxy group, and specific examples thereof include a hydroxymethylene group, a 1-hydroxyethylene group, a 2-hydroxyethylene group, a 1,2-dihydroxyethylene group, a 1-hydroxytrimethylene group, a 2-hydroxytrimethylene group, a 3-hydroxytrimethylene group, a 1-hydroxytetramethylene group, a 2-hydroxytetramethylene group, a 3-hydroxytetramethylene group, a 4-hydroxytetramethylene group, a 1,2-dihydroxytetramethylene group, a 1,3-dihydroxytetramethylene group, a 1,4-dihydroxytetramethylene group, a 2,3-dihydroxytetramethylene group, a 2,4-dihydroxytetramethylene group, and a 4,4-dihydroxytetramethylene group, but are not limited thereto.

In Formula (4-2), X₄₀₁ independently represents any of the groups represented by Formulae (4-3) to (4-5) described below, and the carbon atom of a ketone group in Formulae (4-4) and (4-5) described below is bonded to the nitrogen atom to which R⁴⁰⁵ in Formula (4-2) is bonded.

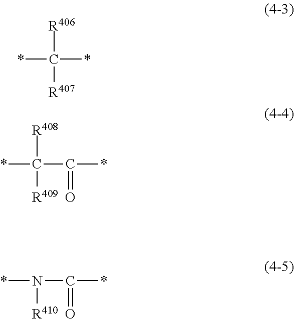

In Formulae (4-3) to (4-5), R⁴⁰⁶ to R⁴¹⁰ independently represent a hydrogen atom, an optionally substituted alkyl group, an optionally substituted alkenyl group, or an organic group having an epoxy group or a sulfonyl group. Specific examples and suitable numbers of carbon atoms of the optionally substituted alkyl group, the optionally substituted alkenyl group, and the organic group having an epoxy group or a sulfonyl group include those described above for R² in Formula (A-1). In addition, specific examples and suitable numbers of carbon atoms of the organic group having a sulfonyl group are the same as those described above for R⁴⁰⁴. * represents a bond.

Among them, from the viewpoint of achieving excellent lithography characteristics with good reproducibility, X₄₀₁ is preferably a group represented by Formula (4-5).

From the viewpoint of achieving excellent lithographic characteristics with good reproducibility, at least one of R⁴⁰⁴ and R⁴⁰⁶ to R⁴¹⁰ is preferably an alkyl group in which a terminal hydrogen atom is substituted with a vinyl group.

As the hydrolyzable organosilane represented by Formula (4-1), a commercially available product may be used, and the hydrolyzable organosilane can also be synthesized by a known method described in WO 2011/102470 A or the like.

Hereinafter, specific examples of the hydrolyzable organosilane represented by Formula (4-1) include silanes represented by Formulae (4-1-1) to (4-1-29) described below, but are not limited thereto.

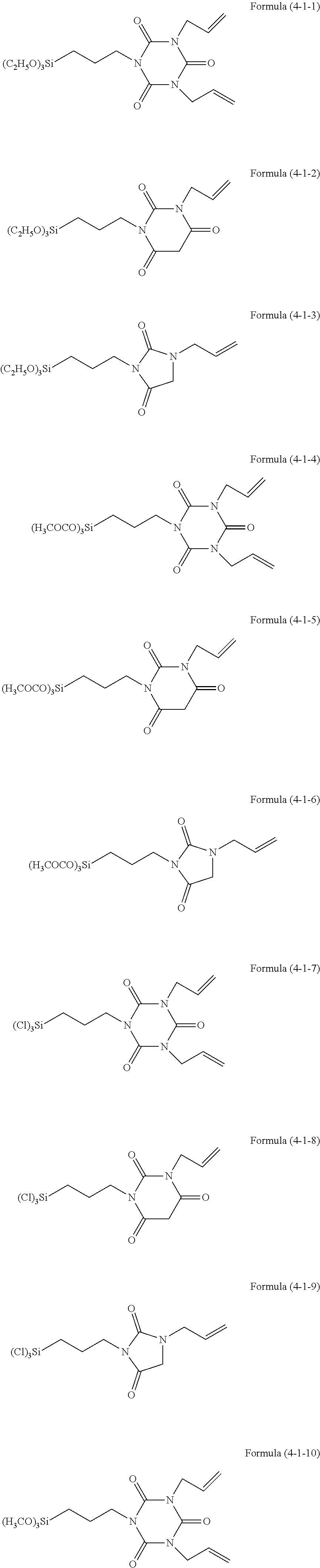

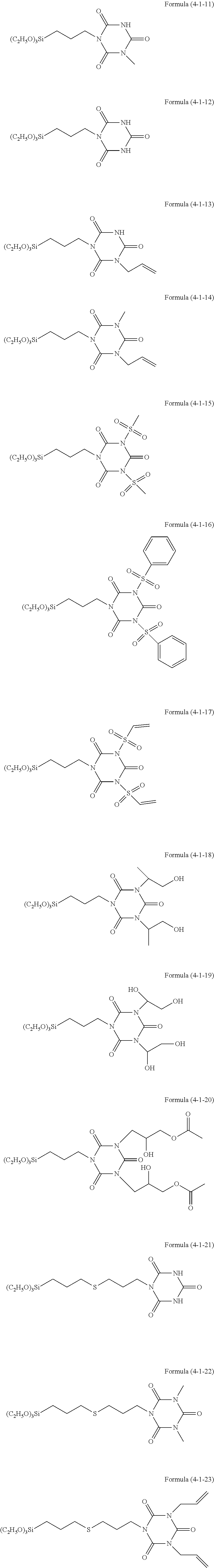

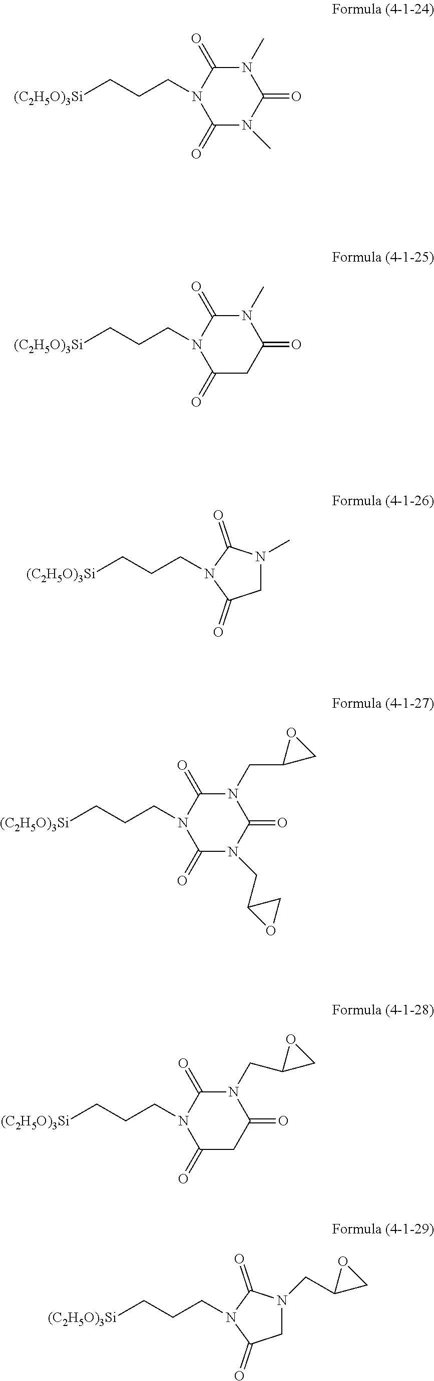

Polysiloxane [A] and polysiloxane [A′] can be a hydrolysis condensate of a hydrolyzable silane including another silane compound other than those exemplified above or a modified product thereof as long as the effect of the present invention is not impaired.

As described above, as polysiloxane [A] and polysiloxane [A′], a modified product in which at least a part of silanol groups of the hydrolysis condensate is modified can be used. For example, a modified product in which a part of silanol groups is alcohol-modified or acetal-protected can be used.

Examples of the polysiloxane as the modified product include a reaction product obtained by a reaction between at least a part of silanol groups of a hydrolysis condensate and a hydroxy group of an alcohol in the condensate of the hydrolyzable silane described above, a dehydration reaction product between the condensate and an alcohol, and a modified product obtained by protecting at least a part of silanol groups of the condensate with an acetal group.

As the alcohol, a monovalent alcohol can be used, and examples include methanol, ethanol, 2-propanol, 1-butanol, 2-butanol, isobutyl alcohol, tert-butyl alcohol, 1-pentanol, 2-pentanol, 3-pentanol, 1-heptanol, 2-heptanol, tert-amyl alcohol, neopentyl alcohol, 2-methyl-1-propanol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, and cyclohexanol.

In addition, for example, alkoxy group-containing alcohols such as 3-methoxybutanol, ethylene glycol monomethyl ether, ethylene glycol monoethyl ether, diethylene glycol monomethyl ether, diethylene glycol monoethyl ether, propylene glycol monomethyl ether(1-methoxy-2-propanol), propylene glycol monoethyl ether (1-ethoxy-2-propanol), and propylene glycol monobutyl ether(1-butoxy-2-propanol) can be used.

Regarding the reaction between the silanol group of the hydrolysis condensate and the hydroxy group of the alcohol, the hydrolysis condensate and the alcohol are brought into contact with each other and reacted at a temperature of 40 to 160° C., for example, 60° C., for 0.1 to 48 hours, for example, 24 hours, whereby a modified product in which the silanol group is capped is obtained. At this time, the alcohol of the capping agent can be used as a solvent in the composition containing the polysiloxane.

In addition, a dehydration reaction product of a hydrolysis condensate of a hydrolyzable silane and an alcohol can be produced by reacting the hydrolysis condensate with the alcohol in the presence of an acid as a catalyst, capping a silanol group with the alcohol, and removing generated water generated by dehydration to the outside of the reaction system.

As the acid, an organic acid having an acid dissociation constant (pka) of −1 to 5, preferably 4 to 5 can be used. Examples of the acid include a trifluoroacetic acid, a maleic acid, a benzoic acid, an isobutyric acid, and acetic acid, and among them, a benzoic acid, an isobutyric acid, and an acetic acid can be exemplified.

In addition, as the acid, an acid having a boiling point of 70 to 160° C. can be used, and examples thereof include a trifluoroacetic acid, an isobutyric acid, an acetic acid, and a nitric acid.

As described above, the acid preferably has a physical property of having an acid dissociation constant (pka) of 4 to 5 or a boiling point of 70 to 160° C. That is, one having a weak acidity or one having a strong acidity and a low boiling point can be used.

Then, as the acid, any property can be used from the properties of the acid dissociation constant and the boiling point.

For acetal protection of the silanol group of the hydrolysis condensate, a vinyl ether, for example, a vinyl ether represented by Formula (5) described below, can be used, and a partial structure represented by Formula (6) described below can be introduced into a polysiloxane by the reaction.

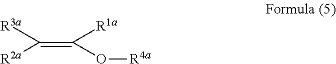

In Formula (5), R^{1a}, R^{2a}, and R^{3a} each represent a hydrogen atom or an alkyl group having 1 to 10 carbon atoms, R^{4a} represents an alkyl group having 1 to 10 carbon atoms, and R^{2a} and R^{4a} may be bonded to each other to form a ring. Examples of the alkyl group include those exemplified above.

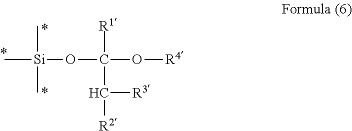

In Formula (6), R^{1′}, R^{2′}, and R^{3′} each represent a hydrogen atom or an alkyl group having 1 to 10 carbon atoms, R^{4′} represents an alkyl group having 1 to 10 carbon atoms, and R^{2′} and R^{4′} may be bonded to each other to form a ring. In Formula (6), * represents a bond to an adjacent atom. Examples of the adjacent atom include an oxygen atom of a siloxane bond, an oxygen atom of a silanol group, and a carbon atom derived from R¹ of Formula (1). Examples of the alkyl group include those exemplified above.

Examples of the vinyl ether represented by Formula (5) include aliphatic vinyl ether compounds such as methyl vinyl ether, ethyl vinyl ether, isopropyl vinyl ether, normal butyl vinyl ether, 2-ethylhexyl vinyl ether, tert-butyl vinyl ether, and cyclohexyl vinyl ether, and cyclic vinyl ether compounds such as 2,3-dihydrofuran, 4-methyl-2,3-dihydrofuran, and 3,4-dihydro-2H-pyran. In particular, ethyl vinyl ether, propyl vinyl ether, butyl vinyl ether, ethylhexyl vinyl ether, cyclohexyl vinyl ether, 3,4-dihydro-2H-pyran, or 2,3-dihydrofuran can be preferably used.

The acetal protection of the silanol group can be performed using a hydrolysis condensate, a vinyl ether, and an aprotic solvent such as propylene glycol monomethyl ether acetate, ethyl acetate, dimethylformamide, tetrahydrofuran, or 1,4-dioxane as a solvent, and using a catalyst such as a pyridium para-toluenesulfonic acid, a trifluoromethanesulfonic acid, a para-toluenesulfonic acid, a methanesulfonic acid, a hydrochloric acid, or a sulfuric acid.

Note that capping of the silanol group with an alcohol and acetal protection of the silanol group may be performed simultaneously with hydrolysis and condensation of a hydrolyzable silane described below.

The weight average molecular weight of the hydrolysis condensate of the hydrolyzable silane or the modified product thereof can be, for example, 500 to 1,000,000. From the viewpoint of suppressing precipitation of a hydrolysis condensate s or a modified product thereof in the composition, or the like, the weight average molecular weight can be preferably 500,000 or less, more preferably 250,000 or less, and still more preferably 100,000 or less, and from the viewpoint of achieving both storage stability and coatability, or the like, the weight average molecular weight can be preferably 700 or more, and more preferably 1,000 or more.

Note that the weight average molecular weight is a molecular weight obtained in terms of polystyrene by GPC analysis. The GPC analysis can be performed using, for example, a GPC apparatus (trade name: HLC-8220GPC, manufactured by Tosoh Corporation), a GPC column (trade name: Shodex (registered trademark) KF803L, KF802, KF801, manufactured by Showa Denko Co., Ltd.), at a column temperature of 40° C., with the use of tetrahydrofuran as an eluent (elution solvent), at a flow rate (flow speed) of 1.0 mL/min, with polystyrene (Shodex (registered trademark) manufactured by Showa Denko Co., Ltd.) as a standard sample.

The hydrolysis condensate of the hydrolyzable silane is obtained by hydrolyzing and condensing the silane compound (hydrolyzable silane) described above.

The silane compound (hydrolyzable silane) described above contains an alkoxy group, an aralkyloxy group, an acyloxy group, or a halogen atom that is directly bonded to a silicon atom, that is, an alkoxysilyl group, an aralkyloxysilyl group, an acyloxysilyl group, or a halogenated silyl group (hereinafter, referred to as a hydrolyzable group).

For the hydrolysis of these hydrolyzable groups, usually 0.1 to 100 mol, for example, 0.5 to 100 mol, preferably 1 to 10 mol of water is used per 1 mol of the hydrolyzable group.

At the time of hydrolysis and condensation, a hydrolysis catalyst may be used for the purpose of accelerating the reaction, or hydrolysis and condensation may be performed without using a hydrolysis catalyst. When a hydrolysis catalyst is used, usually 0.0001 to 10 mol, preferably 0.001 to 1 mol, of the hydrolysis catalyst can be used per 1 mol of the hydrolyzable group.

The reaction temperature at the time of performing hydrolysis and condensation is usually in a range of a room temperature or higher and a reflux temperature at normal pressure of an organic solvent that can be used for hydrolysis or lower, and can be, for example, 20 to 110° C. or, for example, 20 to 80° C.

For the hydrolysis, the hydrolysis may be performed completely, that is, all hydrolyzable groups may be changed to silanol groups, or the hydrolysis may be performed partially, that is, unreacted hydrolyzable groups may be left.

Examples of the hydrolysis catalyst that can be used in hydrolysis and condensation include metal chelate compounds, organic acids, inorganic acids, organic bases, and inorganic bases.

Examples of the metal chelate compound as the hydrolysis catalyst include titanium chelate compounds, such as triethoxy-mono(acetylacetonato)titanium, tri-n-propoxy-mono(acetylacetonato)titanium, tri-i-propoxy-mono(acetylacetonato)titanium, tri-n-butoxy-mono(acetylacetonato)titanium, tri-sec-butoxy-mono(acetylacetonato)titanium, tri-t-butoxy-mono(acetylacetonato)titanium, diethoxy-bis(acetylacetonato)titanium, di-n-propoxy-bis(acetylacetonato)titanium, di-i-propoxy-bis(acetylacetonato)titanium, di-n-butoxy-bis(acetylacetonato)titanium, di-sec-butoxy-bis(acetylacetonato)titanium, di-t-butoxy-bis(acetylacetonato)titanium, monoethoxy-tris(acetylacetonato)titanium, mono-n-propoxy-tris(acetylacetonato)titanium, mono-i-propoxy-tris(acetylacetonato)titanium, mono-n-butoxy-tris(acetylacetonato)titanium, mono-sec-butoxy-tris(acetylacetonato)titanium, mono-t-butoxy-tris(acetylacetonato)titanium, tetrakis(acetylacetonato)titanium, triethoxy-mono(ethylacetoacetato)titanium, tri-n-propoxy-mono(ethylacetoacetato)titanium, tri-i-propoxy-mono(ethylacetoacetato)titanium, tri-n-butoxy-mono(ethylacetoacetato)titanium, tri-sec-butoxy-mono(ethylacetoacetato)titanium, tri-t-butoxy-mono(ethylacetoacetato)titanium, diethoxy-bis(ethylacetoacetato)titanium, di-n-propoxy-bis(ethylacetoacetato)titanium, di-i-propoxy-bis(ethylacetoacetato)titanium, di-n-butoxy-bis(ethylacetoacetato)titanium, di-sec-butoxy-bis(ethylacetoacetato)titanium, di-t-butoxy-bis(ethylacetoacetato)titanium, monoethoxy-tris(ethylacetoacetato)titanium, mono-n-propoxy-tris (ethylacetoacetato)titanium, mono-i-propoxy-tris(ethylacetoacetato)titanium, mono-n-butoxy-tris(ethylacetoacetato)titanium, mono-sec-butoxy-tris(ethylacetoacetato)titanium, mono-t-butoxy-tris(ethylacetoacetato)titanium, tetrakis(ethylacetoacetato)titanium, mono(acetylacetonato)tris(ethylacetoacetato)titanium, bis(acetylacetonato)bis(ethylacetoacetato)titanium, and tris(acetylacetonato)mono(ethylacetoacetato)titanium; zirconium chelate compounds, such as triethoxy-mono(acetylacetonato)zirconium, tri-n-propoxy-mono(acetylacetonato)zirconium, tri-i-propoxy-mono(acetylacetonato)zirconium, tri-n-butoxy-mono(acetylacetonato)zirconium, tri-sec-butoxy-mono(acetylacetonato)zirconium, tri-t-butoxy-mono(acetylacetonato)zirconium, diethoxy-bis(acetylacetonato)zirconium, di-n-propoxy-bis(acetylacetonato)zirconium, di-i-propoxy-bis(acetylacetonato)zirconium, di-n-butoxy-bis(acetylacetonato)zirconium, di-sec-butoxy-bis(acetylacetonato)zirconium, di-t-butoxy-bis(acetylacetonato)zirconium, monoethoxy-tris(acetylacetonato)zirconium, mono-n-propoxy-tris(acetylacetonato)zirconium, mono-i-propoxy-tris(acetylacetonato)zirconium, mono-n-butoxy-tris (acetylacetonato)zirconium, mono-sec-butoxy-tris(acetylacetonato)zirconium, mono-t-butoxy-tris(acetylacetonato)zirconium, tetrakis(acetylacetonato)zirconium, triethoxy-mono(ethylacetoacetato)zirconium, tri-n-propoxy-mono(ethylacetoacetato)zirconium, tri-i-propoxy-mono(ethylacetoacetato)zirconium, tri-n-butoxy-mono(ethylacetoacetato)zirconium, tri-sec-butoxy-mono(ethylacetoacetato)zirconium, tri-t-butoxy-mono(ethylacetoacetato)zirconium, diethoxy-bis(ethylacetoacetato)zirconium, di-n-propoxy-bis(ethylacetoacetato)zirconium, di-i-propoxy-bis(ethylacetoacetato)zirconium, di-n-butoxy-bis(ethylacetoacetato)zirconium, di-sec-butoxy-bis(ethylacetoacetato)zirconium, di-t-butoxy-bis(ethylacetoacetato)zirconium, monoethoxytris(ethylacetoacetato)zirconium, mono-n-propoxy-tris(ethylacetoacetato)zirconium, mono-i-propoxy-tris(ethylacetoacetato)zirconium, mono-n-butoxy-tris(ethylacetoacetato)zirconium, mono-sec-butoxy-tris(ethylacetoacetato)zirconium, mono-t-butoxy-tris(ethylacetoacetato)zirconium, tetrakis(ethylacetoacetato)zirconium, mono(acetylacetonato)tris(ethylacetoacetato)zirconium, bis(acetylacetonato)bis(ethylacetoacetato)zirconium, and tris(acetylacetonato)mono(ethylacetoacetato)zirconium; and aluminum chelate compounds, such as tris(acetylacetonato)aluminum and tris(ethylacetoacetato)aluminum; but are not limited thereto.

Examples of the organic acid as the hydrolysis catalyst include an acetic acid, a propionic acid, a butanoic acid, a pentanoic acid, a hexanoic acid, a heptanoic acid, an octanoic acid, a nonanoic acid, a decanoic acid, an oxalic acid, a maleic acid, a methylmalonic acid, an adipic acid, a sebacic acid, a gallic acid, a butyric acid, a mellitic acid, an arachidonic acid, a 2-ethylhexanoic acid, an oleic acid, a stearic acid, a linoleic acid, a linolenic acid, a salicylic acid, a benzoic acid, a p-aminobenzoic acid, a p-toluenesulfonic acid, a benzenesulfonic acid, a monochloroacetic acid, a dichloroacetic acid, a trichloroacetic acid, a trifluoroacetic acid, a formic acid, a malonic acid, a sulfonic acid, a phthalic acid, a fumaric acid, a citric acid, and a tartaric acid, but are not limited thereto.

Examples of the inorganic acid as the hydrolysis catalyst include a hydrochloric acid, a nitric acid, a sulfuric acid, a hydrofluoric acid, and a phosphoric acid, but are not limited thereto.

Examples of the organic base as the hydrolysis catalyst include pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononane, diazabicycloundecene, tetramethylammonium hydroxide, tetraethylammonium hydroxide, tetrapropylammonium hydroxide, tetrabutylammonium hydroxide, trimethylphenylammonium hydroxide, benzyltrimethylammonium hydroxide, and benzyltriethylammonium hydroxide, but are not limited thereto.

Examples of the inorganic base as the hydrolysis catalyst include ammonia, sodium hydroxide, potassium hydroxide, barium hydroxide, and calcium hydroxide, but are not limited thereto.

Among these catalysts, metal chelate compounds, organic acids, and inorganic acids are preferable, and these may be used alone or in combination of two or more.

Among them, in the present invention, a nitric acid can be suitably used as the hydrolysis catalyst. By using a nitric acid, the storage stability of the reaction solution after hydrolysis and condensation can be improved, and in particular, a change in the molecular weight of the hydrolysis condensate or its modified product can be suppressed. The stability of the hydrolysis condensate or its modified product in the solution has been found to depend on the pH of the solution. As a result of intensive studies, it has been found that the pH of the solution becomes a stable region by using an appropriate amount of nitric acid.

In addition, as described above, a nitric acid can also be used in, for example, capping of a silanol group with an alcohol when obtaining a modified product of a hydrolysis condensate, and thus is also preferable from the viewpoint of being able to contribute to both reactions of hydrolysis and condensation of a hydrolyzable silane and alcohol capping of a hydrolysis condensate.

When hydrolysis and condensation are performed, an organic solvent may be used as a solvent, and specific examples thereof include aliphatic hydrocarbon-based solvents such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon-based solvents, such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, and n-amylnaphthalene; monoalcohol-based solvents, such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, n-heptanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; polyhydric alcohol-based solvents, such as ethylene glycol, propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin; ketone-based solvents, such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone; ether-based solvents, such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether (1-methoxy-2-propanol), propylene glycol monoethyl ether (1-ethoxy-2-propanol), propylene glycol monopropyl ether, propylene glycol monobutyl ether, propylene glycol monomethyl ether acetate (1-methoxy-2-propanol monoacetate), dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester-based solvents, such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethylene glycol diacetate, triethylene glycol methyl ether acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-based solvents, such as N-methylformamide, N,N-dimethylformamide, N,N-diethylformamide, acetamide, N-methylacetamide, N,N-dimethylacetamide, N-methylpropionamide, and N-methyl-2-pyrrolidone; and sulfur-based solvents, such as dimethyl sulfide, diethyl sulfide, thiophene, tetrahydrothiophene, dimethyl sulfoxide, sulfolane, and 1,3-propanesultone, but are not limited thereto. These solvents can be used alone or in combination of two or more kinds thereof.

After completion of the hydrolysis and condensation reaction, the reaction solution is used as it is, or diluted or concentrated, and the resultant reaction solution is neutralized, and treated using an ion exchange resin, whereby the hydrolysis catalyst such as an acid or a base used for hydrolysis and condensation can be removed. In addition, before or after such treatment, alcohol and water as by-products, the hydrolysis catalyst used, and the like can be removed from the reaction solution by distillation under reduced pressure or the like.

The thus-obtained hydrolysis condensate or a modified product thereof (hereinafter, also referred to as polysiloxane) is obtained in the form of a polysiloxane varnish dissolved in an organic solvent, and can be used as it is for preparing a composition for forming a silicon-containing resist underlayer film. That is, the reaction solution can be used as it is (or after dilution) for the preparation of the composition for forming a silicon-containing resist underlayer film, and at this time, the hydrolysis catalyst used for hydrolysis and condensation, by-products, and the like may remain in the reaction solution as long as the effect of the present invention is not impaired. For example, the hydrolysis catalyst or a nitric acid used at the time of alcohol capping of the silanol group may remain in the polymer varnish solution in an amount of about 100 ppm to 5,000 ppm.

The obtained polysiloxane varnish may be subjected to solvent substitution or may be appropriately diluted with a solvent. Note that when the storage stability of the obtained polysiloxane varnish is not poor, the organic solvent can be removed through distillation to set the concentration of a film-forming component to 100%. Note that the film-forming component refers to a component obtained by removing a solvent component from all components of the composition.

The organic solvent used for solvent substitution, dilution, or the like of the polysiloxane varnish may be the same as or different from the organic solvent used for the hydrolysis and condensation reaction of the hydrolyzable silane. The diluting solvent is not particularly limited, and one kind or two or more kinds can be arbitrarily selected and used.

### <Component [C]: Solvent>

In the first embodiment, for the solvent as component [C], any solvent can be used without particular limitation as long as it is a solvent capable of dissolving and mixing component [A] and, if necessary, other components contained in the composition for forming a silicon-containing resist underlayer film.

In the second embodiment, for the solvent as component [C], any solvent can be used without particular limitation as long as it is a solvent capable of dissolving and mixing component [A′] and component [B] and, if necessary, other components contained in the composition for forming a silicon-containing resist underlayer film.

Solvent [C] is preferably an alcohol-based solvent, more preferably an alkylene glycol monoalkyl ether, which is an alcohol-based solvent, and still more preferably a propylene glycol monoalkyl ether. Since these solvents are also capping agents for silanol groups of the hydrolysis condensate, it is possible to prepare a composition for forming a silicon-containing resist underlayer film from a solution obtained by preparing polysiloxane [A] or polysiloxane [A′] without requiring solvent substitution or the like.

Examples of the alkylene glycol monoalkyl ether include ethylene glycol monomethyl ether, ethylene glycol monoethyl ether, ethylene glycol monopropyl ether, ethylene glycol monobutyl ether, propylene glycol monomethyl ether(1-methoxy-2-propanol), propylene glycol monoethyl ether(1-ethoxy-2-propanol), methyl isobutyl carbinol, and propylene glycol monobutyl ether.

Specific examples of other solvents [C] include methyl cellosolve acetate, ethyl cellosolve acetate, propyrene glycol, propylene glycol monomethyl ether acetate (1-methoxy-2-propanol monoacetate), propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methyl butyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methyl-2-pyrrolidone, 4-methyl-2-pentanol, and γ-butyrolactone, and the solvents can be used alone or in combination of two or more.

In addition, the composition for forming a silicon-containing resist underlayer film of the present invention may contain water as a solvent. When water is contained as the solvent, the content thereof can be, for example, 30 mass % or less, preferably 20 mass % or less, and still more preferably 15 mass % or less with respect to the total mass of the solvent contained in the composition.

### <Component [D]: Curing Catalyst>

The composition for forming a silicon-containing resist underlayer film can be a composition not containing a curing catalyst, but preferably contains a curing catalyst (component [D]).

As the curing catalyst, ammonium salts, phosphines, phosphonium salts, sulfonium salts, and the like can be used. Note that the salts described below as an example of the curing catalyst may be added in the form of a salt or may form a salt in the composition (one that is added as a separate compound at the time of addition and forms a salt in the system).

Examples of the ammonium salt include a quaternary ammonium salt having a structure represented by Formula (D-1):

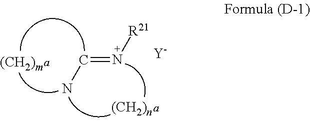

(where m^{a} represents an integer of 2 to 11, n^{a} represents an integer of 2 to 3, R²¹ represents an alkyl group, an aryl group, or an aralkyl group, and Y⁻ represents an anion),
a quaternary ammonium salt having a structure represented by Formula (D-2):

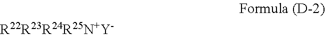

(where R²², R²³, R²⁴, and R²⁵ independently represent an alkyl group, an aryl group, or an aralkyl group, Y⁻ represents an anion, and R²², R²³, R²⁴, and R²⁵ are each bonded to a nitrogen atom),
a quaternary ammonium salt having a structure represented by Formula (D-3):

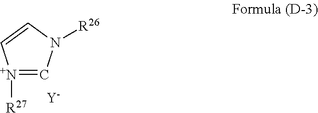

(where R²⁶ and R²⁷ independently represent an alkyl group, an aryl group, or an aralkyl group, and Y⁻ represents an anion),
a quaternary ammonium salt having a structure represented by Formula (D-4):

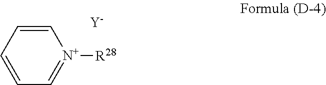

(where R²⁸ represents an alkyl group, an aryl group, or an aralkyl group, and Y⁻ represents an anion),
a quaternary ammonium salt having a structure represented by Formula (D-5):

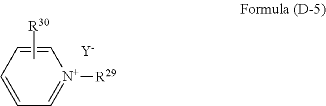

(where R²⁹ and R³⁰ independently represent an alkyl group, an aryl group, or an aralkyl group, and Y⁻ represents an anion), and
a tertiary ammonium salt having a structure represented by Formula (D-6)

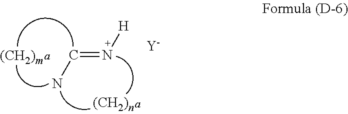

(where m^{a} represents an integer of 2 to 11, n^{a} represents an integer of 2 to 3, and Y⁻ represents an anion).

In addition, examples of the phosphonium salt includes a quaternary phosphonium salt represented by Formula (D-7):

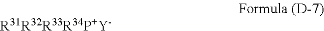

(where R³¹, R³², R³³, and R³⁴ independently represent an alkyl group, an aryl group, or an aralkyl group, Y⁻ represents an anion, and R³¹, R³², R³³, and R³⁴ are each bonded to a phosphorus atom).

In addition, examples of the sulfonium salt includes a tertiary sulfonium salt represented by Formula (D-8):

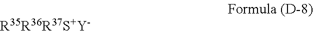

(where R³⁵, R³⁶, and R³⁷ independently represent an alkyl group, an aryl group, or an aralkyl group, Y⁻ represents an anion, and R³⁵, R³⁶, and R³⁷ are each bonded to a sulfur atom).

The compound of Formula (D-1) is a quaternary ammonium salt derived from an amine, m^{a} represents an integer of 2 to 11, and n^{a} represents an integer of 2 to 3. R²¹ of this quaternary ammonium salt represents, for example, an alkyl group having 1 to 18 and preferably 2 to 10 carbon atoms, an aryl group having 6 to 18 carbon atoms, or an aralkyl group having 7 to 18 carbon atoms, and examples thereof include a linear alkyl group such as an ethyl group, a propyl group, or a butyl group, a benzyl group, a cyclohexyl group, a cyclohexylmethyl group, and a dicyclopentadienyl group. In addition, examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻).

The compound of Formula (D-2) is a quaternary ammonium salt represented by R²²R²³R²⁴R²⁵N⁺Y⁻. R²², R²³, R²⁴, and R²⁵ of this quaternary ammonium salt are, for example, an alkyl group having 1 to 18 carbon atoms such as an ethyl group, a propyl group, a butyl group, a cyclohexyl group, and a cyclohexylmethyl group, an aryl group having 6 to 18 carbon atoms such as a phenyl group, or an aralkyl group having 7 to 18 carbon atoms such as a benzyl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). This quaternary ammonium salt can be obtained as a commercially available product, and examples thereof include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of Formula (D-3) is a quaternary ammonium salt derived from a 1-substituted imidazole, the number of carbon atoms of R²⁶ and R²⁷ is, for example, 1 to 18, and the total number of carbon atoms of R²⁶ and R²⁷ is preferably 7 or more. Examples of R²⁶ include an alkyl group such as a methyl group, an ethyl group, and a propyl group, an aryl group such as a phenyl group, and an aralkyl group such as a benzyl group, and examples of R²⁷ include an aralkyl group such as a benzyl group, and an alkyl group such as an octyl group and an octadecyl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). This compound can also be obtained as a commercially available product, but can be produced by reacting an imidazole-based compound such as 1-methylimidazole or 1-benzylimidazole with an aralkyl halide, an alkyl halide, or an aryl halide such as benzyl bromide, methyl bromide, or benzene bromide.

The compound of Formula (D-4) is a quaternary ammonium salt derived from pyridine, and R²⁸ is, for example, an alkyl group having 1 to 18 carbon atoms, preferably 4 to 18 carbon atoms, an aryl group having 6 to 18 carbon atoms, or an aralkyl group having 7 to 18 carbon atoms, and examples thereof include a butyl group, an octyl group, a benzyl group, and a lauryl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). This compound can also be obtained as a commercially available product, but can be produced, for example, by reacting pyridine with an alkyl halide such as lauryl chloride, benzyl chloride, benzyl bromide, methyl bromide, or octyl bromide, or an aryl halide. Examples of the compound include N-laurylpyridinium chloride and N-benzylpyridinium bromide.

The compound of Formula (D-5) is a quaternary ammonium salt derived from a substituted pyridine represented by picoline or the like, and R²⁹ is, for example, an alkyl group having 1 to 18 carbon atoms, preferably 4 to 18 carbon atoms, an aryl group having 6 to 18 carbon atoms, or an aralkyl group having 7 to 18 carbon atoms, and examples thereof include a methyl group, an octyl group, a lauryl group, and a benzyl group. R³⁰ is, for example, an alkyl group having 1 to 18 carbon atoms, an aryl group having 6 to 18 carbon atoms, or an aralkyl group having 7 to 18 carbon atoms, and for example, when the compound represented by Formula (D-5) is quaternary ammonium derived from picoline, R³⁰ is a methyl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). This compound can also be obtained as a commercially available product, but can be produced, for example, by reacting a substituted pyridine such as picoline with an alkyl halide such as methyl bromide, octyl bromide, lauryl chloride, benzyl chloride, or benzyl bromide, or an aryl halide. Examples of the compound include N-benzylpicolinium chloride, N-benzylpicolinium bromide, and N-laurylpicolinium chloride.

The compound of Formula (D-6) is a tertiary ammonium salt derived from an amine, m^{a} represents an integer of 2 to 11, and n^{a} represents 2 to 3. In addition, examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). The present compound can be produced by a reaction of an amine with a weak acid such as a carboxylic acid or phenol. Examples of the carboxylic acid include a formic acid and an acetic acid, and when a formic acid is used, the anion (Y⁻) is (HCOO⁻), and when an acetic acid is used, the anion (Y⁻) is (CH₃COO⁻). In addition, when phenol is used, the anion (Y⁻) is (C₆H₅O⁻).

The compound of Formula (D-7) is a quaternary phosphonium salt having the structure of R³¹R³²R³³R³⁴P⁺Y⁻. R³¹, R³², R³³, and R³⁴ are, for example, an alkyl group having 1 to 18 carbon atoms such as an ethyl group, a propyl group, a butyl group, or cyclohexylmethyl, an aryl group having 6 to 18 carbon atoms such as a phenyl group, or an aralkyl group having 7 to 18 carbon atoms such as a benzyl group, preferably three of the four substituent groups R³¹ to R³⁴ are an unsubstituted phenyl group or a substituted phenyl group, and for example, a phenyl group or a tolyl group can be exemplified, and the remaining one is an alkyl group having 1 to 18 carbon atoms, an aryl group having 6 to 18 carbon atoms, or an aralkyl group having 7 to 18 carbon atoms. In addition, examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). This compound can be obtained as a commercial product, and examples thereof include tetraalkylphosphonium halides such as a tetra-n-butylphosphonium halide and a tetra-n-propylphosphonium halide, trialkylbenzylphosphonium halides such as a triethylbenzylphosphonium halide, triphenylmonoalkylphosphonium halides such as a triphenylmethylphosphonium halide and a triphenylethylphosphonium halide, a triphenylbenzylphosphonium halide, a tetraphenylphosphonium halide, a tritolylmonoarylphosphonium halide, and a tritolylmonoalkylphosphonium halide (as described above, the halogen atom is a chlorine atom or a bromine atom). In particular, triphenylmonoalkylphosphonium halides such as a triphenylmethylphosphonium halide and a triphenylethylphosphonium halide, triphenylmonoarylphosphonium halides such as a triphenylbenzylphosphonium halide, tritolylmonoarylphosphonium halides such as a tritolylmonophenylphosphonium halide, and tritolylmonoalkylphosphonium halides such as a tritolylmonomethylphosphonium halide (the halogen atom is a chlorine atom or a bromine atom) are preferable.

In addition, examples of the phosphines include primary phosphines such as methylphosphine, ethylphosphine, propylphosphine, isopropylphosphine, isobutylphosphine, and phenylphosphine; secondary phosphines such as dimethylphosphine, diethylphosphine, diisopropylphosphine, diisoamylphosphine, and diphenylphosphine; and tertiary phosphines such as trimethylphosphine, triethylphosphine, triphenylphosphine, methyldiphenylphosphine, and dimethylphenylphosphine.

The compound of Formula (D-8) is a tertiary sulfonium salt having the structure of R³⁵R³⁶R³⁷S⁺Y⁻. R³⁵, R³⁶, and R³⁷ are, for example, an alkyl group having 1 to 18 carbon atoms such as an ethyl group, a propyl group, a butyl group, or cyclohexylmethyl, an aryl group having 6 to 18 carbon atoms such as a phenyl group, or an aralkyl group having 7 to 18 carbon atoms such as a benzyl group, preferably two of the three substituent groups R³⁵ to R³⁷ are an unsubstituted phenyl group or a substituted phenyl group, and for example, a phenyl group or a tolyl group can be exemplified, and the remaining one is an alkyl group having 1 to 18 carbon atoms, an aryl group having 6 to 18 carbon atoms, or an aralkyl group having 7 to 18 carbon atoms. In addition, examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), alcoholate (—O⁻), maleate anion, and nitrate anion. This compound can be obtained as a commercially available product, and examples thereof include trialkylsulfonium halides such as a tri-n-butylsulfonium halide and a tri-n-propylsulfonium halide, dialkylbenzylsulfonium halides such as a diethylbenzylsulfonium halide, diphenylmonoalkylsulfonium halides such as a diphenylmethylsulfonium halide and a diphenylethylsulfonium halide, a triphenylsulfonium halide (as described above, the halogen atom is a chlorine atom or a bromine atom), trialkylsulfonium carboxylates such as a tri-n-butylsulfonium carboxylate and a tri-n-propylsulfonium carboxylate, dialkylbenzylsulfonium carboxylates such as diethylbenzylsulfonium carboxylate, diphenylmonoalkylsulfonium carboxylates such as a diphenylmethylsulfonium carboxylate and a diphenylethylsulfonium carboxylate, and triphenylsulfonium carboxylate. In addition, a triphenylsulfonium halide and a triphenylsulfonium carboxylate can be preferably used.

In addition, a nitrogen-containing silane compound can be added as a curing catalyst. Examples of the nitrogen-containing silane compound include imidazole ring-containing silane compounds such as N-(3-triethoxysilylpropyl)-4,5-dihydroimidazole.

The content of curing catalyst [D] in the composition for forming a silicon-containing resist underlayer film as the first embodiment is preferably 0.1 to 30 parts by mass, more preferably 0.5 to 25 parts by mass, and still more preferably 1 to 20 parts by mass with respect to 100 parts by mass of polysiloxane [A] from the viewpoint of more sufficiently obtaining the effect of the present invention.

The content of curing catalyst [D] in the composition for forming a silicon-containing resist underlayer film as the second embodiment is preferably 0.1 to 30 parts by mass, more preferably 0.5 to 25 parts by mass, and still more preferably 1 to 20 parts by mass with respect to 100 parts by mass of polysiloxane [A′] from the viewpoint of more sufficiently obtaining the effect of the present invention.

### <Component [E]: Nitric Acid>

The composition for forming a silicon-containing resist underlayer film preferably contains nitric acid [E].

Nitric acid [E] may be added at the time of preparing the composition for forming a silicon-containing resist underlayer film, but in the production of the polysiloxane described above, a nitric acid is used as a hydrolysis catalyst or at the time of alcohol capping of a silanol group, and the nitric acid remaining in the polysiloxane varnish can also be treated as nitric acid [E].

The blending amount of nitric acid [E](residual nitric acid amount) can be, for example, 0.0001 mass % to 1 mass %, 0.001 mass % to 0.1 mass %, or 0.005 mass % to 0.05 mass % based on the total mass of the composition for forming a silicon-containing resist underlayer film.

### <Other Additives>

In the composition for forming a silicon-containing resist underlayer film, various additives can be blended depending on the use of the composition.

Examples of the additive include known additives blended in a material (composition) for forming various films that can be used for manufacturing a semiconductor element, such as a resist underlayer film, an antireflection film, and a pattern reversal film, such as a crosslinking agent, a crosslinking catalyst, a stabilizer (organic acid, water, alcohols, or the like), an organic polymer, an acid generator, a surfactant (nonionic surfactant, anionic surfactant, cationic surfactant, silicon-based surfactant, fluorine-based surfactant, UV-curable surfactant, or the like), a pH adjuster, a metal oxide, a rheology controlling agent, and an adhesion aid.

Note that various additives will be exemplified below, but the additives are not limited thereto.

### <<Stabilizer>>

The stabilizer may be added for the purpose of stabilizing the hydrolysis condensate of the hydrolyzable silane, and as a specific example thereof, an organic acid, water, alcohol, or a combination thereof may be added.

Examples of the organic acid include an oxalic acid, a malonic acid, a methylmalonic acid, a succinic acid, a maleic acid, a malic acid, a tartaric acid, a phthalic acid, a citric acid, a glutaric acid, a lactic acid, and a salicylic acid. Among them, an oxalic acid and a maleic acid are preferable. When the organic acid is added, the addition amount thereof is 0.1 to 5.0 mass % with respect to the hydrolysis condensate of the hydrolyzable silane. These organic acids can also serve as pH adjusters.

As the water, pure water, ultrapure water, deionized water, or the like can be used, and when used, the addition amount thereof can be 1 to 20 parts by mass with respect to 100 parts by mass of the composition for forming a silicon-containing resist underlayer film.

The alcohol is preferably one that easily disperses by heating after application, and examples thereof include methanol, ethanol, propanol, i-propanol, and butanol. When an alcohol is added, the addition amount thereof can be 1 to 20 parts by mass with respect to 100 parts by mass of the composition for forming a silicon-containing resist underlayer film.

### <<Organic Polymer>>

By adding the organic polymer to the composition for forming a silicon-containing resist underlayer film, the dry etching rate (amount of reduction in film thickness per unit time), the attenuation coefficient, the refractive index, and the like of the film (resist underlayer film) formed from the composition can be adjusted. The organic polymer is not particularly limited, and is appropriately selected from various organic polymers (polycondensation polymer and addition polymerization polymer) according to the purpose of addition.

Specific examples thereof include addition polymerization polymers and polycondensation polymers such as polyester, polystyrene, polyimide, acrylic polymers, methacrylic polymers, polyvinyl ether, phenol novolac, naphthol novolac, polyether, polyamide, and polycarbonate.

In the present invention, an organic polymer containing an aromatic ring or a heteroaromatic ring such as a benzene ring, a naphthalene ring, an anthracene ring, a triazine ring, a quinoline ring, or a quinoxaline ring, which functions as a light absorption site, can also be suitably used when such a function is needed. Specific examples of such an organic polymer include addition polymerization polymers containing, as a structural unit thereof, an addition polymerizable monomer such as benzyl acrylate, benzyl methacrylate, phenyl acrylate, naphthyl acrylate, anthryl methacrylate, anthrylmethyl methacrylate, styrene, hydroxystyrene, benzyl vinyl ether and N-phenylmaleimide, and polycondensation polymers such as phenol novolac and naphthol novolac, but are not limited thereto.

When an addition polymerization polymer is used as the organic polymer, the polymer may be either a homopolymer or a copolymer.

An addition polymerizable monomer is used in the production of the addition polymerization polymer, and specific examples of such an addition polymerizable monomer include an acrylic acid, a methacrylic acid, an acrylate ester compound, a methacrylate ester compound, an acrylamide compound, a methacrylamide compound, a vinyl compound, a styrene compound, a maleimide compound, maleic anhydride, and acrylonitrile, but are not limited thereto.

Specific examples of the acrylate ester compound include methyl acrylate, ethyl acrylate, normal hexyl acrylate, i-propyl acrylate, cyclohexyl acrylate, benzyl acrylate, phenyl acrylate, anthrylmethyl acrylate, 2-hydroxyethyl acrylate, 3-chloro-2-hydroxypropyl acrylate, 2-hydroxypropyl acrylate, 2,2,2-trifluoroethyl acrylate, 2,2,2-trichloroethyl acrylate, 2-bromoethyl acrylate, 4-hydroxybutyl acrylate, 2-methoxyethyl acrylate, tetrahydrofurfuryl acrylate, 2-methyl-2-adamantyl acrylate, 5-acryloyloxy-6-hydroxynorbornene-2-carboxylic-6-lactone, 3-acryloxypropyltriethoxysilane, and glycidyl acrylate, but are not limited thereto.

Specific examples of the methacrylate ester compound include methyl methacrylate, ethyl methacrylate, normal hexyl methacrylate, i-propyl methacrylate, cyclohexyl methacrylate, benzyl methacrylate, phenyl methacrylate, anthrylmethyl methacrylate, 2-hydroxyethyl methacrylate, 2-hydroxypropyl methacrylate, 2,2,2-trifluoroethyl methacrylate, 2,2,2-trichloroethyl methacrylate, 2-bromoethyl methacrylate, 4-hydroxybutyl methacrylate, 2-methoxyethyl methacrylate, tetrahydrofurfuryl methacrylate, 2-methyl-2-adamantyl methacrylate, 5-methacryloyloxy-6-hydroxynorbornene-2-carboxylic-6-lactone, 3-methacryloxypropyltriethoxysilane, glycidyl methacrylate, 2-phenylethyl methacrylate, hydroxyphenyl methacrylate, and bromophenyl methacrylate, but are not limited thereto.

Specific examples of the acrylamide compound include acrylamide, N-methylacrylamide, N-ethylacrylamide, N-benzylacrylamide, N-phenylacrylamide, N,N-dimethylacrylamide, and N-anthrylacrylamide, but are not limited thereto.

Specific examples of the methacrylamide compound include methacrylamide, N-methylmethacrylamide, N-ethylmethacrylamide, N-benzylmethacrylamide, N-phenylmethacrylamide, N,N-dimethylmethacrylamide, and N-anthrylacrylamide, but are not limited thereto.

Specific examples of the vinyl compound include vinyl alcohol, 2-hydroxyethyl vinyl ether, methyl vinyl ether, ethyl vinyl ether, benzyl vinyl ether, vinylacetic acid, vinyltrimethoxysilane, 2-chloroethyl vinyl ether, 2-methoxyethyl vinyl ether, vinylnaphthalene, and vinylanthracene, but are not limited thereto.

Specific examples of the styrene compound include styrene, hydroxystyrene, chlorostyrene, bromostyrene, methoxystyrene, cyanostyrene, and acetylstyrene, but are not limited thereto.

Specific examples of the maleimide compound include maleimide, N-methylmaleimide, N-phenylmaleimide, N-cyclohexylmaleimide, N-benzylmaleimide, and N-hydroxyethylmaleimide, but are not limited thereto.

When a polycondensation polymer is used as a polymer, the polymer is, for example, a polycondensation polymer composed of a glycol compound and a dicarboxylic acid compound. Examples of the glycol compound include diethylene glycol, hexamethylene glycol, and butylene glycol. Examples of the dicarboxylic acid compound include succinic acid, adipic acid, terephthalic acid, and maleic anhydride. In addition, examples include polyesters, polyamides, and polyimides, such as polypyromellitimide, poly(p-phenyleneterephthalamide), polybutylene terephthalate, and polyethylene terephthalate, but are not limited thereto.

When the organic polymer contains a hydroxy group, the hydroxy group can be crosslinked with, for example, a hydrolysis condensate.

Usually, the organic polymer may have a weight average molecular weight of 1,000 to 1,000,000. In the case of blending the organic polymer, the weight average molecular weight may be, for example, 3,000 to 300,000, or 5,000 to 300,000, or 10,000 to 200,000, from the viewpoints of sufficiently achieving the functional effect of the polymer and suppressing the precipitation in the composition.

Such organic polymers may be used alone or in combination of two or more kinds.

When the composition for forming a silicon-containing resist underlayer film contains an organic polymer, the content cannot be univocally determined, since the content is appropriately determined in consideration of the function of the organic polymer, or the like, and the content may usually be 1 to 200 mass % relative to polysiloxane [A] and polysiloxane [A′], from the viewpoint of, for example, suppressing the precipitation in the composition, the content may be, for example, 100 mass % or less, and is preferably 50 mass % or less, more preferably 30 mass % or less, and from the viewpoint of, for example, sufficiently achieving the effect, the content may be, for example, 5 mass % or more, and preferably 10 mass % or more, more preferably 30 mass % or more.

### <<Acid Generator>>

Examples of the acid generator include a thermal acid generator and a photoacid generator, and a photoacid generator can be preferably used.

Examples of the photoacid generator include an onium salt compound, a sulfonimide compound, and a disulfonyldiazomethane compound, but are not limited thereto. Note that the photoacid generator may also function as a curing catalyst depending on the type thereof, for example, a carboxylate such as a nitrate or a maleate in an onium salt compound described below, or a hydrochloride.

In addition, examples of the thermal acid generator include tetramethylammonium nitrate, but are not limited thereto.

Specific examples of the onium salt compound include iodonium salt compounds, such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-t-butylphenyl)iodonium camphorsulfonate, and bis(4-t-butylphenyl)iodonium trifluoromethanesulfonate; and sulfonium salt compounds, such as triphenylsulfonium hexafluoroantimonate, triphenylsulfonium nonafluoro normal butanesulfonate, triphenylsulfonium camphorsulfonate, triphenylsulfonium trifluoromethanesulfonate, triphenylsulfonium nitrate (nitrate), triphenylsulfonium trifluoroacetate, triphenylsulfonium maleate, and triphenylsulfonium chloride, but are not limited thereto.

Specific examples of the sulfonimide compound include N-(trifluoromethanesulfonyloxy)succinimide, N-(nonafluoro normal butane sulfonyloxy)succinimide, N-(camphorsulfonyloxy)succinimide, and N-(trifluoromethanesulfonyloxy)naphthalimide, but are not limited thereto.

Specific examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane, but are not limited thereto.

When the composition for forming a silicon-containing resist underlayer film contains an acid generator, the content cannot be univocally determined, since the content is appropriately determined in consideration of, for example, the type of the acid generator, the content is usually 0.01 to 5 mass % relative to polysiloxane [A] and polysiloxane [A′], from the viewpoint of, for example, suppressing the precipitation of the acid generator in the composition, the content is preferably 3 mass % or less, more preferably 1 mass % or less, and from the viewpoint of, for example, sufficiently achieving the effect, the content is preferably 0.1 mass % or more, more preferably 0.5 mass % or more.

Note that the acid generators may be used alone or in combination of two or more kinds, and a photoacid generator and a thermal acid generator may be used in combination.

### <<Surfactant>>

When the composition for forming a silicon-containing resist underlayer film is applied to a substrate or an organic underlayer film, the surfactant is effective for suppressing generation of pinholes, striations, and the like. Examples of the surfactant include a nonionic surfactant, an anionic surfactant, a cationic surfactant, a silicon-based surfactant, a fluorine-based surfactant, and an UV curable surfactant. More specifically, examples include nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylallyl ethers, such as polyoxyethylene octylphenol ether and polyoxyethylene nonylphenol ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants, such as trade names EFTOP (registered trademark) EF301, EF303, and EF352 (manufactured by Mitsubishi Materials Electronic Chemicals Co., Ltd. (former Tohkem Products Corporation)), trade names MEGAFACE (registered trademark) F171, F173, R-08, R-30, R-30N, and R-40LM (manufactured by DIC Corporation), Fluorad FC430 and FC431 (manufactured by 3M Japan Limited), trade name Asahi Guard (registered trademark) AG710 (manufactured by AGC Inc.) and trade names SURFLON 5-382, SC101, SC102, SC103, SC104, SC105, and SC106 (manufactured by AGC Seimi Chemical Co., Ltd.); and Organosiloxane Polymer KP341 (manufactured by Shin-Etsu Chemical Co., Ltd.), but are not limited thereto.

These surfactants may be used alone or in combination of two or more kinds.

When the composition for forming a silicon-containing resist underlayer film contains a surfactant, the content is usually 0.0001 to 5 mass %, preferably 0.001 to 4 mass %, and more preferably 0.01 to 3 mass % with respect to polysiloxane [A] or polysiloxane [A′].

### <<Rheology Controlling Agent>>

The rheology controlling agent is added mainly for the purpose of improving the fluidity of the composition for forming a silicon-containing resist underlayer film, and particularly for the purpose of improving the uniformity of the film thickness of a film formed in a baking process or improving the fillability of the composition in the interior of a hole. Specific examples include phthalic acid derivatives, such as dimethyl phthalate, diethyl phthalate, di-i-butyl phthalate, dihexyl phthalate, and butyl-i-decyl phthalate; adipic acid derivatives, such as di-normal butyl adipate, di-i-butyl adipate, di-i-octyl adipate, and octyldecyl adipate; maleic acid derivatives, such as di-normal butyl maleate, diethyl maleate, and dinonyl maleate; oleic acid derivatives, such as methyl oleate, butyl oleate, and tetrahydrofurfuryl oleate; and stearic acid derivatives, such as normal butyl stearate and glyceryl stearate.

In the case of use of these rheology controlling agents, the addition amount thereof is usually less than 30 mass % relative to the entire film-forming component of the composition for forming a silicon-containing resist underlayer film.

### <<Adhesion Aid>>

The adhesion aid is added mainly for the purpose of improving the adhesion between a substrate, an organic underlayer film, or a resist, and a film (resist underlayer film) formed from the composition for forming a silicon-containing resist underlayer film, and particularly for the purpose of suppressing and preventing removal of the resist during development. Specific examples include chlorosilanes, such as trimethylchlorosilane, dimethylvinylchlorosilane, methyldiphenylchlorosilane, and chloromethyldimethylchlorosilane; alkoxysilanes, such as trimethylmethoxysilane, dimethyldiethoxysilane, methyldimethoxysilane, dimethylvinylethoxysilane; silazanes, such as hexamethyldisilazane, N,N′-bis(trimethylsilyl)urea, dimethyltrimethylsilylamine, and trimethylsilylimidazole; other silanes, such as γ-chloropropyltrimethoxysilane, γ-aminopropyltriethoxysilane, and γ-glycidoxypropyltrimethoxysilane; heterocyclic compounds, such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; and urea or thiourea compounds, such as 1,1-dimethylurea and 1,3-dimethylurea.

In the case of use of these adhesion aids, the addition amount is usually less than 5 mass %, preferably less than 2 mass %, relative to the film-forming component of the composition for forming a silicon-containing resist underlayer film.

### <<pH Adjuster>>

In addition, examples of the pH adjuster can include other acids having one or two or more carboxylic acid groups such as the organic acids mentioned above as the stabilizer. When a pH adjuster is used, the addition amount thereof can be 0.01 to 20 parts by mass, 0.01 to 10 parts by mass, or 0.01 to 5 parts by mass with respect to 100 parts by mass of polysiloxane [A] or polysiloxane [A′].

### <<Metal Oxide>>

In addition, examples of the metal oxide that can be added to the composition for forming a silicon-containing resist underlayer film include a metal such as tin (Sn), titanium (Ti), aluminum (Al), zirconium (Zr), zinc (Zn), niobium (Nb), tantalum (Ta), and tungsten (W), and an oxide of one kind or a combination of two or more kinds among metalloids such as boron (B), silicon (Si), germanium (Ge), arsenic (As), antimony (Sb), and tellurium (Te), but are not limited thereto.

The concentration of the film-forming component in the composition for forming a silicon-containing resist underlayer film can be, for example, 0.1 to 50 mass %, 0.1 to 30 mass %, 0.1 to 25 mass %, or 0.5 to 20.0 mass % with respect to the total amount of the composition.

The content of polysiloxane [A] or polysiloxane [A′] in the film-forming component is usually 20 mass % to 100 mass %, but from the viewpoint of obtaining the effect of the present invention with good reproducibility or the like, the lower limit thereof is preferably 50 mass %, more preferably 60 mass %, still more preferably 70 mass %, and yet still more preferably 80 mass %, the upper limit thereof is preferably 99 mass %, and the rest thereof can be an additive described below.

In addition, the composition for forming a silicon-containing resist underlayer film preferably has a pH of 2 to 5, and more preferably has a pH of 3 to 4.

The composition for forming a silicon-containing resist underlayer film of the first embodiment can be produced by mixing polysiloxane [A], solvent [C], and when other components are contained as desired, the other components. At this time, a solution containing polysiloxane [A] may be prepared in advance, and this solution may be mixed with solvent [C] and other components.

The mixing order is not particularly limited. For example, solvent [C] may be added to and mixed with the solution containing polysiloxane [A], and the other components may be added to the mixture, or the solution containing polysiloxane [A], solvent [C], and the other components may be simultaneously mixed.

If necessary, solvent [C] may be further added at the end, or some components relatively soluble in solvent [C] may not be included in the mixture, and the components may be added at the end, but, from the viewpoint of suppressing aggregation and separation of the constituent components and preparing a composition excellent in uniformity with good reproducibility, it is preferable to prepare a solution in which polysiloxane [A] is dissolved well in advance, and prepare a composition using the solution. Note that attention is paid to the fact that polysiloxane [A] may aggregate or precipitate when mixed, depending on the type and amount of solvent [C] to be mixed together, the amount and properties of other components, and the like. In addition, when a composition is prepared using the solution in which polysiloxane [A] is dissolved, attention is also paid to the fact that it is necessary to determine the concentration of the solution of polysiloxane [A] and the use amount thereof so that polysiloxane [A] in the finally obtained composition is in a desired amount.

In preparation of the composition, heating may be appropriately performed as long as the components are not decomposed or altered.

The composition for forming a silicon-containing resist underlayer film of the second embodiment can be produced by mixing polysiloxane [A′], hydrolyzable silane (A) having a carbon-carbon triple bond [B], solvent [C], and when other components are contained as desired, the other components. At this time, a solution containing polysiloxane [A′] may be prepared in advance, and this solution may be mixed with hydrolyzable silane (A) having a carbon-carbon triple bond [B], solvent [C], and other components.

The mixing order is not particularly limited. For example, hydrolyzable silane (A) having a carbon-carbon triple bond [B] and solvent [C] may be added to and mixed with the solution containing polysiloxane [A′], and the other components may be added to the mixture, or the solution containing polysiloxane [A′], hydrolyzable silane (A) having a carbon-carbon triple bond [B], solvent [C], and the other components may be simultaneously mixed.

If necessary, solvent [C] may be further added at the end, or some components relatively soluble in solvent [C] may not be included in the mixture, and the components may be added at the end, but, from the viewpoint of suppressing aggregation and separation of the constituent components and preparing a composition excellent in uniformity with good reproducibility, it is preferable to prepare a solution in which polysiloxane [A′] is dissolved well in advance, and prepare a composition using the solution. Note that attention is paid to the fact that polysiloxane [A′] may aggregate or precipitate when mixed, depending on the types and amounts of hydrolyzable silane (A) having a carbon-carbon triple bond [B] and solvent [C] to be mixed together, the amount and properties of other components, and the like. In addition, when a composition is prepared using the solution in which polysiloxane [A′] is dissolved, attention is also paid to the fact that it is necessary to determine the concentration of the solution of polysiloxane [A′] and the use amount thereof so that polysiloxane [A′] in the finally obtained composition is in a desired amount.

In preparation of the composition, heating may be appropriately performed as long as the components are not decomposed or altered.

In the present invention, filtration may be performed using a submicrometer-order filter or the like at a stage in the middle of producing the composition for forming a silicon-containing resist underlayer film or after mixing all the components. Note that although the material type of the filter used at this time is not limited, for example, a nylon filter, a fluororesin filter, or the like can be used.

The composition for forming a silicon-containing resist underlayer film of the present invention can be suitably used as a composition for forming a resist underlayer film used in a lithography process.

### (Resist Underlayer Film, Semiconductor Processing Substrate, Pattern Forming Method, and Method for Manufacturing Semiconductor Element)

The resist underlayer film of the present invention is a cured product of the composition for forming a silicon-containing resist underlayer film of the present invention.

The semiconductor processing substrate of the present invention includes, for example, the silicon-containing resist underlayer film of the present invention.

A method for manufacturing a semiconductor element according to the present invention includes, for example:
a step of forming an organic underlayer film on a substrate;
a step of forming a resist underlayer film on the organic underlayer film using a composition for forming a silicon-containing resist underlayer film of the present invention; and
a step of forming a resist film on the resist underlayer film.

A pattern forming method of the present invention includes, for example:
a step of forming an organic underlayer film on a semiconductor substrate;
a step of applying a composition for forming a silicon-containing resist underlayer film of the present invention on the organic underlayer film and baking the composition to form a resist underlayer film;
a step of applying a composition for forming a resist film on the resist underlayer film to form a resist film;
a step of exposing and developing the resist film to obtain a resist pattern;
a step of etching the resist underlayer film using the resist pattern as a mask; and
a step of etching the organic underlayer film using the patterned resist underlayer film as a mask.

Hereinafter, as one aspect of the present invention, a semiconductor processing substrate, a pattern forming method, and a method for manufacturing a semiconductor element using the silicon-containing resist underlayer film of the present invention or the composition for forming a silicon-containing resist underlayer film of the present invention will be described.

First, the composition for forming a silicon-containing resist underlayer film of the present invention is applied onto a substrate [including, for example, a semiconductor substrate such as a silicon wafer coated with a silicon oxide film, a silicon nitride film, or a silicon oxynitride film, a silicon nitride substrate, a quartz substrate, a glass substrate (alkali-free glass, low-alkali glass, and crystallized glass), a glass substrate on which an indium tin oxide (ITO) film or an indium zinc oxide (IZO) film is formed, a plastic (polyimide, PET, or the like) substrate, a low dielectric constant material (low-k material) coated substrate, a flexible substrate, or the like] used for manufacturing a precision integrated circuit element by an appropriate application method such as a spinner or a coater, and then baked using a heating means such as a hot plate to form a cured product of the composition, thereby forming a resist underlayer film. Hereinafter, in the present specification, the resist underlayer film refers to the silicon-containing resist underlayer film of the present invention or a film formed from the composition for forming a silicon-containing resist underlayer film of the present invention.

The baking conditions are appropriately selected from a baking temperature of 40° C. to 400° C., or 80° C. to 250° C., and a baking time of 0.3 minutes to 60 minutes. Preferably, the baking temperature is 150° C. to 250° C., and the baking time is 0.5 minutes to 2 minutes.

The film thickness of the resist underlayer film formed here is, for example, 10 nm to 1,000 nm, or 20 nm to 500 nm, or 50 nm to 300 nm, or 100 nm to 200 nm, or 10 to 150 nm.

Note that as the composition for forming a silicon-containing resist underlayer film to be used at the time of forming the resist underlayer film, a composition for forming a silicon-containing resist underlayer film filtered through a nylon filter can be used. Here, the composition for forming a silicon-containing resist underlayer film filtered through a nylon filter refers to a composition that has been filtered through a nylon filter at a stage in the middle of producing the composition for forming a silicon-containing resist underlayer film or after mixing all the components.

One aspect of the present invention is an aspect in which an organic underlayer film is formed on a substrate and then a resist underlayer film is formed on the organic underlayer film, but an aspect in which an organic underlayer film is not provided may be adopted in some cases.

The organic underlayer film used here is not particularly limited, and can be arbitrarily selected and used from those conventionally used in the lithography process.

By adopting an aspect in which an organic underlayer film on a substrate, a resist underlayer film on the organic underlayer film, and a resist film to be described below provided on the resist underlayer film, the pattern width of the photoresist film is narrowed, and even when the photoresist film is thinly applied in order to prevent pattern collapse, the substrate can be processed by selecting an appropriate etching gas to be described below. For example, the resist underlayer film can be processed using a fluorine-based gas having a sufficiently high etching rate with respect to the photoresist film as an etching gas, the organic underlayer film can be processed using an oxygen-based gas having a sufficiently high etching rate with respect to the resist underlayer film as an etching gas, and the substrate can be processed using a fluorine-based gas having a sufficiently high etching rate with respect to the organic underlayer film as an etching gas.

Note that the substrate and the coating method that can be used at this time are the same as those described above.

Next, for example, a layer (resist film) of a photoresist material is formed on the resist underlayer film. The resist film can be formed by a known method, that is, by applying a coating type resist material (composition for forming a resist film) on the resist underlayer film and baking the resist material.

The film thickness of the resist film is, for example, 10 nm to 10,000 nm, or 100 nm to 2,000 nm, or 200 nm to 1,000 nm, or 30 nm to 200 nm.

The photoresist material used for the resist film formed on the resist underlayer film is not particularly limited as long as it is sensitive to light (for example, KrF excimer laser, ArF excimer laser, or the like) used for exposure, and both a negative photoresist material and a positive photoresist material can be used. Examples include a positive photoresist material formed of a novolac resin and a 1,2-naphthoquinone diazide sulfonic acid ester; a chemically amplified photoresist material formed of a binder having a group that decomposes with an acid to thereby increase the alkali dissolution rate and a photoacid generator; a chemically amplified photoresist material formed of a low-molecular-weight compound that decomposes with an acid to thereby increase the alkali dissolution rate of the photoresist material, an alkali-soluble binder, and a photoacid generator; and a chemically amplified photoresist material formed of a binder having a group that decomposes with an acid to thereby increase the alkali dissolution rate, a low-molecular-weight compound that decomposes with an acid to thereby increase the alkali dissolution rate of the photoresist material, and a photoacid generator.

Specific examples of commercially available products include, but are not limited to, trade name APEX-E manufactured by Shipley, trade name PAR710 manufactured by Sumitomo Chemical Company, Limited, trade name AR2772JN manufactured by JSR, and trade name SEPR430 manufactured by Shin-Etsu Chemical Co., Ltd. In addition, other examples include fluorine atom-containing polymer-based photoresist materials described, for example, in Proc. SPIE, Vol. 3999, 330-334 (2000), Proc. SPIE, Vol. 3999, 357 to 364 (2000), and Proc. SPIE, Vol. 3999, 365-374 (2000).

In addition, for the resist film formed on the resist underlayer film, a resist film for electron beam lithography (also referred to as an electron beam resist film) or a resist film for EUV lithography (also referred to as an EUV resist film) can be used instead of the photoresist film, that is, the composition for forming a silicon-containing resist underlayer film of the present invention can be used for forming a resist underlayer film for electron beam lithography or for forming a resist underlayer film for EUV lithography. In particular, it is suitable as a composition for forming a resist underlayer film for EUV lithography.

As the electron beam resist material for forming the electron beam resist film, either a negative material or a positive material can be used. Specific examples thereof include a chemically amplified resist material formed of an acid generator and a binder having a group that decomposes with an acid to thereby change the alkali dissolution rate; a chemically amplified resist material formed of an alkali-soluble binder, an acid generator, and a low-molecular-weight compound that decomposes with an acid to thereby change the alkali dissolution rate of the resist material; a chemically amplified resist material formed of an acid generator, a binder having a group that decomposes with an acid to thereby change the alkali dissolution rate, and a low-molecular-weight compound that decomposes with an acid to thereby change the alkali dissolution rate of the resist material; a non-chemically amplified resist material formed of a binder having a group that decomposes with electron beams to thereby change the alkali dissolution rate; and a non-chemically amplified resist material formed of a binder having a moiety that is cut with electron beams to thereby change the alkali dissolution rate. Also in the case of use of these electron beam resist materials, a resist film pattern can be formed by using electron beams as an irradiation source in the same manner as in the case of using the photoresist material.

In addition, as the EUV resist material for forming the EUV resist film, a methacrylate resin-based resist material or a metal oxide resist material can be used.

Examples of the metal oxide resist material include a coating composition containing a metal oxo-hydroxo network having an organic ligand by a metal carbon bond and/or a metal carboxylate bond described in JP 2019-113855 A.

Next, the resist film formed on the resist underlayer film is exposed through a predetermined mask (reticle). For the exposure, a KrF excimer laser (wavelength: 248 nm), an ArF excimer laser (wavelength: 193 nm), an F₂ excimer laser (wavelength: 157 nm), EUV (wavelength: 13.5 nm), an electron beam, or the like can be used.

After the exposure, post exposure bake may be performed as necessary. The post exposure bake is performed under conditions appropriately selected from a heating temperature of 70° C. to 150° C. and a heating time of 0.3 minutes to 10 minutes.

Next, development is performed with a developer (for example, an alkaline developer). As a result, for example, when a positive photoresist film is used, the photoresist film of the exposed portion is removed, and a pattern of the photoresist film is formed.

Examples of the developer (alkaline developer) include alkaline aqueous solutions (alkaline developers), for example, aqueous solutions of alkali metal hydroxides, such as potassium hydroxide and sodium hydroxide; aqueous solutions of quaternary ammonium hydroxides, such as tetramethylammonium hydroxide, tetraethylammonium hydroxide, and choline; and aqueous solutions of amines, such as ethanolamine, propylamine, and ethylenediamine. Further, a surfactant or the like can be added to these developers. The conditions for development are appropriately selected from a temperature of 5 to 50° C. and a time of 10 seconds to 600 seconds.

In addition, in the present invention, an organic solvent can be used as the developer, and development is performed with the developer (solvent) after exposure. As a result, for example, when a negative photoresist film is used, the photoresist film of the unexposed portion is removed, and a pattern of the photoresist film is formed.

Specific examples of the developer (organic solvent) include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Further, a surfactant or the like can be added to these developers. The conditions for development are appropriately selected from a temperature of 5° C. to 50° C. and a time of 10 seconds to 600 seconds.

The pattern of the photoresist film (upper layer) thus formed is used as a protective film for removing the resist underlayer film (intermediate layer), and then a film including the patterned photoresist film and the patterned resist underlayer film (intermediate layer) is used as a protective film for removing the organic underlayer film (lower layer). Finally, the substrate is processed using the patterned resist underlayer film (intermediate layer) and the patterned organic underlayer film (lower layer) as protective films.

Removal (patterning) of the resist underlayer film (intermediate layer) performed using the pattern of the resist film (upper layer) as the protective film is performed through dry etching, and gases such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, and dichloroborane can be used.

Note that a halogen-based gas is preferably used for dry etching of the resist underlayer film. In dry etching using a halogen-based gas, a resist film (photoresist film) basically made of an organic substance is hardly removed. On the other hand, the resist underlayer film containing a large amount of silicon atoms is quickly removed by the halogen-based gas. Therefore, a decrease in the film thickness of the photoresist film due to dry etching of the resist underlayer film can be suppressed. Then, as a result, the photoresist film can be used as a thin film. Therefore, dry etching of the resist underlayer film is preferably performed with a fluorine-based gas, and examples of the fluorine-based gas include tetrafluoromethane (CF₄), perfluorocyclobutane (C₄F₈), perfluoropropane (C₃F₈), trifluoromethane, and difluoromethane (CH₂F₂), but are not limited thereto.

When the organic underlayer film is provided between the substrate and the resist underlayer film, the organic underlayer film (lower layer) is preferably removed (patterned) by dry etching with an oxygen-based gas (oxygen gas, oxygen/carbonyl sulfide (COS) mixed gas, and the like) using a film including (the patterned resist film (upper layer) if remaining,) the patterned resist film (upper layer) and the patterned resist underlayer film (intermediate layer) as a protective film. This is because the resist underlayer film of the present invention containing a large amount of silicon atoms is hardly removed by dry etching using an oxygen-based gas.

Thereafter, the processing (patterning) of the (semiconductor) substrate performed using the patterned resist underlayer film (intermediate layer) and, as desired, the patterned organic underlayer film (lower layer) as protective films is preferably performed dry etching using a fluorine-based gas.

Examples of the fluorine-based gas include tetrafluoromethane (CF₄), perfluorocyclobutane (C₄F₈), perfluoropropane (C₃F₈), trifluoromethane, and difluoromethane (CH₂F₂).

After the removal (patterning) of the organic underlayer film or after the processing (patterning) of the substrate, the resist underlayer film may be removed. The resist underlayer film may be removed by dry etching or wet etching (wet method).

Dry etching of the resist underlayer film is preferably performed with a fluorine-based gas as mentioned regarding the patterning, and examples of the fluorine-based gas include tetrafluoromethane (CF₄), perfluorocyclobutane (C₄F₈), perfluoropropane (C₃F₈), trifluoromethane, and difluoromethane (CH₂F₂), but are not limited thereto.

Examples of the chemical liquid used for wet etching of the resist underlayer film include alkaline solutions such as a dilute hydrofluoric acid (hydrofluoric acid), a buffered hydrofluoric acid (mixed solution of HF and NH₄F), an aqueous solution containing a hydrochloric acid and a hydrogen peroxide (SC-2 chemical liquid), an aqueous solution containing a sulfuric acid and a hydrogen peroxide (SPM chemical liquid), an aqueous solution containing a hydrofluoric acid and a hydrogen peroxide (FPM chemical liquid), and an aqueous solution containing ammonia and a hydrogen peroxide (SC-1 chemical liquid). In addition, examples of the alkaline solution include an aqueous solution containing 1 to 99 mass % of ammonia, tetramethylammonium hydroxide (TMAH), tetraethylammonium hydroxide, tetrapropylammonium hydroxide, tetrabutylammonium hydroxide, choline hydroxide, benzyltrimethylammonium hydroxide, benzyltriethylammonium hydroxide, DBU (diazabicycloundecene), DBN (diazabicyclononene), hydroxylamine, 1-butyl-1-methylpyrrolidinium hydroxide, 1-propyl-1-methylpyrrolidinium hydroxide, 1-butyl-1-methylpiperidinium hydroxide, 1-propyl-1-methylpiperidinium hydroxide, mepiquat hydroxide, trimethylsulfonium hydroxide, hydrazines, ethylenediamines, or guanidine, in addition to the ammonia hydrogen peroxide (SC-1 chemical liquid) obtained by mixing ammonia, hydrogen peroxide water, and water described above. These chemical liquids can also be used in mixture.

In addition, an organic antireflection film can be formed on the resist underlayer film before the resist film is formed. The composition of the antireflection film to be used is not particularly limited, and for example, the composition can be arbitrarily selected and used from those conventionally used in a lithography process, and the antireflection film can be formed by a conventionally used method, for example, coating and baking with a spinner and a coater.

In addition, the substrate to which the composition for forming a silicon-containing resist underlayer film is applied may have an organic or inorganic antireflection film formed by a CVD method or the like on the surface thereof, and a resist underlayer film may be formed thereon. When the organic underlayer film is formed on the substrate and then the resist underlayer film of the present invention is formed on the organic underlayer film, the substrate to be used may have an organic or inorganic antireflection film formed by a CVD method or the like on the surface thereof.

The resist underlayer film formed from the composition for forming a silicon-containing resist underlayer film may also absorb light depending on the wavelength of the light used in the lithography process. Then, in such a case, it is possible to function as an antireflection film having an effect of preventing reflected light from the substrate.

Further, the resist underlayer film can also be used as a layer for preventing interaction between a substrate and a resist film (such as a photoresist film), a layer having a function of preventing a bad effect on the substrate of a material used for the resist film or a substance generated at the time of exposure to the resist film, a layer having a function of preventing diffusion of a substance generated from the substrate to the resist film at the time of heating and baking, a barrier layer for reducing a poisoning effect of the resist film by a semiconductor substrate dielectric layer, and the like.

The resist underlayer film can be applied to a substrate having via holes for use in a dual damascene process, and can be used as an embedding material (filling material) capable of filling the holes without gaps. In addition, the resist underlayer film can also be used as a planarization material for planarizing the surface of a semiconductor substrate having irregularities.

In addition, the resist underlayer film of the present invention can prevent reflection of exposure light, for example, UV (ultraviolet) light or DUV (deep ultraviolet) light (ArF light, KrF light), which is not preferable in EUV exposure (wavelength: 13.5 nm), from a substrate or an interface without intermixing with, for example, the EUV resist film, in addition to the function as an underlayer film of the EUV resist film or a hard mask. Therefore, in order to form the underlayer antireflection film of the EUV resist film, the composition for forming a silicon-containing resist underlayer film of the present invention can be suitably used. That is, the resist underlayer film can efficiently prevent reflection as an underlayer of the EUV resist film. When used as the EUV resist underlayer film, the process can be performed in the same manner as the underlayer film for photoresist.

By using the semiconductor processing substrate including the resist underlayer film of the present invention and the semiconductor substrate described above, the semiconductor substrate can be suitably processed.

In addition, by the method for manufacturing a semiconductor element including the step of forming an organic underlayer film, the step of forming the resist underlayer film using the composition for forming a silicon-containing resist underlayer film of the present invention on the organic underlayer film, and the step of forming a resist film on the siresist underlayer film as described above, processing of a semiconductor substrate with high accuracy can be achieved with high reproducibility, and therefore stable manufacturing of a semiconductor element can be expected.

### EXAMPLES

Hereinafter, the present invention will be described more specifically with reference to synthesis examples and examples, but the present invention is not limited to only the examples described below.

Note that apparatuses and conditions used for analyzing physical properties of a sample in the examples are described below.

### (1) Molecular Weight Measurement

The molecular weight of the polysiloxane used in the present invention is a molecular weight obtained in terms of polystyrene by GPC analysis.

The measurement of GPC can be performed under conditions of, for example, a GPC apparatus (trade name: HLC-8220GPC, manufactured by Tosoh Corporation), a GPC column (trade name: Shodex (registered trademark) KF803L, KF802, KF801, manufactured by Showa Denko Co., Ltd.), at a column temperature of 40° C., with the use of tetrahydrofuran as an eluent (elution solvent), at a flow rate (flow speed) of 1.0 mL/min, with polystyrene (manufactured by Showa Denko Co., Ltd.) as a standard sample.

### (2) ¹H-NMR

Evaluation was performed using a nuclear magnetic resonance apparatus 1H-NMR (400 MHz) manufactured by JEOL, and d6-Acetone as a solvent.

### (3) Residual Nitric Acid Amount

The amount of nitric acid remaining in the system was measured by ion chromatography evaluation.

### [1] Synthesis of Polymer (Hydrolysis Condensate)

### Synthesis Example 1

A 300 mL flask was charged with 16.66 g of tetraethoxysilane, 12.87 g of methyltriethoxysilane, 2.43 g of O-(propargyl)-N-(triethoxysilylpropyl) carbamate, and 47.89 g of propylene glycol monoethyl ether, and while the resultant mixture solution was stirred with a magnetic stirrer, 20.18 g of 0.1M aqueous nitric acid solution was added dropwise.

After the dropwise addition, the flask was transferred to an oil bath adjusted to 60° C., and reacted for 20 hours. Thereafter, ethanol and water as reaction by-products were distilled under reduced pressure and concentrated to obtain a hydrolysis condensate (polymer) solution.

Propylene glycol monoethyl ether was further added to the obtained solution, the concentration was adjusted so as to achieve a solvent proportion of propylene glycol monomethyl ether of 100% and a solid residue content of 20 mass % at 140° C., and filtration was performed with a nylon filter (pore size: 0.1 μm).

The resultant polymer contained a polysiloxane having a structure represented by the formula described below and have a weight average molecular weight of 3,000 as determined by GPC in terms of polystyrene. In addition, from ¹H-NMR, the amount capped with propylene glycol monoethyl ether was 3 mol % with respect to Si atoms. In addition, the residual nitric acid amount in the polymer solution was 0.07%.

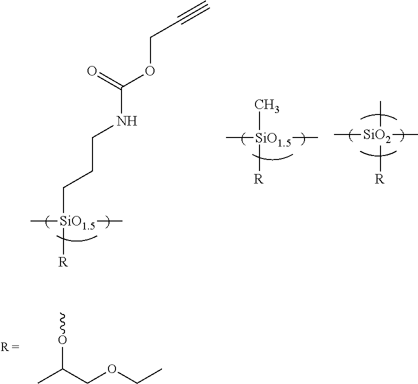

### Synthesis Example 2

A 300 mL flask was charged with 15.87 g of tetraethoxysilane, 9.51 g of methyltriethoxysilane, 6.93 g of O-(propargyl)-N-(triethoxysilylpropyl) carbamate, and 48.47 g of propylene glycol monoethyl ether, and while the resultant mixture solution was stirred with a magnetic stirrer, 19.22 g of 0.1M aqueous nitric acid solution was added dropwise.

After the dropwise addition, the flask was transferred to an oil bath adjusted to 60° C., and reacted for 20 hours. Thereafter, ethanol and water as reaction by-products were distilled under reduced pressure and concentrated to obtain a hydrolysis condensate (polymer) solution.

Propylene glycol monoethyl ether was further added to the obtained solution, the concentration was adjusted so as to achieve a solvent proportion of propylene glycol monomethyl ether of 100% and a solid residue content of 20 mass % at 140° C., and filtration was performed with a nylon filter (pore size: 0.1 μm).

The resultant polymer contained a polysiloxane having a structure represented by the formula described below and have a weight average molecular weight of 3,400 as determined by GPC in terms of polystyrene. In addition, from ¹H-NMR, the amount capped with propylene glycol monoethyl ether was 3 mol % with respect to Si atoms. In addition, the residual nitric acid amount in the polymer solution was 0.08%.

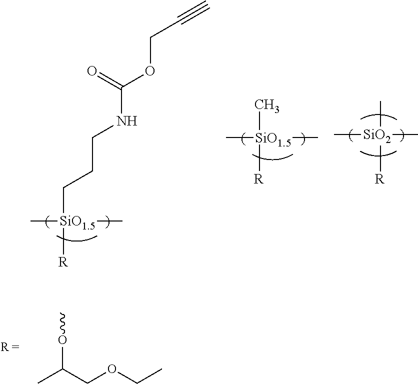

### Synthesis Example 3

A 300 mL flask was charged with 15.9 g of tetraethoxysilane, 10.90 g of methyltriethoxysilane, 3.16 g of diallyl isocyanurate propyl triethoxysilane, 2.32 g of O-(propargyl)-N-(triethoxysilylpropyl) carbamate, and 48.4 g of propylene glycol monoethyl ether, and while the resultant mixture solution was stirred with a magnetic stirrer, 19.3 g of aqueous nitric acid solution (0.1 mol/L) was added dropwise.

After the dropwise addition, the flask was transferred to an oil bath adjusted to 60° C., and refluxed for 20 hours. Thereafter, ethanol and water as reaction by-products were distilled under reduced pressure and concentrated to obtain a hydrolysis condensate (polymer) solution.

Propylene glycol monoethyl ether was further added to the solution, the concentration was adjusted so as to achieve a solvent proportion of propylene glycol monomethyl ether of 100% and a solid residue content of 20 mass % at 140° C., and filtration was performed with a nylon filter (pore size: 0.1 μm).

The resultant polymer contained a polysiloxane having a structure represented by the formula described below and have a weight average molecular weight of Mw 3,200 as determined by GPC in terms of polystyrene. In addition, from ¹H-NMR, the amount capped with propylene glycol monoethyl ether was 2 mol % with respect to Si atoms. In addition, the residual nitric acid amount in the polymer solution was 0.08%.

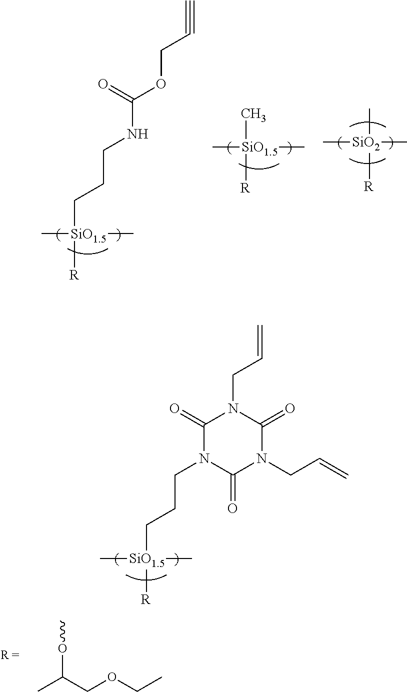

### Synthesis Example 4

A 300 mL flask was charged with 16.39 g of tetraethoxysilane, 11.22 g of methyltriethoxysilane, 2.07 g of thiocyanate propyltriethoxysilane, 2.39 g of O-(propargyl)-N-(triethoxysilylpropyl) carbamate, and 48.1 g of propylene glycol monoethyl ether, and while the resultant mixture solution was stirred with a magnetic stirrer, 19.8 g of aqueous nitric acid solution (0.1 mol/L) was added dropwise.

After the dropwise addition, the flask was transferred to an oil bath adjusted to 60° C., and refluxed for 20 hours. Thereafter, ethanol and water as reaction by-products were distilled under reduced pressure and concentrated to obtain a hydrolysis condensate (polymer) solution.

Propylene glycol monoethyl ether was further added to the solution, the concentration was adjusted so as to achieve a solvent proportion of propylene glycol monomethyl ether of 100% and a solid residue content of 20 mass % at 140° C., and filtration was performed with a nylon filter (pore size: 0.1 μm).

The resultant polymer contained a polysiloxane having a structure represented by the formula described below and have a weight average molecular weight of Mw 3,000 as determined by GPC in terms of polystyrene. In addition, from ¹H-NMR, the amount capped with propylene glycol monoethyl ether was 3 mol % with respect to Si atoms. In addition, the residual nitric acid amount in the polymer solution was 0.09%.

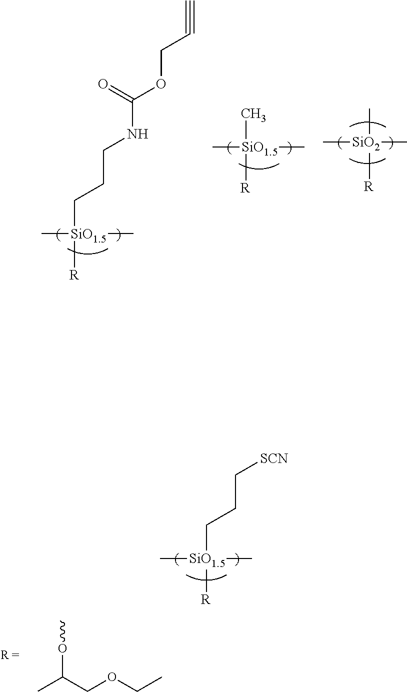

### Synthesis Example 5

A 300 mL flask was charged with 16.13 g of tetraethoxysilane, 11.04 g of methyltriethoxysilane, 2.67 g of triethoxy((2-methoxy-4-(methoxymethyl)phenoxy)methyl)silane, 2.35 g of O-(propargyl)-N-(triethoxysilylpropyl) carbamate, and 48.3 g of propylene glycol monoethyl ether, and while the resultant mixture solution was stirred with a magnetic stirrer, 19.5 g of aqueous nitric acid solution (0.1 mol/L) was added dropwise.

After the dropwise addition, the flask was transferred to an oil bath adjusted to 60° C., and refluxed for 20 hours. Thereafter, ethanol and water as reaction by-products were distilled under reduced pressure and concentrated to obtain a hydrolysis condensate (polymer) solution.

Propylene glycol monoethyl ether was further added to the solution, the concentration was adjusted so as to achieve a solvent proportion of propylene glycol monomethyl ether of 100% and a solid residue content of 20 mass % at 140° C., and filtration was performed with a nylon filter (pore size: 0.1 μm).

The resultant polymer contained a polysiloxane having a structure represented by the formula described below and have a weight average molecular weight of Mw 3,500 as determined by GPC in terms of polystyrene. In addition, from ¹H-NMR, the amount capped with propylene glycol monoethyl ether was 4 mol % with respect to Si atoms. In addition, the residual nitric acid amount in the polymer solution was 0.08%.

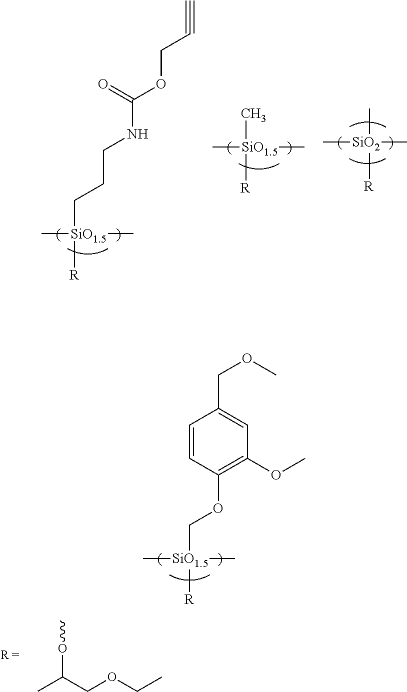

### Synthesis Example 6

A 300 mL flask was charged with 16.4 g of tetraethoxysilane, 11.23 g of methyltriethoxysilane, 2.02 g of bicyclo[2.2.1]hept-5-ene-2-yltriethoxysilane, 2.39 g of O-(propargyl)-N-(triethoxysilylpropyl) carbamate, and 48.1 g of propylene glycol monoethyl ether, and while the resultant mixture solution was stirred with a magnetic stirrer, 19.9 g of aqueous nitric acid solution (0.1 mol/L) was added dropwise.

After the dropwise addition, the flask was transferred to an oil bath adjusted to 60° C., and refluxed for 20 hours. Thereafter, ethanol and water as reaction by-products were distilled under reduced pressure and concentrated to obtain a hydrolysis condensate (polymer) solution.

Propylene glycol monoethyl ether was further added, the concentration was adjusted so as to achieve a solvent proportion of propylene glycol monomethyl ether of 100% and a solid residue content of 20 mass % at 140° C., and filtration was performed with a nylon filter (pore size: 0.1 μm).

The resultant polymer contained a polysiloxane having a structure represented by the formula described below and have a weight average molecular weight of Mw 2,800 as determined by GPC in terms of polystyrene. In addition, from ¹H-NMR, the amount capped with propylene glycol monoethyl ether was 3 mol % with respect to Si atoms. In addition, the residual nitric acid amount in the polymer solution was 0.09%.

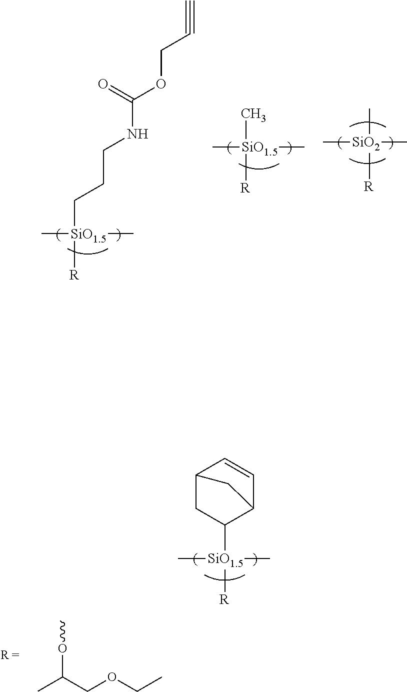

### Synthesis Example 7

A 300 mL flask was charged with 16.6 g of tetraethoxysilane, 12.53 g of methyltriethoxysilane, 2.42 g of O-(propargyl)-N-(triethoxysilylpropyl) carbamate, and 47.9 g of propylene glycol monoethyl ether, and while the resultant mixture solution was stirred with a magnetic stirrer, 0.36 g of dimethylaminopropyltrimethoxysilane and 20.1 g of aqueous nitric acid solution (0.2 mol/L) were added dropwise.

After the dropwise addition, the flask was transferred to an oil bath adjusted to 60° C., and refluxed for 20 hours. Thereafter, ethanol, methanol, and water as reaction by-products were distilled under reduced pressure and concentrated to obtain a hydrolysis condensate (polymer) solution.

Propylene glycol monoethyl ether was further added to the solution, the concentration was adjusted so as to achieve a solvent proportion of propylene glycol monomethyl ether of 100% and a solid residue content of 20 mass % at 140° C., and filtration was performed with a nylon filter (pore size: 0.1 μm).

The resultant polymer contained a polysiloxane having a structure represented by the formula described below and have a weight average molecular weight of Mw 3,100 as determined by GPC in terms of polystyrene. In addition, from ¹H-NMR, the amount capped with propylene glycol monoethyl ether was 3 mol % with respect to Si atoms. In addition, the residual nitric acid amount in the polymer solution was 0.17%.

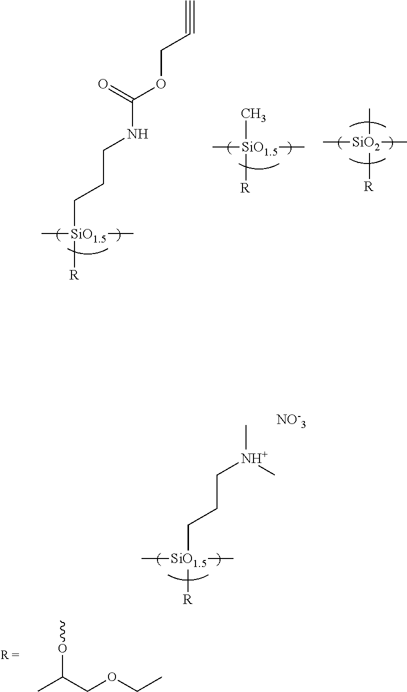

### Comparative Synthesis Example 1

A 300 mL flask was charged with 23.35 g of tetraethoxysilane, 8.57 g of methyltriethoxysilane, 47.9 g of propylene glycol monoethyl ether, and while the resultant mixture solution was stirred with a magnetic stirrer, 20.2 g of aqueous nitric acid solution (0.1 mol/L) was added dropwise.

After the dropwise addition, the flask was transferred to an oil bath adjusted to 60° C., and refluxed for 20 hours. Thereafter, ethanol and water as reaction by-products were distilled under reduced pressure and concentrated to obtain a hydrolysis condensate (polymer) solution.

Propylene glycol monoethyl ether was further added to the solution, the concentration was adjusted so as to achieve a solvent proportion of propylene glycol monomethyl ether of 100% and a solid residue content of 20 mass % at 140° C., and filtration was performed with a nylon filter (pore size: 0.1 μm).

The resultant polymer contained a polysiloxane having a structure represented by the formula described below and have a weight average molecular weight of Mw 3,500 as determined by GPC in terms of polystyrene. In addition, from ¹H-NMR, the amount capped with propylene glycol monoethyl ether was 4 mol % with respect to Si atoms. In addition, the residual nitric acid amount in the polymer solution was 0.08%.

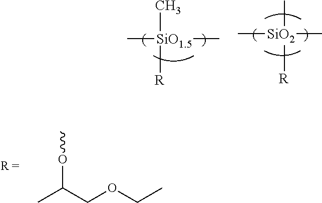

### [2] Preparation of Composition Applied to Resist Pattern

The polysiloxane (polymer) obtained in the above Synthesis Examples, the stabilizer (additive 1), the curing catalyst (additive 2), and the solvent were mixed at the ratio shown in Table 1, and the mixture was filtered through a 0.1 μm fluororesin filter to prepare each composition to be applied to a resist pattern. Each addition amount in Table 1 is shown in parts by mass.

Note that the composition of the hydrolysis condensate (polymer) was prepared as a solution containing the condensate obtained in the Synthesis Examples, but the addition ratio of the polymer in Table 1 was not the addition amount of the polymer solution but the addition amount of the polymer itself.

Abbreviations in Table 1 are as described below.

### <Solvent>

DIW: ultrapure water
PGEE: propylene glycol monoethyl ether
PGME: propylene glycol monomethyl ether

### <Additive 1>

MA: maleic acid

### <Additive 2>

TPSNO3: triphenylsulfonium nitrate
TPSML: triphenylsulfonium maleate
TPSTfAc: triphenylsulfonium trifluoroacetate
IMTEOS: triethoxysilylpropyl-4,5-dihydroimidazole
TPSAc: triphenylsulfonium acetate
BTEAC: benzyltriethylammonium chloride salt

TABLE 1

| | Polymer | Additive 1 | Additive 2 | Solvent | | |
|---|---|---|---|---|---|---|
| Example 1 | Synthesis example 1 | MA | TPSNO3 | PGEE | PGME | DIW |
| (Parts by mass) | 1 | 0.01 | 0.05 | 80 | 8 | 12 |
| Example 2 | Synthesis example 2 | MA | TPSML | PGEE | PGME | DIW |
| (Parts by mass) | 1 | 0.01 | 0.05 | 80 | 8 | 12 |
| Example 3 | Synthesis example 3 | MA | TPSTfAc | PGEE | PGME | DIW |
| (Parts by mass) | 1 | 0.01 | 0.05 | 80 | 8 | 12 |
| Example 4 | Synthesis example 4 | MA | IMTEOS | PGEE | PGME | DIW |
| (Parts by mass) | 1 | 0.01 | 0.01 | 80 | 8 | 12 |
| Example 5 | Synthesis example 5 | MA | TPSAc | PGEE | PGME | DIW |
| (Parts by mass) | 1 | 0.01 | 0.05 | 80 | 8 | 12 |
| Example 6 | Synthesis example 6 | MA | BTEAC | PGEE | PGME | DIW |
| (Parts by mass) | 1 | 0.01 | 0.05 | 80 | 8 | 12 |
| Example 7 | Synthesis example 7 | MA | TPSNO3 | PGEE | PGME | DIW |
| (Parts by mass) | 1 | 0.01 | 0.05 | 80 | 8 | 12 |
| Comparative | Comparative | MA | IMTEOS | PGEE | PGME | DIW |
| example 1 | synthesis example 1 | | | | | |
| (Parts by mass) | 1 | 0.01 | 0.01 | 80 | 8 | 12 |

* Examples 1 to 7 and Comparative Example 1 each further contain a nitric acid contained in the polymer solutions prepared in Synthesis Examples 1 to 7 and Comparative Synthesis Example 1.

### [3] Preparation of Composition for Forming Organic Resist Underlayer Film

Under nitrogen, a 100 mL four-necked flask was charged with carbazole (6.69 g, 0.040 mol, manufactured by Tokyo Chemical Industry Co., Ltd.), 9-fluorenone (7.28 g, 0.040 mol, manufactured by Tokyo Chemical Industry Co., Ltd.), and para-toluenesulfonic acid monohydrate (0.76 g, 0.0040 mol, manufactured by Tokyo Chemical Industry Co., Ltd.), and then 1,4-dioxane (6.69 g, manufactured by KANTO CHEMICAL CO., INC.) was added, the resultant mixture was stirred and heated to 100° C. for dissolution, to thereby initiate polymerization. After the elapse of 24 hours, the mixture was left to cool to 60° C.

The cooled reaction mixture was diluted with chloroform (34 g, manufactured by KANTO CHEMICAL CO., INC.), and the diluted mixture was added to methanol (168 g, manufactured by KANTO CHEMICAL CO., INC.) for precipitation.

The resultant precipitate was filtered and collected, and the collected solid was dried with a reduced-pressure dryer at 80° C. for 24 hours, to thereby obtain 9.37 g of a target polymer represented by Formula (X) (hereinafter abbreviated as PCzFL).

Note that the result of measurement of PCzFL by ¹H-NMR were as described below.

¹H-NMR (400 MHz, DMSO-d6): δ7.03-7.55 (br, 12H), δ7. 61-8.10 (br, 4H), δ11.18 (br, 1H)

In addition, PCzFL was found to have a weight average molecular weight Mw of 2,800 as determined by GPC in terms of polystyrene and a polydispersity Mw/Mn of 1.77.

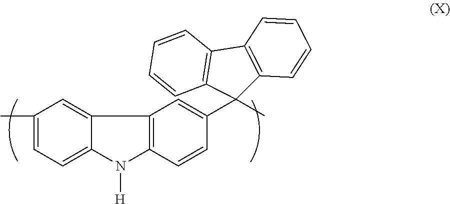

20 g of PCzFL was mixed with 3.0 g of tetramethoxymethyl glycoluril (trade name: Powderlink 1174, manufactured by Cytec Industries Japan (former Mitsui Cytec Ltd.)) serving as a crosslinking agent, 0.30 g of pyridinium para-toluenesulfonate serving as a catalyst, and 0.06 g of MEGAFACE R-30 (trade name, manufactured by DIC Corporation) serving as a surfactant, and the mixture was dissolved in 88 g of propylene glycol monomethyl ether acetate to prepare a solution. Thereafter, the solution was filtered with a polyethylene-made microfilter having a pore size of 0.10 μm, and then filtered with a polyethylene-made microfilter having a pore size of 0.05 μm, to thereby prepare a composition for forming an organic resist underlayer film used for a lithography process using a multilayer film.

### [4] Solvent Resistance and Developer Resistance Test

Each of the compositions prepared in Examples 1 to 7 and Comparative Example 1 was applied onto a silicon wafer with a spinner. The composition was heated on a hot plate at 215° C. for one minute, to thereby form an Si-containing resist underlayer film, and the film thickness of the resultant underlayer film was measured.

Subsequently, a mixed solvent of propylene glycol monomethyl ether/propylene glycol monomethyl ether acetate (7/3 (V/V)) was applied onto the Si-containing resist underlayer film, and then spin-dried. The film thickness of the underlayer film after application was measured, and the ratio (%) of the change in film thickness after application of the mixed solvent was calculated with the film thickness before application of the mixed solvent as a reference (100%). A film thickness change of 1% or less before and after application of the mixed solvent was evaluated as “good”, and a film thickness change of more than 1% was evaluated as “not cured”.

In addition, an alkaline developer (2.38% aqueous tetramethylammonium hydroxide (TMAH) solution) was applied onto an Si-containing resist underlayer film formed on a silicon wafer in the same manner as described above, and then spin-dried, the film thickness of the underlayer film after application was measured, and the ratio (%) of the change in film thickness after application of the developer was calculated with the film thickness before application of the developer as a reference (100%). A film thickness change of 1% or less before and after application of the developer was evaluated as “good”, and a film thickness change of more than 1% was evaluated as “not cured”.

The obtained results are shown in Table 2.

TABLE 2

| | | Developer |
|---|---|---|
| | Solvent resistance | resistance |
| Example 1 | Good | Good |
| Example 2 | Good | Good |
| Example 3 | Good | Good |
| Example 4 | Good | Good |
| Example 5 | Good | Good |
| Example 6 | Good | Good |
| Example 7 | Good | Good |
| Comparative | Good | Good |
| example 1 | | |

### [5] Formation of Resist Pattern by EUV Exposure: Positive Solvent Development

The composition for forming an organic resist underlayer film was applied onto a silicon wafer using a spinner, and baked on a hot plate at 215° C. for 60 seconds to obtain an organic underlayer film (A layer) having a film thickness of 90 nm.

The composition obtained in Example 1 was applied thereon by spin coating, and heated at 215° C. for 1 minute to form a resist underlayer film (B layer) (20 nm).

Further, a resist solution for EUV (methacrylate resin-based resist) was applied thereon by spin coating, and heated at 110° C. for 1 minute to form an EUV resist film (C layer), and then the EUV resist film (C layer) was exposed using an EUV exposure apparatus (NXE3400) manufactured by ASML under the conditions of NA=0.33, σ=0.63/0.84, and Quadropole.

After the exposure, the post exposure bake (PEB, 105° C., 1 min) was performed, cooling was performed on a cooling plate to a room temperature, development was performed for 30 seconds using a TMAH 2.38% developer, and rinsing treatment was performed to form a resist pattern.

In the same procedure, a resist pattern was formed using each of the compositions obtained in Examples 2 to 7 and Comparative Example 1.

Then, each of the obtained patterns was evaluated for formation of a 28 nm pitch and a 12 nm line pattern by confirming the pattern shape through observation of a cross section of the pattern.

In the observation of the pattern shape, evaluation “good” was given to a shape between footing and undercut and a state of no significant residue in a space portion, evaluation “collapse” was given to an unfavorable state of collapse of the resist pattern. The obtained results are shown in Table 3.

TABLE 3

| | Pattern shape |
|---|---|
| Example 1 | Good |
| Example 2 | Good |
| Example 3 | Good |
| Example 4 | Good |
| Example 5 | Good |
| Example 6 | Good |
| Example 7 | Good |
| Comparative | Collapse |
| example 1 | |

1. A composition for forming a silicon-containing resist underlayer film, comprising:
component [A]: a carbon-carbon triple bond-containing polysiloxane; and
component [C]: a solvent.

2. The composition for forming a silicon-containing resist underlayer film according to claim 1, wherein the carbon-carbon triple bond-containing polysiloxane contains a structural unit derived from a hydrolyzable silane (A) having a carbon-carbon triple bond.

3. A composition for forming a silicon-containing resist underlayer film, comprising:
component [A′]: a polysiloxane;
component [B]: a hydrolyzable silane (A) having a carbon-carbon triple bond; and
component [C]: a solvent.

4. The composition for forming a silicon-containing resist underlayer film according to claim 2, wherein the hydrolyzable silane (A) is a compound represented by Formula (A-1) described below: 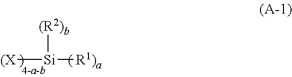
in Formula (A-1), a represents an integer of 1 to 3;
b represents an integer of 0 to 2;
a+b represents an integer of 1 to 3;
R¹ represents an organic group that has a carbon-carbon triple bond and may have an ionic bond;
R² represents an optionally substituted alkyl group, an optionally substituted aryl group, an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group, or a combination of two or more thereof,
X represents an alkoxy group, an aralkyloxy group, an acyloxy group, or a halogen atom;
when there are a plurality of R¹, R², and X, the plurality of R¹, R², and X may be the same or different.

5. The composition for forming a silicon-containing resist underlayer film according to claim 4, wherein R¹ in the Formula (A-1) is represented by Formula (A-2a) described below: 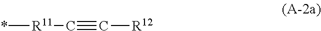
in Formula (A-2a), R¹¹ represents a single bond or a divalent organic group that may have an ionic bond;
R¹² represents a hydrogen atom, an alkyl group having 1 to 6 carbon atoms that may have a substituent group, or an aryl group that may have a substituent group;
* represents a bond.

6. The composition for forming a silicon-containing resist underlayer film according to claim 1, wherein the carbon-carbon triple bond-containing polysiloxane as the component [A] is a polysiloxane modified product in which a part of silanol groups is alcohol-modified or acetal-protected.

7. The composition for forming a silicon-containing resist underlayer film according to claim 3, wherein the polysiloxane as the component [A′] is a polysiloxane modified product in which a part of silanol groups is alcohol-modified or acetal-protected.

8. The composition for forming a silicon-containing resist underlayer film according to claim 1, wherein the component [C] contains an alcohol-based solvent.

9. The composition for forming a silicon-containing resist underlayer film according to claim 8, wherein the component [C] contains a propylene glycol monoalkyl ether.

10. The composition for forming a silicon-containing resist underlayer film according to claim 1, further comprising: component [D]: a curing catalyst.

11. The composition for forming a silicon-containing resist underlayer film according to claim 1, further comprising: component [E]: a nitric acid.

12. The composition for forming a silicon-containing resist underlayer film according to claim 1, wherein the component [C] contains water.

13. The composition for forming a silicon-containing resist underlayer film according to claim 1, the composition being for forming a resist underlayer film for EUV lithography.

14. A silicon-containing resist underlayer film, the film being a cured product of the composition for forming a silicon-containing resist underlayer film according to claim 1.

15. A semiconductor processing substrate comprising:
a semiconductor substrate; and
the silicon-containing resist underlayer film according to claim 14.

16. A method for manufacturing a semiconductor element, the method comprising:
forming an organic underlayer film on a substrate;
forming a resist underlayer film on the organic underlayer film using the composition for forming a silicon-containing resist underlayer film according to claim 1; and
forming a resist film on the resist underlayer film.

17. The method for manufacturing a semiconductor element according to claim 16, wherein the resist film is formed of a resist for EUV lithography.

18. The method for manufacturing a semiconductor element according to claim 16, wherein in the forming the resist underlayer film, a composition for forming a silicon-containing resist underlayer film filtered through a nylon filter is used.

19. A pattern forming method, comprising:
forming an organic underlayer film on a semiconductor substrate;
applying the composition for forming a silicon-containing resist underlayer film according to claim 1 on the organic underlayer film and baking the composition to form a resist underlayer film;
applying a composition for forming a resist film on the resist underlayer film to form a resist film;
exposing and developing the resist film to obtain a resist pattern;
etching the resist underlayer film using the resist pattern as a mask; and
etching the organic underlayer film using the patterned resist underlayer film as a mask.

20. The pattern forming method according to claim 19, further comprising:
removing the resist underlayer film by a wet method using a chemical liquid after the etching the organic underlayer film.

21. The pattern forming method according to claim 19, wherein the resist film is formed of a resist for EUV lithography.

22. The composition for forming a silicon-containing resist underlayer film according to claim 3, wherein the hydrolyzable silane (A) is a compound represented by Formula (A-1) described below: 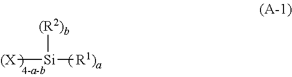
in Formula (A-1), a represents an integer of 1 to 3;
b represents an integer of 0 to 2;
a+b represents an integer of 1 to 3;
R1 represents an organic group that has a carbon-carbon triple bond and may have an ionic bond;
R2 represents an optionally substituted alkyl group, an optionally substituted aryl group, an optionally substituted aralkyl group, an optionally substituted halogenated alkyl group, an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group, an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group, or a combination of two or more thereof,
X represents an alkoxy group, an aralkyloxy group, an acyloxy group, or a halogen atom;
when there are a plurality of R1, R2, and X, the plurality of R1, R2, and X may be the same or different.

23. The composition for forming a silicon-containing resist underlayer film according to claim 22, wherein R1 in the Formula (A-1) is represented by Formula (A-2a) described below: 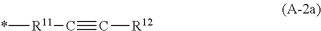
in Formula (A-2a), R11 represents a single bond or a divalent organic group that may have an ionic bond;
R12 represents a hydrogen atom, an alkyl group having 1 to 6 carbon atoms that may have a substituent group, or an aryl group that may have a substituent group;
* represents a bond.

24. A silicon-containing resist underlayer film, the film being a cured product of the composition for forming a silicon-containing resist underlayer film according to claim 3.

25. A semiconductor processing substrate comprising:
a semiconductor substrate; and
the silicon-containing resist underlayer film according to claim 24.

26. A method for manufacturing a semiconductor element, the method comprising:
forming an organic underlayer film on a substrate;
forming a resist underlayer film on the organic underlayer film using the composition for forming a silicon-containing resist underlayer film according to claim 3; and
forming a resist film on the resist underlayer film.

27. A pattern forming method, comprising:
forming an organic underlayer film on a semiconductor substrate;
applying the composition for forming a silicon-containing resist underlayer film according to claim 3 on the organic underlayer film and baking the composition to form a resist underlayer film;
applying a composition for forming a resist film on the resist underlayer film to form a resist film;
exposing and developing the resist film to obtain a resist pattern;
etching the resist underlayer film using the resist pattern as a mask; and
etching the organic underlayer film using the patterned resist underlayer film as a mask.
